(19) United States
(12) Patent Application Publication
(10) Pub. No.: US 2025/0194396 A1
(43) Pub. Date: Jun. 12, 2025

(54) ORGANIC LIGHT EMITTING DIODE COMPRISING ORGANOMETALLIC COMPOUND AND VARIOUS TYPES OF HOST MATERIALS

(71) Applicant: LG DISPLAY CO., LTD., Seoul (KR)

(72) Inventors: Inbum Song, Seoul (KR); Dohan Kim, Goyang-si (KR); Sungjin Park, Incheon (KR); Jaemin Moon, Seoul (KR); Seokwoo Kang, Hwaseong-si (KR)

(73) Assignee: LG DISPLAY CO., LTD., Seoul (KR)

(21) Appl. No.: 18/810,214

(22) Filed: Aug. 20, 2024

(30) Foreign Application Priority Data
Dec. 11, 2023 (KR) 10-2023-0179039

(51) Int. Cl. H10K 85/30; C09K 11/02; C09K 11/06; H10K 50/12; H10K 85/60

(52) U.S. Cl. CPC H10K 85/342; C09K 11/02; C09K 11/06; H10K 85/633; H10K 85/636; H10K 85/6576; C09K 2211/1011; C09K 2211/1037; C09K 2211/185; H10K 50/12; H10K 85/624; H10K 85/626; H10K 85/6572; H10K 85/6574

(57) ABSTRACT

An organic light emitting diode in one example includes an emission material layer including an organometallic compound and various types of host materials. Further, a display device including the organic light emitting diodes is discussed.

### CROSS REFERENCE TO RELATED APPLICATION

The present application claims priority to Korean Patent Application No. 10-2023-0179039, filed Dec. 11, 2023, the entire contents of which is incorporated by reference into the present application for all purposes.

### BACKGROUND OF THE INVENTION

### Field of the Invention

The present disclosure relates to an organic light emitting diode including an organometallic compound and various types of host materials.

### Description of the Related Art

Interest in display devices is increasing and has application in various fields. As one of the display devices, a technology of an organic light emitting display devices including an organic light emitting diode (OLED) is developing rapidly.

The OLED is an element for emitting energies of excitons as light after forming electrons and holes in pair to form excitons when charges are injected into an emission material layer formed between an anode and a cathode. Compared to conventional display technologies, the OLED can be implemented at a low voltage, consume relatively less power, provide excellent colors, can be applied to a flexible substrate to be used variously, and can allow a display device to be freely adjusted in size.

The OLED can have a wide viewing angle and a high contrast ratio compared to liquid crystal display (LCD) devices and does not require a backlight, making it lightweight and ultra-thin. The OLED is formed by arranging a plurality of intermediate layers, such as a hole injection layer, a hole transport layer, a hole transport auxiliary layer, an electron blocking layer, an electron transport layer, an electron injection layer, and the like between the cathode (electron injection electrode) and the anode (hole injection electrode).

In the structure of the OLED, when a voltage is applied between two electrodes, electrons and holes are injected from the cathode and the anode, respectively, and excitons generated from the emission material layer fall to a ground state to emit light.

Organic materials used in the OLED can be largely classified into a light emitting material and a charge transport material. The light emitting material is an important factor in determining the luminous efficiency of the OLED, and the light emitting material should have high quantum efficiency, excellent mobility of electrons and holes, and be uniformly and stably present in the emission material layer. The light emitting material is classified into light emitting materials, such as blue, red, and green, depending on colored light and is used as hosts and dopants to increase color purity and increase luminous efficiency through energy transfer as color materials.

In the case of fluorescent materials, while only a singlet of about 25% of the excitons formed in the emission material layer is used to generate light, and a triplet of 75% is mostly lost as heat, phosphorescent materials has a luminous mechanism that converts both the singlet and the triplet into light.

So far, organic metal compounds have been used as phosphorescent materials used in the OLED. There is still a technical need to improve the performance of the OLED by deriving high-efficiency phosphorescent dopant materials and applying hosts with optimal photophysical characteristics to improve the efficiency and lifetime of the element compared to conventional OLEDs.

### SUMMARY OF THE DISCLOSURE

Therefore, the present disclosure is directed to providing an organic light emitting diode (OLED) in which an organometallic compound and various types of host materials, which are capable of increasing a driving voltage, efficiency, and a lifetime, are applied to an organic emission material layer.

The objects of the present disclosure are not limited to the above-described object, and other objects and advantages of the present disclosure which are not mentioned can be understood by the following description and more clearly understood by embodiments of the present disclosure. In addition, it can be easily seen that the objects and advantages of the present disclosure can be achieved by means and combinations thereof which are described in the claims.

To achieve the object, one embodiment of the present disclosure can provide an organic light emitting diode including a first electrode, a second electrode facing the first electrode, and an intermediate layer disposed between the first electrode and the second electrode, wherein the intermediate layer includes an emission material layer, the emission material layer includes a dopant material and a host material, the dopant material includes an organometallic compound represented by Chemical Formula 1 below, and the host material includes a mixture of a compound represented by Chemical Formula 4 below and a compound represented by Chemical Formula 5 below:

M(L_{A})ₘ(L_{B})ₙ <Chemical Formula 1>
in Chemical Formula 1,
M is a central coordination metal and is one selected from the group consisting of molybdenum (Mo); tungsten (W); rhenium (Re); ruthenium (Ru); osmium (Os); rhodium (Rh); iridium (Ir); palladium (Pd); platinum (Pt); and gold (Au),
L_{A} is a ligand represented by Chemical Formula 2,
L_{B} is a bidentate ligand,
m is 1, 2 or 3, n is 0, 1 or 2, and (m+n) is the oxidation number of the central coordination metal M,

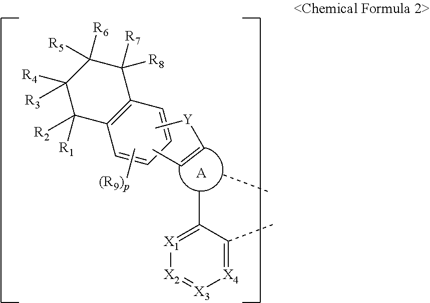

in Chemical Formula 2,
A has a ring structure selected from substituted or unsubstituted pyridine and substituted or unsubstituted pyrimidine,
R₁ to R₈ are, each independently, at least one selected from the group consisting of hydrogen; deuterium; a substituted or unsubstituted C1-C20 linear alkyl group; a substituted or unsubstituted C3-C20 branched alkyl group; and a substituted or unsubstituted C4-C20 bicycloalkyl group, and optionally, R₁ to R₈ are partially or entirely deuterated,
R₉ is, each independently, at least one selected from the group consisting of hydrogen; deuterium; a substituted or unsubstituted C1-C20 linear alkyl group; a substituted or unsubstituted C3-C20 branched alkyl group; a C3-C20 cycloalkyl group; halogen; a nitrile group; a substituted or unsubstituted C1-C20 alkoxy group; and combinations thereof, and optionally, R₉ is partially or entirely deuterated,
when any one of R₁ to R₉ is substituted, a substituent of R₁ to R₉ can, each independently, be at least one selected from the group consisting of deuterium; halogen; a C3-C10 cycloalkyl group; and combinations thereof, and when a plurality of the substituents of R₁ to R₉ are present, each substituent is the same as or different from each other,
Y is at least one selected from the group consisting of BR₁₀; CR₁₀R₁₁; C═O; CNR₁₀; SiR₁₀R₁₁; NR₁₀; PR₁₀; AsR₁₀; SbR₁₀; P(O) R₁₀; P(S) R₁₀; P(Se) R₁₀; As(O) R₁₀; As(S) R₁₀; As(Se) R₁₀; Sb(O) R₁₀; Sb(S) R₁₀; Sb(Se) R₁₀; O; S; Se; Te; SO; SO₂; SeO; SeO₂; TeO; and TeO₂,
X₁ to X₄ are, each independently, at least one selected from CR₁₂ and nitrogen (N),
when any two of X₁ to X₄ that are adjacent to each other are CR₁₂, two R₁₂ are not bonded, or are bonded to form a 5-membered or 6-membered, substituted or unsubstituted aromatic ring or heteroaromatic ring structure, when one of any two of X₁ to X₄ that are adjacent is CR₁₂ and the other is nitrogen (N), R₁₂ is not bonded, or is bonded to the nitrogen to form a 5-membered or 6-membered heteroaromatic ring structure, and the aromatic ring or the heteroaromatic ring structure formed where R₁₂ is bonded is not substituted or substituted with at least one deuterium,
R₁₀ to R₁₂ are, each independently, at least one selected from the group consisting of hydrogen; deuterium; halogen; a hydroxyl group; a nitro group; an amidino group; a hydrazine group; a hydrazone group; a substituted or unsubstituted C1-C20 linear alkyl group; a substituted or unsubstituted C3-C20 branched alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
when any one of R₁₀ to R₁₂ is substituted, a substituent of R₁₀ to R₁₂ is, each independently, at least one selected from the group consisting of deuterium; halogen; and combinations thereof, and when a plurality of the substituents of R₁₀ to R₁₂ are present, each substituent is the same as or different from each other,
at least p is 2, and
dotted line represents a connection position to the central coordination metal M,

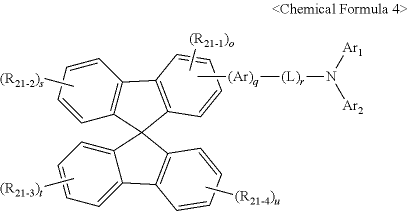

in Chemical Formula 4,
Ar is, each independently, a divalent group of an aromatic ring or a heteroaromatic ring selected from the group consisting of benzene; naphthalene; phenanthrene; fluorene; spirobifluorene; dibenzofuran; and dibenzothiophene,
Ar₁ and Ar₂ are, each independently, a substituted or unsubstituted C6-C60 aryl group or a substituted or unsubstituted C2-C60 heteroaryl group,
R₂₁₋₁ to R₂₁₋₄ are, each independently, at least one selected from the group consisting of deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
o is an integer from 0 to 3, when o is an integer of 2 or 3, R₂₁₋₁ is the same or different, and optionally, R₂₁₋₁ is deuterated partially or entirely,
s is an integer from 0 to 4, when s is an integer from 2 to 4, R₂₁₋₂ is the same or different, and optionally, R₂₁₋₂ is deuterated partially or entirely,
t is an integer from 0 to 4, when t is an integer from 2 to 4, R₂₁₋₃ is the same or different, and optionally, R₂₁₋₃ is deuterated partially or entirely,
u is an integer from 0 to 4, when u is an integer from 2 to 4, R₂₁₋₄ is the same or different, and optionally, R₂₁₋₄ is deuterated partially or entirely,
q is an integer from 0 to 2, and
r is an integer of 0 or 1, and
a linker L is at least one selected from the group consisting of a substituted or unsubstituted C6-C30 arylene group; a substituted or unsubstituted C2-C30 heteroarylene group; and a substituted or unsubstituted C7-C20 arylalkylene group,

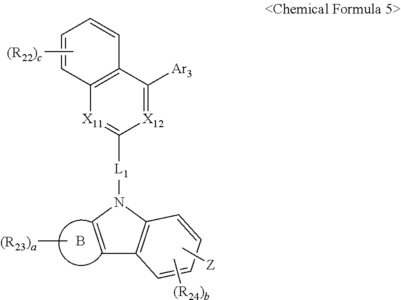

in Chemical Formula 5,
a B ring is a substituted or unsubstituted C6-C30 monocyclic or polycyclic aromatic fused ring,
X₁₁ and X₁₂ are, each independently, N or CR′,
L₁ is one selected from the group consisting of a single bond; a substituted or unsubstituted C6-C30 arylene group; a substituted or unsubstituted C2-C30 heteroarylene group; and a substituted or unsubstituted C3-C30 cycloalkylene group,
Ar₃ is one selected from the group consisting of hydrogen; deuterium; halogen; a substituted or unsubstituted C1-C30 alkyl group; a substituted or unsubstituted C6-C30 aryl group; a substituted or unsubstituted C2-C30 heteroaryl group; and -L₂₄-SiRₖRₗRₘ, in which L₂₄ is a single bond, a substituted or unsubstituted C6-C30 arylene group, or a substituted or unsubstituted C2-C30 heteroarylene group, and Rₖ, Rₗ, and Rₘ are, each independently, hydrogen, a substituted or unsubstituted C1-C30 alkyl group or a substituted or unsubstituted C6-C30 aryl group,
   one or more of hydrogen of an alkyl group, an aryl group, a heteroaryl group, or a -L₂₄-SiRₖRₗRₘ, group, which is Ar₃, are unsubstituted or substituted with one or more of deuterium and halogen atom,
Z is one selected from the group consisting of the following structures,

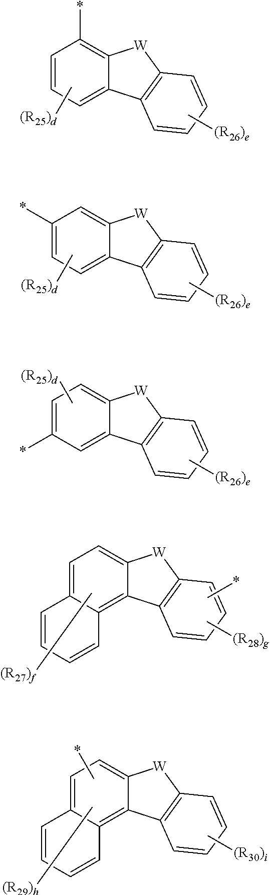

W is one selected from the group consisting of O; S; NR₃₁; CR₃₁R₃₂; and SiR₃₁R₃₂,
R₂₂ to R₃₂ and R′ are, each independently, one selected from the group consisting of hydrogen; deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group, and
a, c, e and i are, each independently, an integer of 1, 2, 3 or 4; b, d, g are, each independently, an integer of 1, 2 or 3; f is an integer of 1, 2, 3, 4, 5, or 6; and h is an integer of 1, 2, 3, 4, or 5.

According to one embodiment of the present disclosure, there can be provided an organic light emitting diode including a first electrode, a second electrode facing the first electrode, and one or more light emitting parts positioned between the first electrode and the second electrode, wherein at least one of the light emitting parts includes a red phosphorescent layer, the red phosphorescent layer includes a dopant material and a host material, the dopant material includes an organometallic compound represented by Chemical Formula 1 below, and the host material includes a compound represented by Chemical Formula 4 below and a compound represented by Chemical Formula 5 below, and the definition of Chemical Formulas 1, 4 and 5 are the same as those defined in one embodiment of the present disclosure.

### BRIEF DESCRIPTION OF THE DRAWINGS

FIG. 1 is a cross-sectional view schematically showing an organic light emitting diode (OLED) according to one or more embodiments of the present disclosure.

FIG. 2 is a cross-sectional view schematically showing the OLED with a tandem structure having two light emitting parts according to one or more embodiments of the present disclosure.

FIG. 3 is a cross-sectional view schematically showing the OLED with a tandem structure having three light emitting parts according to one or more embodiments of the present disclosure.

FIG. 4 is a cross-sectional view schematically showing an OLED display device to which the OLED according to one or more embodiments of the present disclosure is applied.

### DETAILED DESCRIPTION OF THE EMBODIMENTS

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure can unnecessarily obscure the gist of the present disclosure, a detailed description thereof will be omitted. Hereinafter, some embodiments according to the present disclosure will be described in detail with reference to the accompanying drawings. In the drawings, the same reference numerals are used to denote the same or similar components.

In the specification, when terms “including,” “having,” “consisting of,” “arranging,” “providing,” and the like are used, other portions can be added unless “only” is used. When a component is expressed in the singular, it includes a case in which a plurality of the components are present unless specifically stated otherwise.

In construing a component in the specification, the component is construed as including the margin of error even when there is no separate explicit description. All the components of each display device and each OLED according to all embodiments of the present disclosure are operatively coupled and configured.

In the specification, the arrangement of an arbitrary component on an “upper portion (or a lower portion)” of a component or “above (or under)” the component may not only mean that the arbitrary component is disposed in contact with an upper surface (or a lower surface) of the component, but also mean that other components can be interposed between the component and the arbitrary component disposed above (or under) the component.

The term “halo” or “halogen” used herein includes fluorine, chlorine, bromine, and iodine.

The term “alkyl group” used herein indicates both linear alkyl radicals and branched alkyl radicals. Unless otherwise stated, the linear alkyl group contains 1 to 20 carbon atoms, the branched alkyl group contains 3 to 20 carbon atoms and contains methyl, ethyl, propyl, isopropyl, butyl, isobutyl, tert-butyl, and the like, and additionally, the alkyl group can be substituted arbitrarily.

The term “cycloalkyl group” used herein indicates cyclic alkyl radicals. Unless otherwise stated, the cycloalkyl group contains 3 to 20 carbon atoms and includes cyclopropyl, cyclopentyl, cyclohexyl, and the like, and additionally, the cycloalkyl group can be substituted arbitrarily.

The term “alkenyl group” used herein indicates both linear alken radicals and branched alken radicals. Unless otherwise stated, the alkenyl group contains 2 to 20 carbon atoms, and additionally, the alkenyl group can be substituted arbitrarily.

The term “cycloalkenyl group” used herein indicates cyclic alkenyl radicals. Unless otherwise stated, the cycloalkenyl group contains 3 to 20 carbon atoms, and additionally, the cycloalkenyl group can be substituted arbitrarily.

The term “alkynyl group” used herein indicates both linear alkyne radicals and branched alkyne radicals. Unless otherwise stated, the alkynyl group contains 2 to 20 carbon atoms. Additionally, the alkynyl group can be substituted arbitrarily.

The term “cycloalkynyl group” used herein indicates cyclic alkynyl radicals. Unless otherwise stated, the cycloalkynyl group contains 3 to 20 carbon atoms, and additionally, the cycloalkynyl group can be substituted arbitrarily.

The terms “aralkyl group” or “arylalkyl group” used herein are used interchangeably and indicates an alkyl group having an aromatic group as a substituent, and unless otherwise stated, the aralkyl group contains 7 to 60 carbon atoms, and additionally, the aralkyl group can be substituted arbitrarily.

The terms “aryl group,” “aromatic group,” “aromatic ring,” “aromatic carbocyclic ring,” and “aromatic heterocyclic ring” used herein can include conjugated structures and can include a single ring and a polycyclic ring. The polycyclic ring can include a “condensed ring,” which are two or more rings where two carbons are shared by two adjacent rings. Unless otherwise stated, the aryl group contains 5 to 60 carbon atoms, and additionally, the aryl group can be substituted arbitrarily.

Unless otherwise stated, the term “carboncyclic ring group” used herein can be used as the term including all of “cycloalkyl group,” “cycloalkenyl group,” and “cycloalkynyl group,” which are alicyclic ring groups, and “aryl group,” which is an aromatic ring group.

The term “heterocyclic ring group” used herein indicates that one or more of the carbon atoms constituting an aryl group, a cycloalkyl group, a cycloalkenyl group, a cycloalkynyl group, an aralkyl group (arylalkyl group), an arylamino group, and the like are substituted with a heteroatom, such as oxygen (O), nitrogen (N), sulfur (S), etc., and with reference to the above definition, includes a heteroaryl group, a heterocycloalkyl group, a heterocycloalkenyl group, a heterocycloalkynyl group, a heteroarylalkyl group (heteroarylalkyl group), a heteroarylamino group, and the like, and unless otherwise stated, the heteroaryl group contains 2 to 60 carbon atoms and additionally, the heterocyclic ring group can be substituted arbitrarily.

The terms “heteroalkyl group,” “heteroalkenyl group,” “heteroalkynyl group,” and “heteroaralkyl group (heteroarylalkyl group)” used herein indicate that one or more of the carbon atoms constituting the corresponding “alkyl group,” “alkenyl group,” “alkynyl group,” and “aralkyl group (arylalkyl group)” are substituted with heteroatoms, such as oxygen (O), nitrogen (N), and sulfur (S), and additionally, the heteroalkyl group, the heteroalkenyl group, the heteroalkynyl group, and heteroaralkyl group (heteroarylalkyl group) can be substituted arbitrarily.

The terms “alkylamino group,” “aralkyl amino group,” “arylamino group,” and “heteroarylamino group” used herein indicate that the amine group is substituted with the alkyl group, the aralkyl group, the aryl group, and the heteroaryl group that is a hetero ring and include all of primary, secondary, and tertiary amines, and additionally, the alkylamino group, the aralkylamino group, the arylamino group, and the heteroarylamino group can be substituted arbitrarily.

The terms “alkylsilyl group,” “arylsilyl group,” “alkoxy group,” “aryloxy group,” “alkylthio group,” and “arylthio group” indicate that each of the silyl group, the oxy group, or the thio group is substituted with the alkyl group and the aryl group, and additionally, the alkylsilyl group, the arylsilyl group, the alkoxy group, the aryloxy group, the alkylthio group, and the arylthio group may be substituted arbitrarily.

The term “substituted” indicates that another substituent is bonded to the corresponding carbon atom instead of the hydrogen atom (H) bonded to the carbon atom, and in the case of “substituted,” one or more substituents are used, and when a plurality of the substituents are present, each substituent can be the same as or different from each other.

Unless otherwise stated herein, the substituent(s) in the case of being “substituted” can be at least one selected from the group consisting of deuterium, halogen, C1-C20 alkyl, C3-C30 cycloalkyl, C1-C20 heteroalkyl, C2-C30 heterocycloalkyl, C7-C30 arylalkyl, C1-C20 alkoxy, C6-C30 aryloxy, amino, silyl, C1-C20 alkylsilyl, C6-C20 arylsilyl, C7-C20 alkylarylsilyl, C2-C20 alkenyl, C3-C20 cycloalkenyl, C2-C20 heteroalkenyl, C2-C20 alkynyl, C6-C30 aryl, C2-C30 heteroaryl, C2-C20 acyl, carboxyl, nitrile, isonitrile, sulfanyl, phosphino, phenyl, dibenzofuran, and combinations thereof, and includes a case in which at least one hydrogen of the substituents is substituted with deuterium, which can be the case, for example, where the substituent is partially or entirely deuterated.

The term ‘combinations thereof’ in the definition of a substituent indicates that multiple substituents may exist, and the plurality of a substituent is defined as a combination from the defined list.

Substituents mentioned herein, other than those defined above follow definitions of known substituents.

As used herein, a case where two substituents defined as including hydrogen are bonded to form a ring includes a case where one of the two substituents is hydrogen and the other is not hydrogen, and the hydrogen is removed while the two substituents are bonded.

As used herein, “deuterated” can indicate substitution with deuterium instead of light hydrogen in a compound.

As used herein, the term “bidentate ligand” refers to a ligand having two coordination sites that can simultaneously binding to a metal atom such as iridium. In some embodiments, the bidentate ligand includes bidentate carboxylate, bidentate amine, bidentate thiocarboxylate, bidentate diphosphine, bidentate mercaptopyrimidine or bidentate dithiocarboxylate.

Unless otherwise stated herein, a position to be substituted is not limited as long as it is a position where a hydrogen atom is substituted, for example, a position where a substituent can be substituted, and when two or more substituents are present, the substituents can be the same as or different from each other.

The objects and substituents as defined herein can be the same as or different from each other unless otherwise stated.

Hereinafter, a structure of an organometallic compound and an organic light emitting diode (OLED) including the same according to the present disclosure will be described in detail.

Conventionally, organometallic compounds have been used as dopants in phosphorescent layers, and for example, structures such as 2-phenylpyridine are known as main ligand structures of the organometallic compounds. However, since the conventional light emitting dopants have limitations in increasing the efficiency and lifetime of OLEDs, it is necessary to develop new light emitting dopant materials. The present disclosure was completed by experimentally confirming that by mixing a hole transport type host and an electron transport type host as host materials together with the dopant material, it was possible to further increase the efficiency and lifetime of the OLED and decrease the driving voltage, thereby improving the characteristics of the OLED.

According to one embodiment of the present disclosure, there is provided an organic light emitting diode including:
a first electrode;
a second electrode facing the first electrode; and
an intermediate layer disposed between the first electrode and the second electrode,
wherein the intermediate layer includes an emission material layer, and the emission material layer includes a dopant material and a host material,

The dopant material includes an organometallic compound represented by Chemical Formula 1 below, and

The host material includes a mixture of a compound represented by Chemical Formula 4 below and a compound represented by Chemical Formula 5.

M(L_{A})ₘ(L_{B})ₙ <Chemical Formula 1>
in Chemical Formula 1,
M is a central coordination metal and is one selected from the group consisting of molybdenum (Mo); tungsten (W); rhenium (Re); ruthenium (Ru); osmium (Os); rhodium (Rh); iridium (Ir); palladium (Pd); platinum (Pt); and gold (Au),
L_{A} is a ligand represented by Chemical Formula 2,
L_{B} is a bidentate ligand,
m is 1, 2 or 3, n is 0, 1 or 2, and (m+n) is the oxidation number of the central coordination metal M,

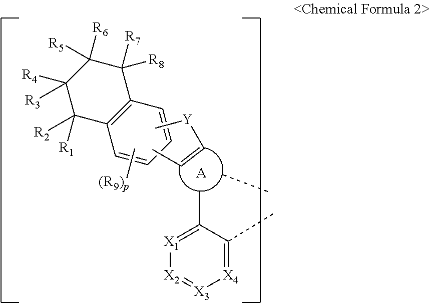

in Chemical Formula 2,
A has a ring structure selected from substituted or unsubstituted pyridine and substituted or unsubstituted pyrimidine, R₁ to R₈ are, each independently, at least one selected from the group consisting of hydrogen; deuterium; a substituted or unsubstituted C1-C20 linear alkyl group; a substituted or unsubstituted C3-C20 branched alkyl group; and a substituted or unsubstituted C4-C20 bicycloalkyl group, and optionally, R₁ to R₈ are partially or entirely deuterated,
R₉ is, each independently, at least one selected from the group consisting of hydrogen; deuterium; a substituted or unsubstituted C1-C20 linear alkyl group; a substituted or unsubstituted C3-C20 branched alkyl group; a C3-C20 cycloalkyl group; halogen; a nitrile group; a substituted or unsubstituted C1-C20 alkoxy group; and combinations thereof, and optionally, R₉ is partially or entirely deuterated,
when any one of R₁ to R₉ is substituted, a substituent of R₁ to R₉ is, each independently, be at least one selected from the group consisting of deuterium; halogen; a C3-C10 cycloalkyl group; and combinations thereof, and when a plurality of substituents of R₁ to R₉ are present, each substituent is the same as or different from each other,
Y is at least one selected from the group consisting of BR₁₀; CR₁₀R₁₁; C═O; CNR₁₀; SiR₁₀R₁₁; NR₁₀; PR₁₀; AsR₁₀; SbR₁₀; P(O)R₁₀; P(S)R₁₀; P(Se)R₁₀; As(O)R₁₀; As(S)R₁₀; As(Se)R₁₀; Sb(O) R₁₀; Sb(S) R₁₀; Sb(Se) R₁₀; O; S; Se; Te; SO; SO2; SeO; SeO₂; TeO; and TeO₂,
X₁ to X₄ are, each independently, at least one selected from CR₁₂ and nitrogen (N),
when any two of X₁ to X₄ that are adjacent to each other are CR₁₂, two R₁₂ are not bonded, or are bonded to form a 5-membered or 6-membered, substituted or unsubstituted aromatic ring or heteroaromatic ring structure, when one of any two of X₁ to X₄ that are adjacent is CR₁₂ and the other is nitrogen (N), R₁₂ is not bonded, or is bonded to the nitrogen to form a 5-membered or 6-membered heteroaromatic ring structure, and the aromatic ring or the heteroaromatic ring structure formed where R₁₂ is bonded is not substituted or substituted with at least one deuterium,
R₁₀ to R₁₂ are, each independently, at least one selected from the group consisting of hydrogen; deuterium; halogen; a hydroxyl group; a nitro group; an amidino group; a hydrazine group; a hydrazone group; a substituted or unsubstituted C1-C20 linear alkyl group; a substituted or unsubstituted C3-C20 branched alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
when any one of R₁₀ to R₁₂ is substituted, a substituent of R₁₀ to R₁₂ is, each independently, at least one selected from the group consisting of deuterium; halogen; and combinations thereof, and when a plurality of the substituents of R₁₀ to R₁₂ are present, each substituent is the same as or different from each other, and
p is 2, and
dotted line represents a connection position to the central coordination metal M,

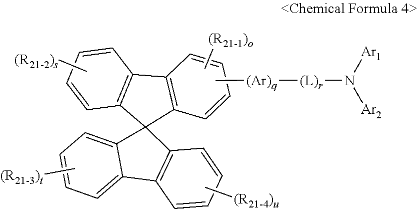

in Chemical Formula 4,
Ar is, each independently, a divalent group of an aromatic ring or a heteroaromatic ring selected from the group consisting of benzene; naphthalene; phenanthrene; fluorene; spirobifluorene; dibenzofuran; and dibenzothiophene,
Ar₁ and Ar₂ are, each independently, a substituted or unsubstituted C6-C60 aryl group or a substituted or unsubstituted C2-C60 heteroaryl group,
R₂₁₋₁ to R₂₁₋₄ are, each independently, at least one selected from the group consisting of deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
o is an integer from 0 to 3, when o is an integer of 2 or 3, R₂₁₋₁ is the same or different, and optionally, R₂₁₋₁ is deuterated partially or entirely,
s is an integer from 0 to 4, when s is an integer from 2 to 4, R₂₁₋₂ is the same or different, and optionally, R₂₁₋₂ is deuterated partially or entirely,
t is an integer from 0 to 4, when t is an integer from 2 to 4, R₂₁₋₃ is the same or different, and optionally, R₂₁₋₃ is deuterated partially or entirely,
u is an integer from 0 to 4, when u is an integer from 2 to 4, R₂₁₋₄ is the same or different, and optionally, R₂₁₋₄ is deuterated partially or entirely,
q is an integer from 0 to 2, and
r is an integer of 0 or 1, and
a linker L is at least one selected from the group consisting of a substituted or unsubstituted C6-C30 arylene group; a substituted or unsubstituted C2-C30 heteroarylene group; and a substituted or unsubstituted C7-C20 arylalkylene group,

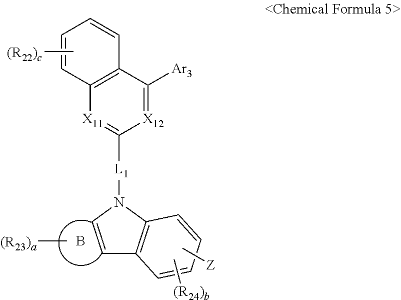

in Chemical Formula 5,
a B ring is a substituted or unsubstituted C6-C30 monocyclic or polycyclic aromatic fused ring,
X₁₁ and X₁₂ are, each independently, N or CR′,
L₁ is one selected from the group consisting of a single bond; a substituted or unsubstituted C6-C30 arylene group; a substituted or unsubstituted C2-C30 heteroarylene group; and a substituted or unsubstituted C3-C30 cycloalkylene group,
Ar₃ is one selected from the group consisting of hydrogen; deuterium; halogen; a substituted or unsubstituted C1-C30 alkyl group; a substituted or unsubstituted C6-C30 aryl group; a substituted or unsubstituted C2-C30 heteroaryl group; and -L₂₄-SiRₖRₗRₘ, in which L₂₄ is a single bond, a substituted or unsubstituted C6-C30 arylene group, or a substituted or unsubstituted C2-C30 heteroarylene group, and Rₖ, Rₗ, and Rₘ are, each independently, hydrogen, a substituted or unsubstituted C1-C30 alkyl group or a substituted or unsubstituted C6-C30 aryl group,
   one or more of hydrogen of an alkyl group, an aryl group, a heteroaryl group, or a -L₂₄-SiRₖRₗRₘ, group, which is Ar₃, are unsubstituted or substituted with one or more of deuterium and halogen atom,
Z is one selected from the group consisting of the following structures,

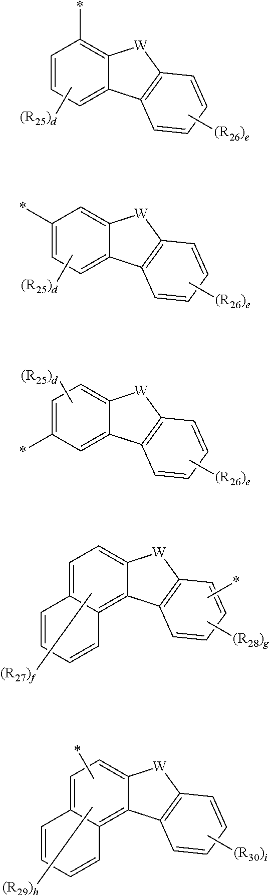

W is one selected from the group consisting of O; S; NR₃₁; CR₃₁R₃₂; and SiR₃₁R₃₂,
R₂₂ to R₃₂ and R′ are, each independently, one selected from the group consisting of hydrogen; deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group, and
a, c, e and i are, each independently, an integer of 1, 2, 3 or 4; b, d, g are, each independently, an integer of 1, 2 or 3; f is an integer of 1, 2, 3, 4, 5, or 6; and h is an integer of 1, 2, 3, 4, or 5.

In one embodiment of the present disclosure, some or all of the compound represented by Chemical Formula 1, the compound represented by Chemical Formula 4, or the compound represented by Chemical Formula 5 can be deuterated.

In one embodiment of the present disclosure, the organometallic compound represented by Chemical Formula 1 can have a homoleptic or heteroleptic structure, for example, have a homoleptic structure in which n is 0, a heteroleptic structure in which n is 1, or a heteroleptic structure in which n is 2 in Chemical Formula 1, and n can be, for example, 2.

In one embodiment of the present disclosure, n in Chemical Formula 1 can be one of integers from 0 to 2, and n can be, for example, 2.

In one embodiment of the present disclosure, m in Chemical Formula 1 can be 1 or more, for example, an integer of 1 to 3, and for example, an integer of 1 or 2.

In Chemical Formula 1, as m is 2 or 3 or n is 2, a plurality of substituents represented by the same symbol can be the same as or different from each other.

In some embodiments, L_{B} in Chemical Formula 1 may include an electron donor moiety to function as an electron donor auxiliary ligand. L_{B} as the electron donor auxiliary ligand may act to increase the electron density of the central coordination metal M in Chemical Formula 1, thereby reducing the energy of MLCT (metal to ligand charge transfer) and increasing a contribution ratio of ³MLCT to the Ti state. As a result, the organic light emitting diode including the organometallic compound represented by Chemical Formula 1 may achieve improved light emitting properties such as high luminous efficiency and high external quantum efficiency.

In some embodiments, L_{B} in Chemical Formula 1 may be represented by at least one structure selected from the group consisting of Chemical Formula 3-1, and Chemical Formula 3-2 below:

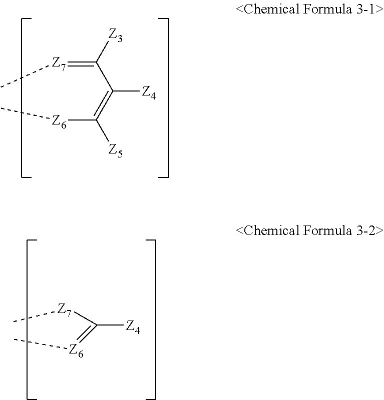

in Chemical Formula 3-1, and Chemical Formula 3-2,
   Z₃ to Z₅ are, each independently, one selected from the group consisting of hydrogen; deuterium; halogen; a hydroxyl group; a nitro group; an amidino group; a hydrazine group; a hydrazone group; a substituted or unsubstituted C1-C20 linear alkyl group; a substituted or unsubstituted C3-C20 branched alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
   Z₆ and Z₇ are, each independently, one selected from the group consisting of oxygen (O) and NR_{z}, and R_{z} is, each independently, one selected from the group consisting of hydrogen; a C1-C20 linear alkyl group; and a substituted or unsubstituted C3-C20 branched alkyl groups, and
   dotted line represents a connection position to the central coordination metal M.

In some embodiments, Z₃ and Z₅ may have the same structure. In some embodiments, at least one of Z₃ or Z₅ may be an unsubstituted C4 branched alkyl group, an unsubstituted C5 branched alkyl group, an unsubstituted C6 branched alkyl group. In some embodiments, Z₆ and Z₇ may have the same structure. In some embodiments, at least one of Z₆ or Z₇ may be NR_{z}, and R_{z} may be an isobutyl group. In some embodiments, Z₄ may be an isobutyl group.

In one embodiment, the compound represented by Chemical Formula 1 can be represented by a structure of one selected from the group consisting of Chemical Formula 1-1-(1), Chemical Formula 1-1-(2), Chemical Formula 1-1-(3). Chemical Formula 1-1-(4), Chemical Formula 1-1-(5), and Chemical Formula 1-1-(6), the compound represented by Chemical Formula 1-2 can be represented by a structure of one selected from the group consisting of Chemical Formula 1-2-(1), Chemical Formula 1-2-(2), Chemical Formula 1-2-(3), Chemical Formula 1-2-(4), Chemical Formula 1-2-(5), and Chemical Formula 1-2-(6), and the compound represented by Chemical Formula 1-3 can be represented by a structure of one selected from the group consisting of Chemical Formula 1-3-(1), Chemical Formula 1-3-(2), Chemical Formula 1-3-(3), Chemical Formula 1-3-(4), Chemical Formula 1-3-(5), and Chemical Formula 1-3-(6),

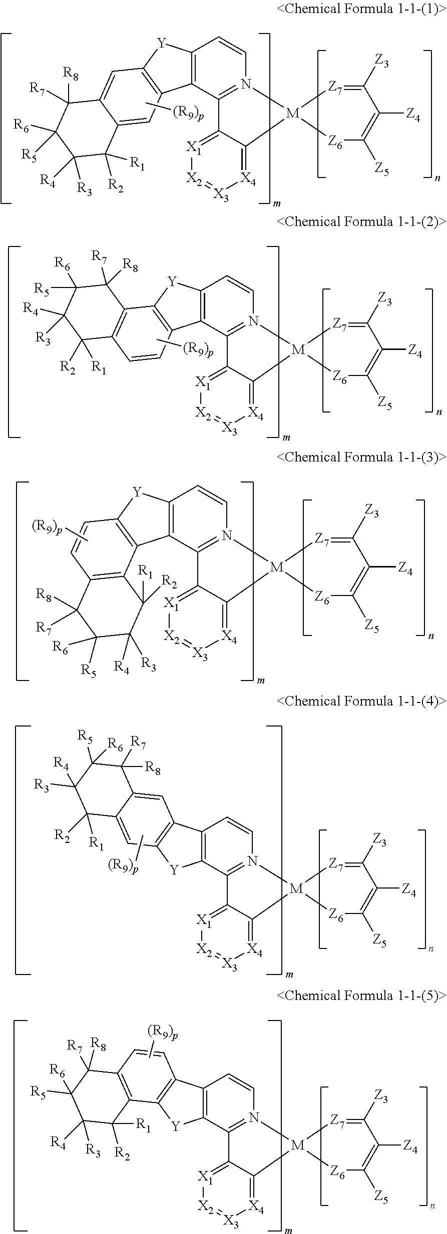

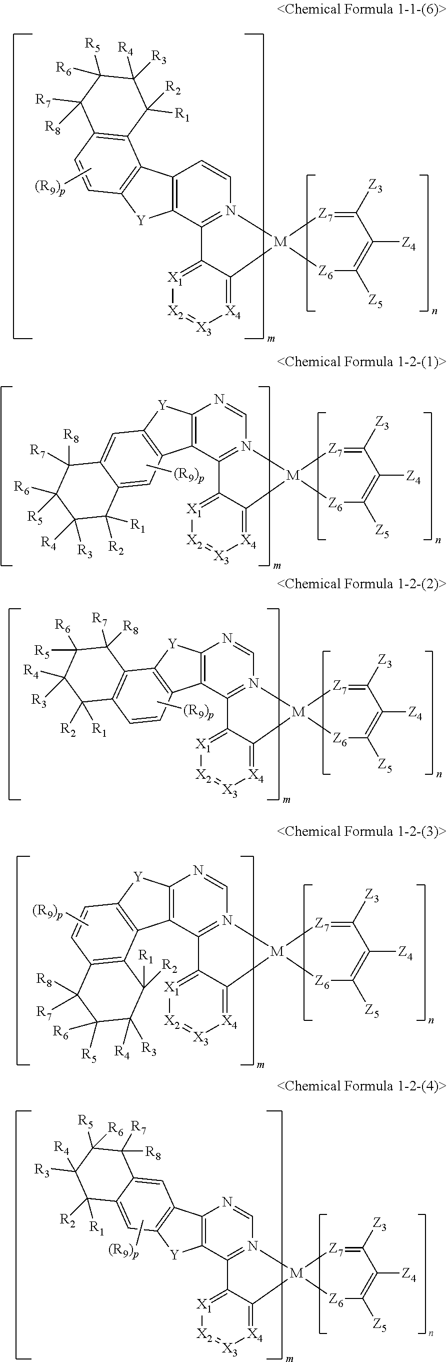

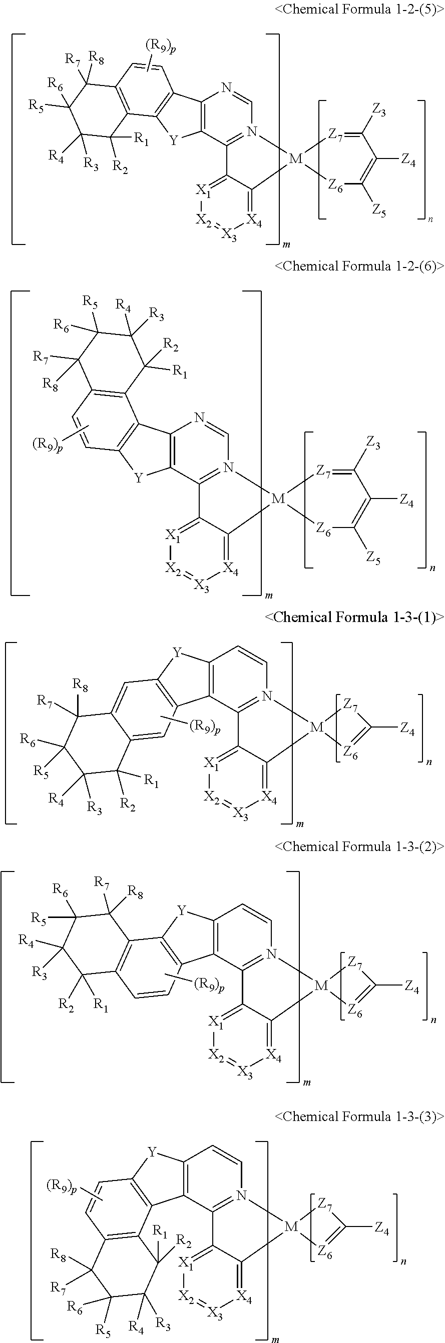

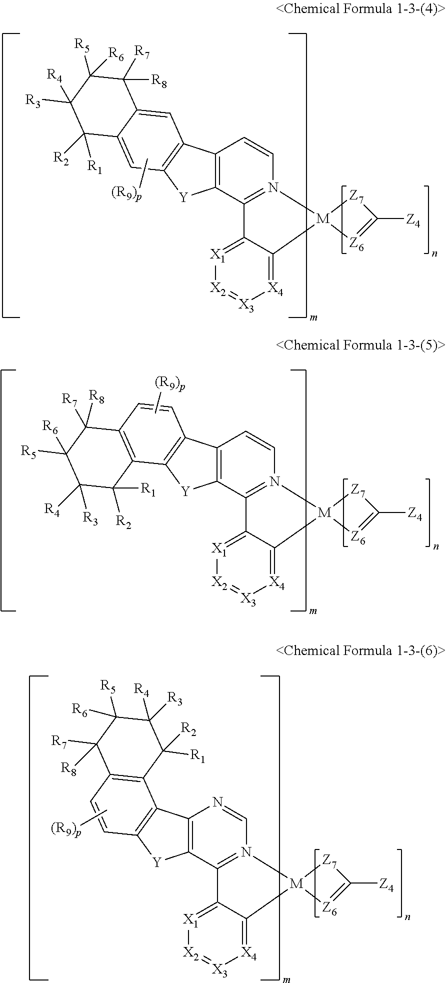

In Chemical Formula 1-1-(1), Chemical Formula 1-1-(2), Chemical Formula 1-1-(3), Chemical Formula 1-1-(4), Chemical Formula 1-1-(5), Chemical Formula 1-1-(6), Chemical Formula 1-2-(1), Chemical Formula 1-2-(2), Chemical Formula 1-2-(3), Chemical Formula 1-2-(4), Chemical Formula 1-2-(5), Chemical Formula 1-2-(6), Chemical Formula 1-3-(1), Chemical Formula 1-3-(2), Chemical Formula 1-3-(3), Chemical Formula 1-3-(4), Chemical Formula 1-3-(5), and Chemical Formula 1-3-(6),

M, X₁ to X₄, Y, R₁ to R₉, p, m, and n are same as defined in Chemical Formula 1, and
Z₃ to Z₇ are as defined in Chemical Formula 3-1, and Chemical Formula 3-2.

In one embodiment of the present disclosure, in Chemical Formula 2, A can have a pyridine ring structure.

In one embodiment of the present disclosure, M in Chemical Formula 1 can be iridium (Ir).

In one embodiment of the present disclosure, Y in Chemical Formula 2 can be any one of oxygen (O), sulfur (S), and selenium (Se).

In one embodiment of the present disclosure, at least one of R₉ in Chemical Formula 2 may not be hydrogen.

In one embodiment of the present disclosure, R₁₀ to R₁₂ in Chemical Formula 2 can, each independently, be at least one selected from the group consisting of hydrogen; deuterium; halogen; a nitrile group; a nitro group; a substituted or unsubstituted C1-C20 alkoxy group; an amino group; a substituted or unsubstituted C1-C10 linear alkyl group; a substituted or unsubstituted C3-C10 branched alkyl group; and a substituted or unsubstituted C3-C10 cycloalkyl group.

According to one embodiment of the present disclosure, the organometallic compound represented by Chemical Formula 1 can be one of Compounds RD-1 to RD-20 below, but is not limited thereto as long as it is included in the definition of Chemical Formula 1.

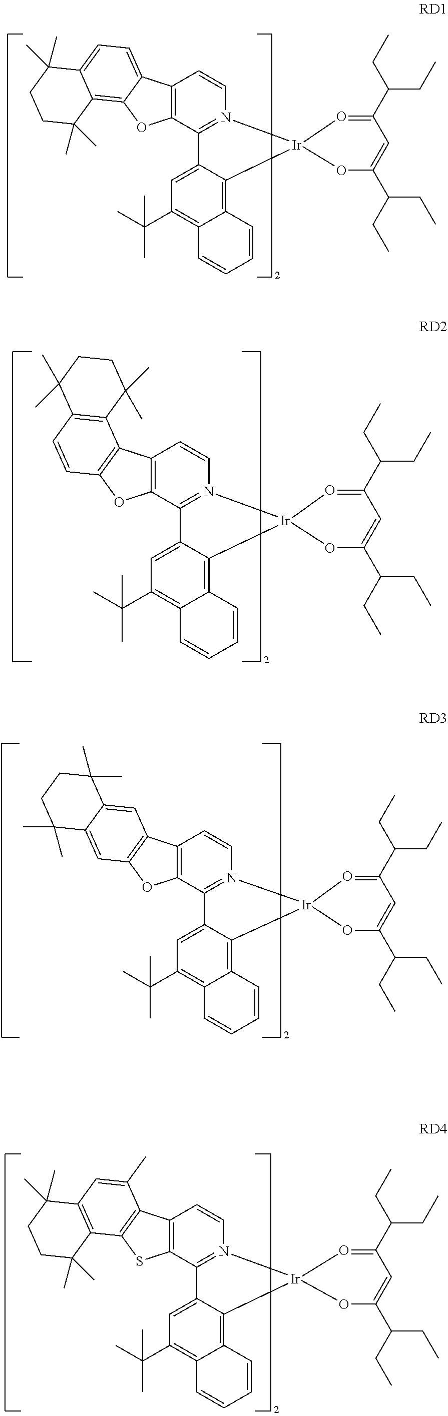

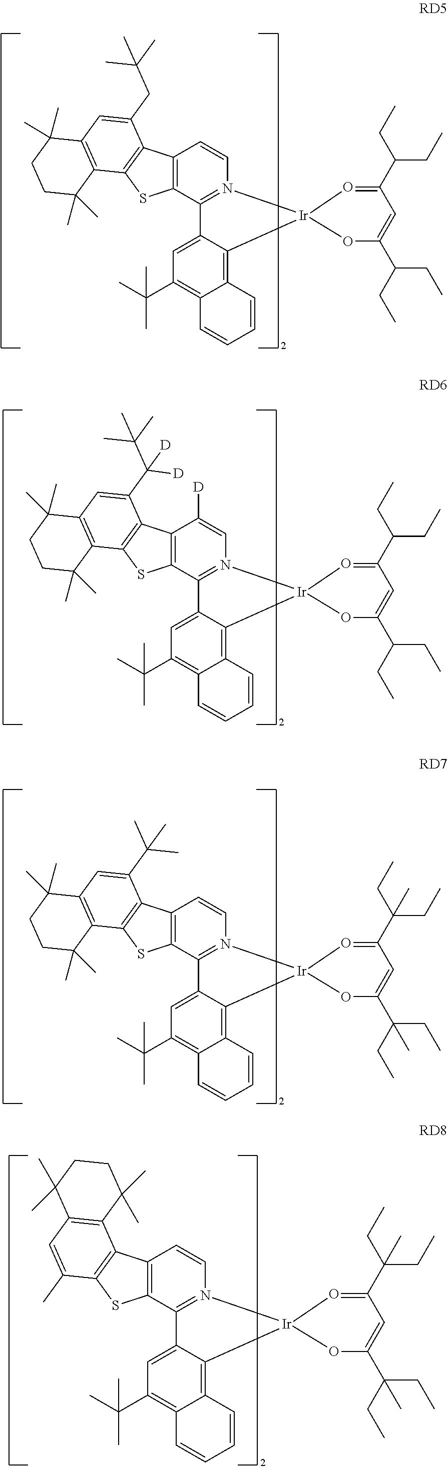

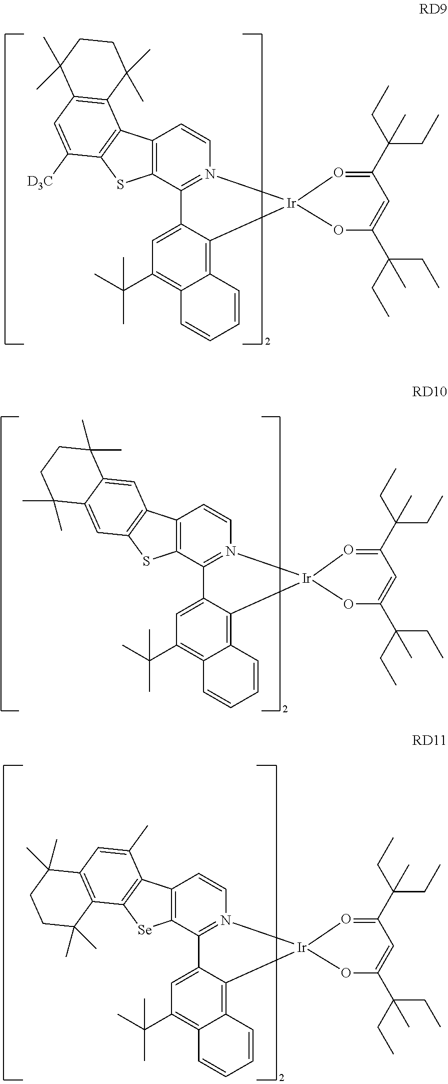

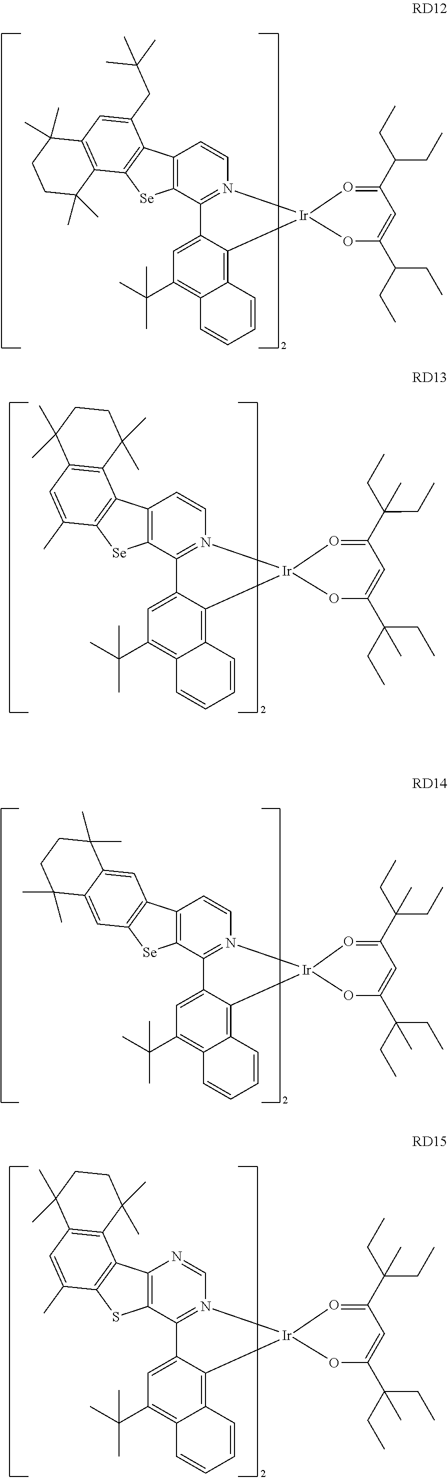

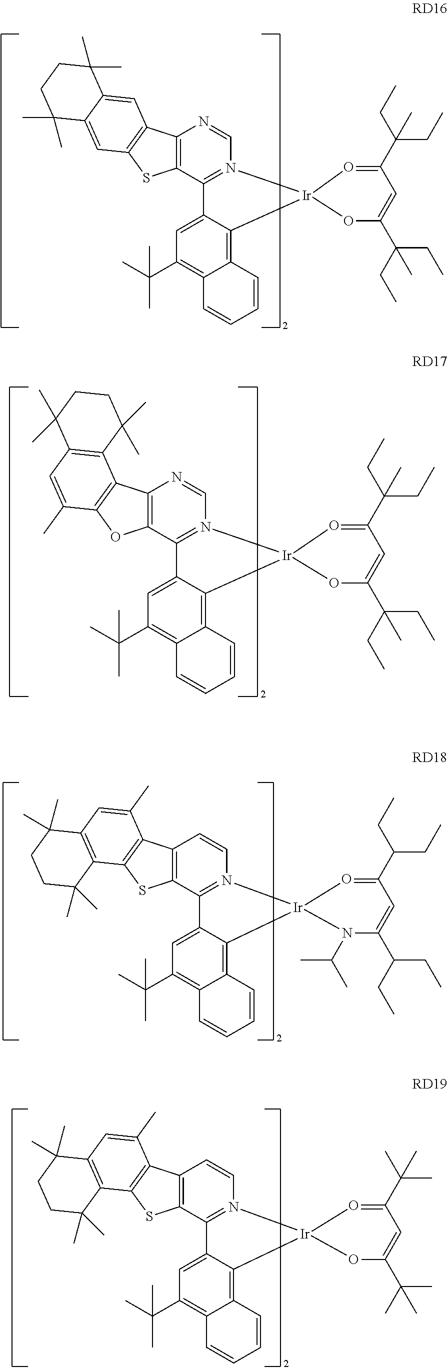

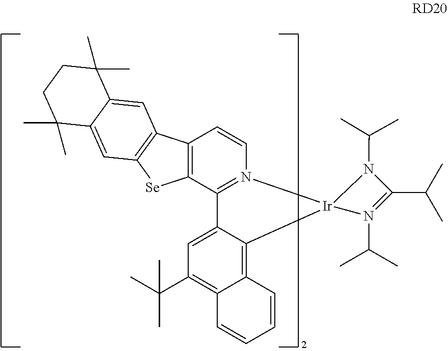

In one embodiment of the present disclosure, in Chemical Formula 4, Ar₁ and Ar₂ are, each independently, one monovalent group selected from the group consisting of substituted or unsubstituted benzene; substituted or unsubstituted biphenyl; substituted or unsubstituted naphthalene; substituted or unsubstituted phenanthrene; substituted or unsubstituted fluorene; substituted or unsubstituted dibenzofuran; substituted or unsubstituted dibenzothiophene; and substituted or unsubstituted spirobifluorene, and at least one hydrogen in any one of Ar₁ and Ar₂ can be substituted with at least one selected from the group consisting of deuterium; halogen atom; a C1-C10 alkyl group; a C6-C20 aryl group; a C2-C20 heteroaryl group; a nitrile group; a silyl group; and combinations thereof.

In one embodiment of the present disclosure, the compound represented by Chemical Formula 4 can be one selected from the group consisting of Compounds RHH-1 to RHH-20 below and is not limited thereto as long as it falls within the definition of Chemical Formula 4.

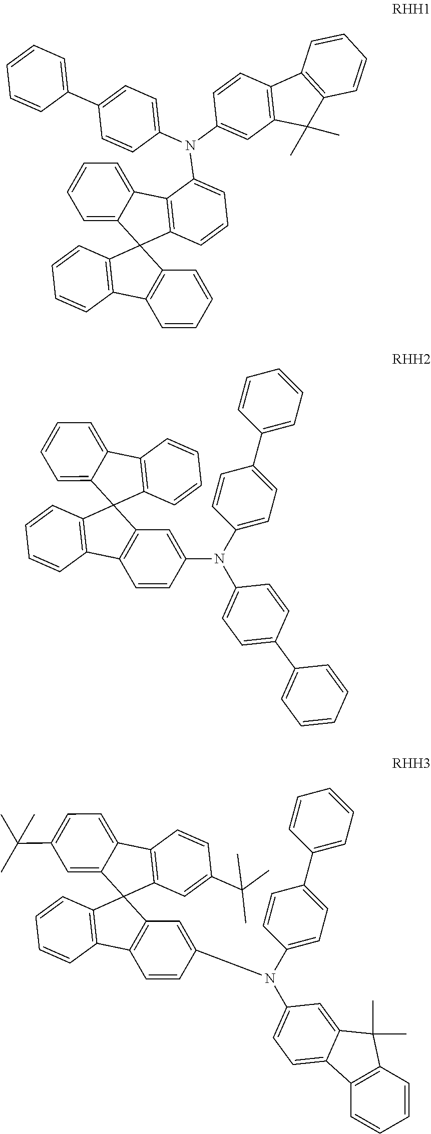 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc4c(c3)C3(c5ccccc5-c5ccccc53)c3ccccc3-4)cc2)cc1 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

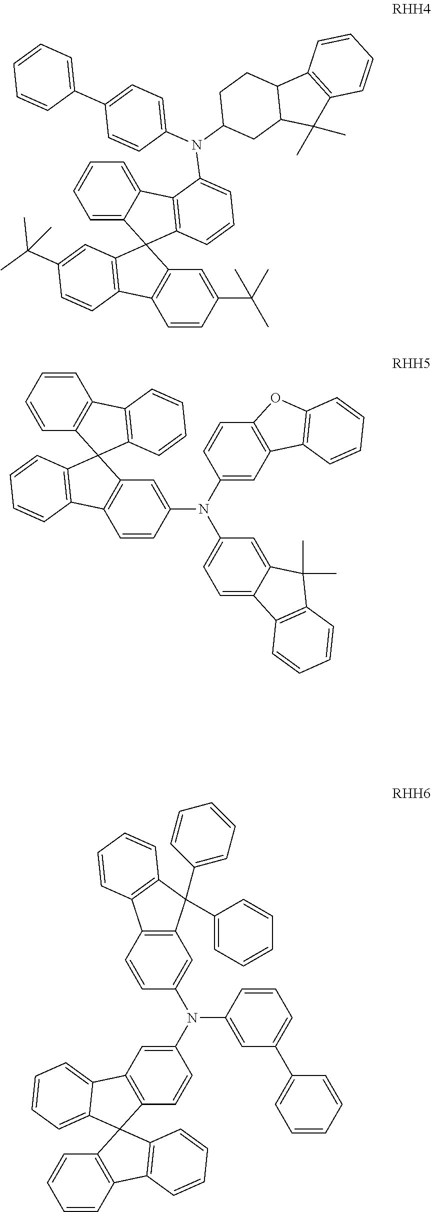 [SMILES: CC(C)(C)c1ccc2c(c1)C1(c3cc(C(C)(C)C)ccc3-2)c2ccccc2-c2c(N(c3ccc(-c4ccccc4)cc3)C3CCC4c5ccccc5C(C)(C)C4C3)cccc21 ; CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1]

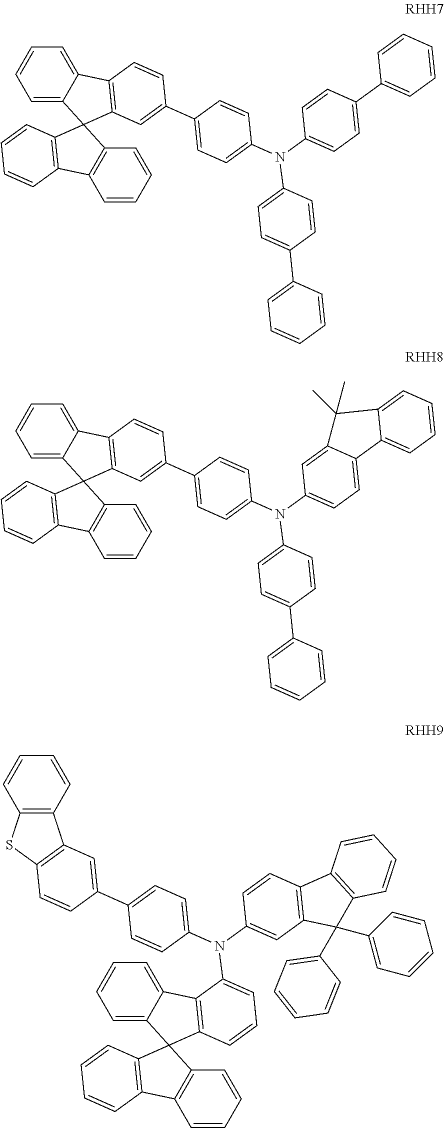 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1]

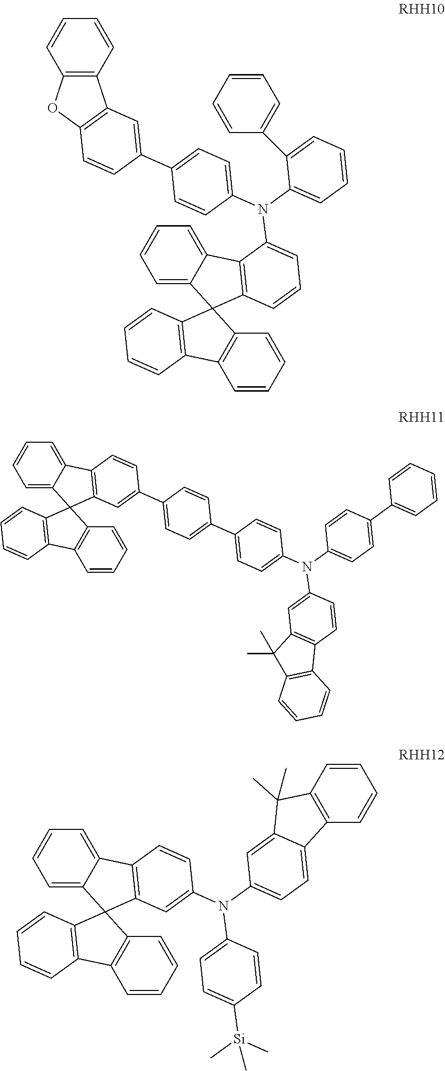 [SMILES: c1ccc(-c2ccccc2N(c2ccc(-c3ccc4oc5ccccc5c4c3)cc2)c2cccc3c2-c2ccccc2C32c3ccccc3-c3ccccc32)cc1 ; CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21 ; CC1(C)c2ccccc2-c2ccc(N(c3ccc([Si](C)(C)C)cc3)c3ccc4c(c3)C3(c5ccccc5-c5ccccc53)c3ccccc3-4)cc21]

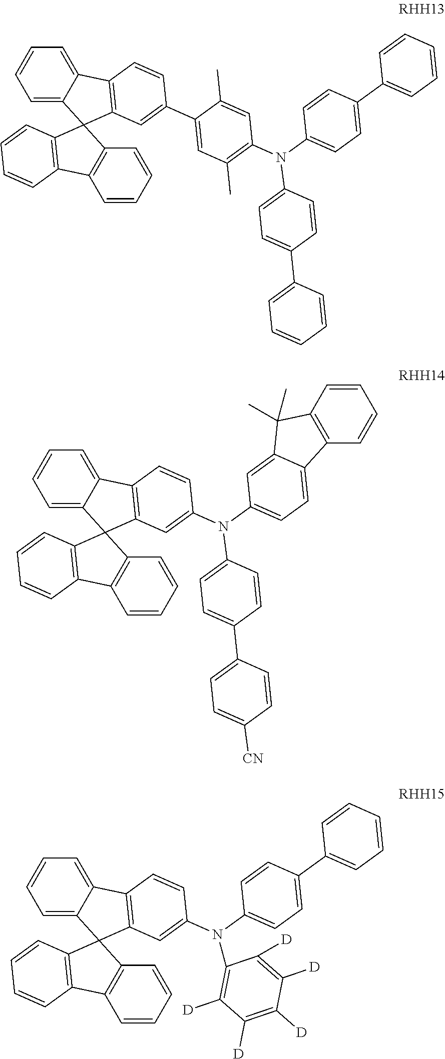

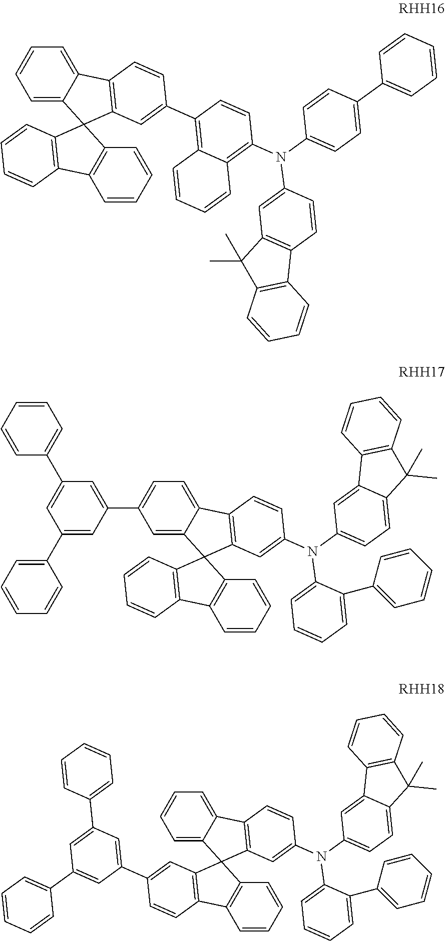 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21 ; CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21]

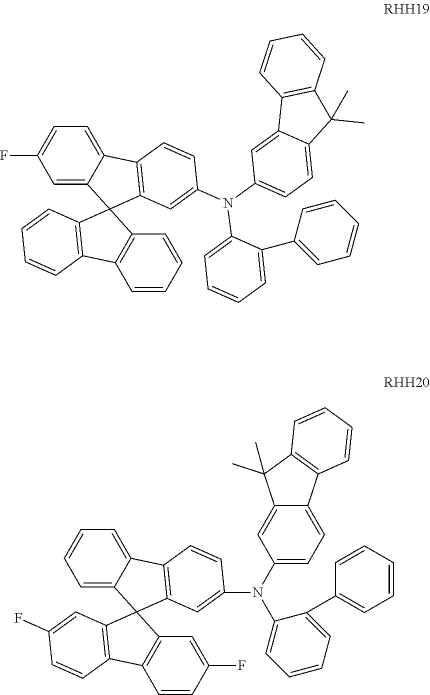 [SMILES: CC1(C)c2ccccc2-c2cc(N(c3ccc4c(c3)C3(c5ccccc5-c5ccccc53)c3cc(F)ccc3-4)c3ccccc3-c3ccccc3)ccc21 ; CC1(C)c2ccccc2-c2ccc(N(c3ccc4c(c3)C3(c5ccccc5-4)c4cc(F)ccc4-c4ccc(F)cc43)c3ccccc3-c3ccccc3)cc21]

In one embodiment of the present disclosure, in Chemical Formula 5, X₁₁ and X₁₂ can be N.

In one embodiment of the present disclosure, the compound represented by Chemical Formula 5 can be one selected from the group consisting of Compounds REH-1 to REH-20 below and is not limited thereto as long as it falls within the definition of Chemical Formula 5.

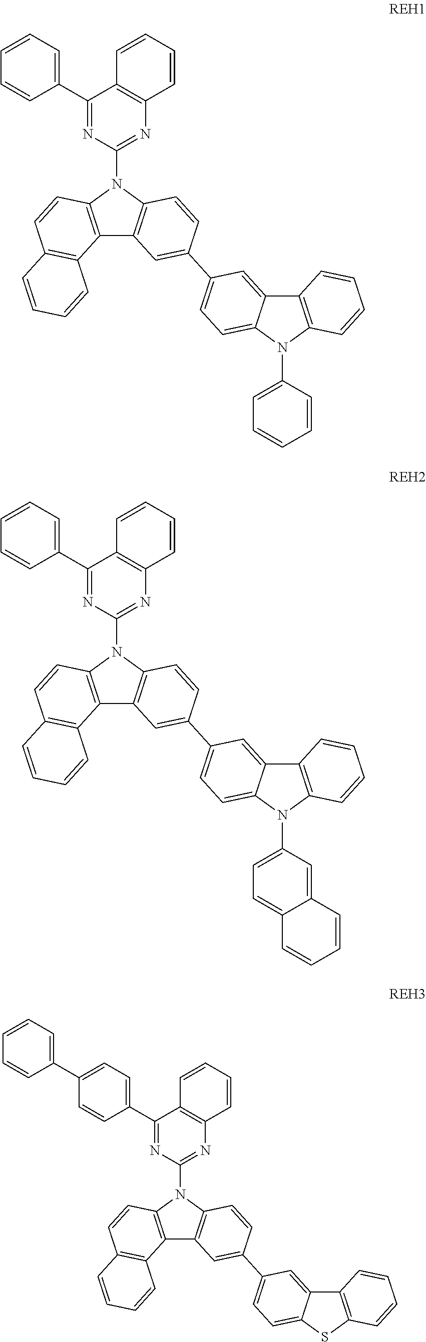 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

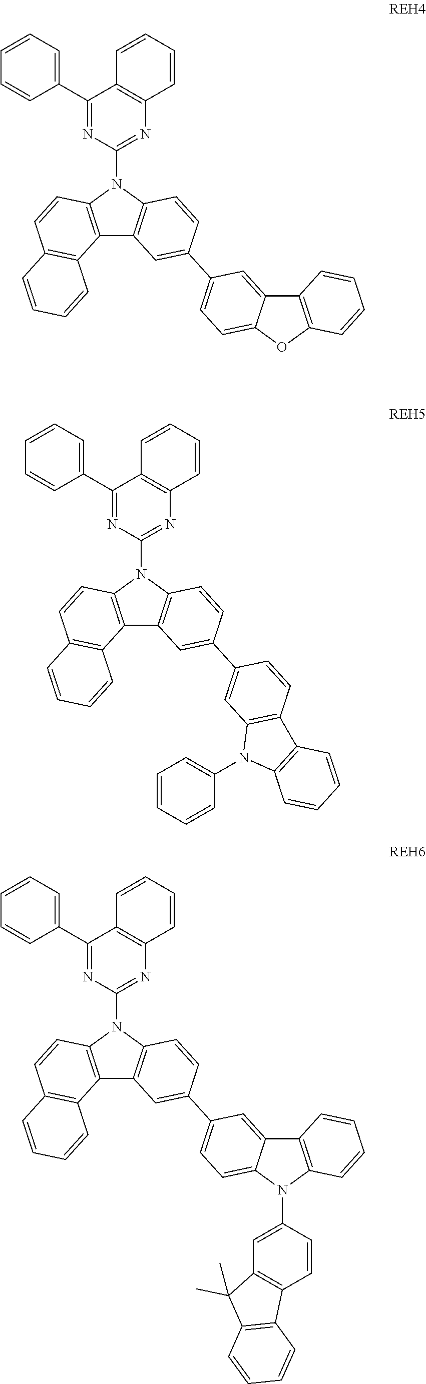 [SMILES: c1ccc(-c2nc(-n3c4ccc(-c5ccc6oc7ccccc7c6c5)cc4c4c5ccccc5ccc43)nc3ccccc23)cc1 ; c1ccc(-c2nc(-n3c4ccc(-c5ccc6c7ccccc7n(-c7ccccc7)c6c5)cc4c4c5ccccc5ccc43)nc3ccccc23)cc1 ; CC1(C)c2ccccc2-c2ccc(-n3c4ccccc4c4cc(-c5ccc6c(c5)c5c7ccccc7ccc5n6-c5nc(-c6ccccc6)c6ccccc6n5)ccc43)cc21]

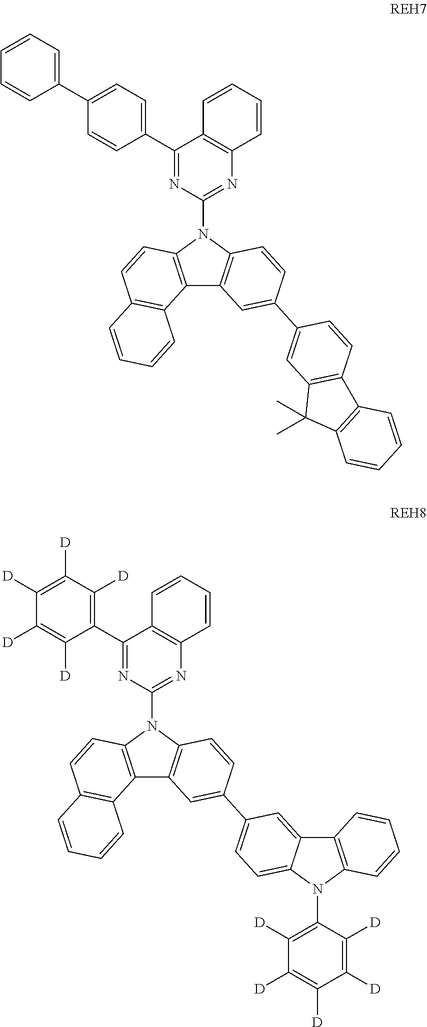 [SMILES: CC1(C)c2ccccc2-c2ccc(-c3ccc4c(c3)c3c5ccccc5ccc3n4-c3nc(-c4ccc(-c5ccccc5)cc4)c4ccccc4n3)cc21 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H]]

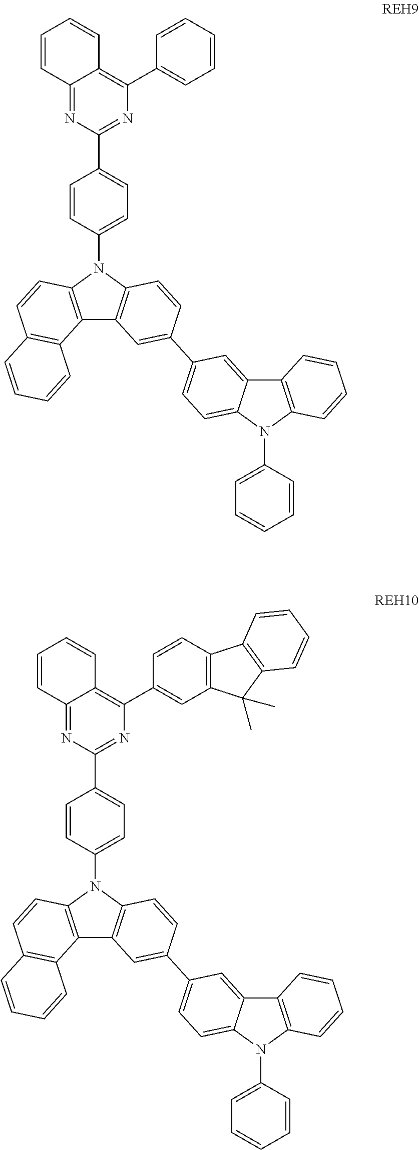 [SMILES: c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1 ; CC1(C)c2ccccc2-c2ccc(-c3nc(-c4ccc(-n5c6ccc(-c7ccc8c(c7)c7ccccc7n8-c7ccccc7)cc6c6c7ccccc7ccc65)cc4)nc4ccccc34)cc21]

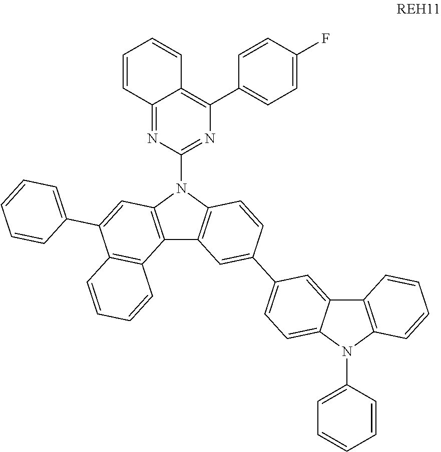 [SMILES: Fc1ccc(-c2nc(-n3c4ccc(-c5ccc6c(c5)c5ccccc5n6-c5ccccc5)cc4c4c5ccccc5c(-c5ccccc5)cc43)nc3ccccc23)cc1]

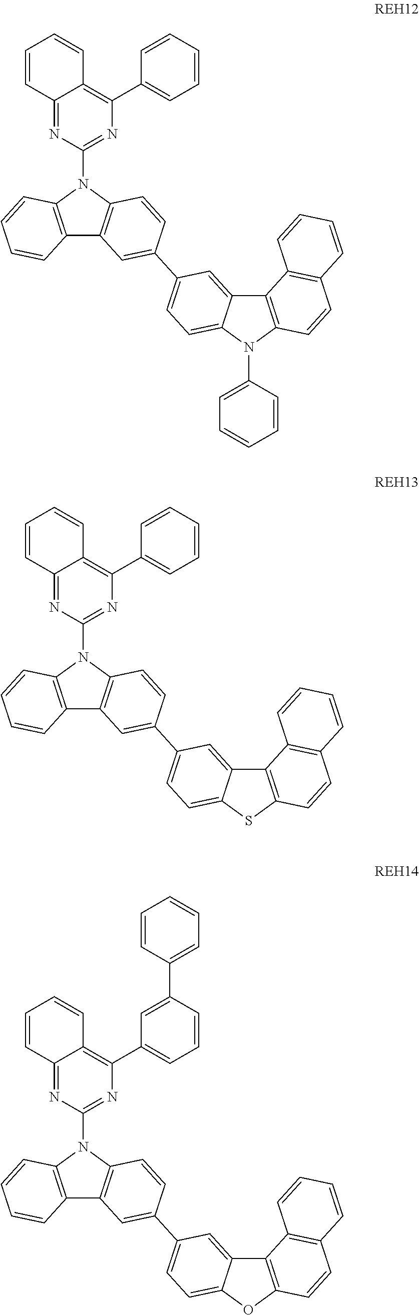 [SMILES: c1ccc(-c2nc(-n3c4ccccc4c4cc(-c5ccc6c(c5)c5c7ccccc7ccc5n6-c5ccccc5)ccc43)nc3ccccc23)cc1 ; c1ccc(-c2nc(-n3c4ccccc4c4cc(-c5ccc6sc7ccc8ccccc8c7c6c5)ccc43)nc3ccccc23)cc1 ; c1ccc(-c2cccc(-c3nc(-n4c5ccccc5c5cc(-c6ccc7oc8ccc9ccccc9c8c7c6)ccc54)nc4ccccc34)c2)cc1]

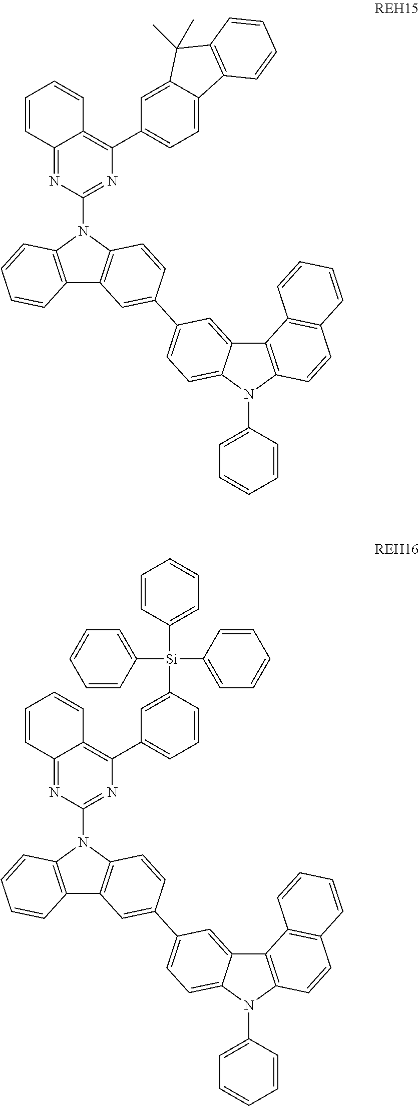 [SMILES: CC1(C)c2ccccc2-c2ccc(-c3nc(-n4c5ccccc5c5cc(-c6ccc7c(c6)c6c8ccccc8ccc6n7-c6ccccc6)ccc54)nc4ccccc34)cc21 ; c1ccc(-n2c3ccc(-c4ccc5c(c4)c4ccccc4n5-c4nc(-c5cccc([Si](c6ccccc6)(c6ccccc6)c6ccccc6)c5)c5ccccc5n4)cc3c3c4ccccc4ccc32)cc1]

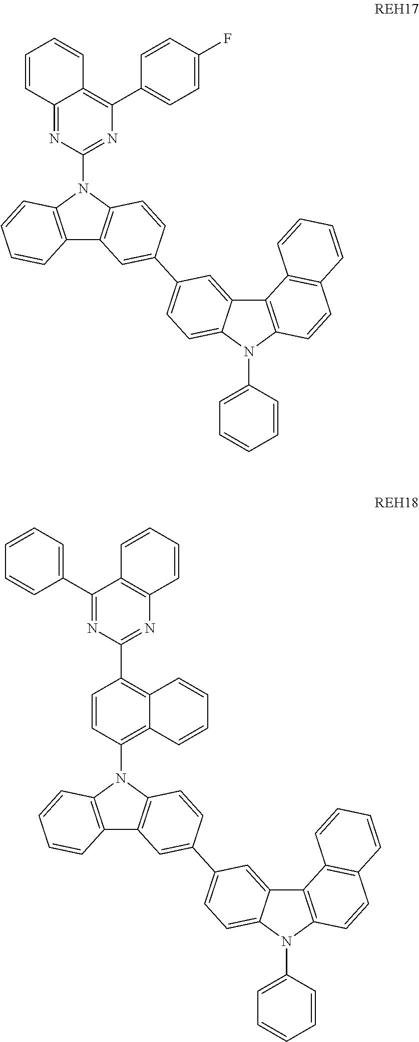 [SMILES: Fc1ccc(-c2nc(-n3c4ccccc4c4cc(-c5ccc6c(c5)c5c7ccccc7ccc5n6-c5ccccc5)ccc43)nc3ccccc23)cc1 ; c1ccc(-c2nc(-c3ccc(-n4c5ccccc5c5cc(-c6ccc7c(c6)c6c8ccccc8ccc6n7-c6ccccc6)ccc54)c4ccccc34)nc3ccccc23)cc1]

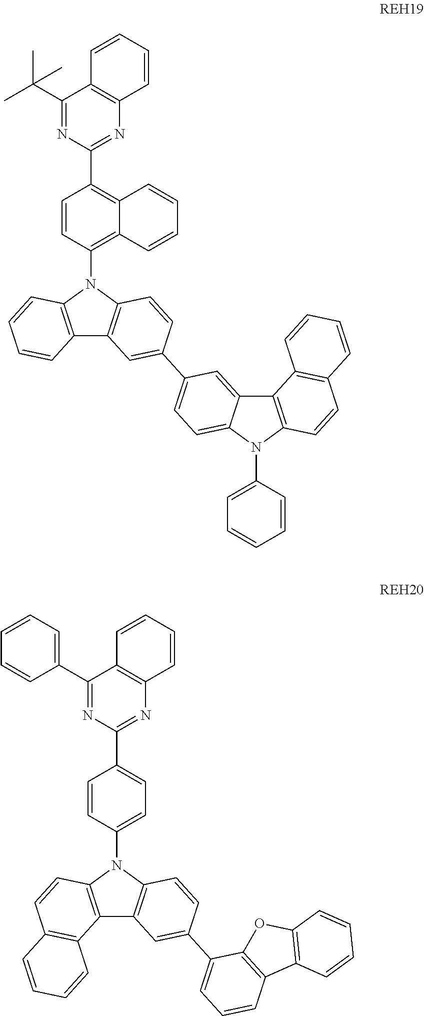 [SMILES: CC(C)(C)c1nc(-c2ccc(-n3c4ccccc4c4cc(-c5ccc6c(c5)c5c7ccccc7ccc5n6-c5ccccc5)ccc43)c3ccccc23)nc2ccccc12 ; c1ccc(-c2nc(-c3ccc(-n4c5ccc(-c6cccc7c6oc6ccccc67)cc5c5c6ccccc6ccc54)cc3)nc3ccccc23)cc1]

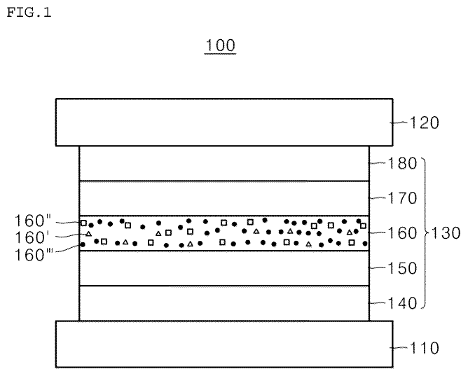

Specifically, referring to FIG. 1 according to one embodiment of the present disclosure, there can be provided an organic light emitting diode 100 including a first electrode 110, a second electrode 120 facing the first electrode 110, and an intermediate layer 130 disposed between the first electrode 110 and the second electrode 120. The intermediate layer 130 can include an emission material layer 160, the emission material layer 160 can include a dopant material 160′ and host materials 160″ and 160″′ and include the organometallic compound 160′ represented by Chemical Formula 1 below as the dopant material, and the host material can include two types of the compound 160″ represented by Chemical Formula 4 below as the hole transport type host and the compound 160″′ represented by Chemical Formula 5 below as the electron transport type host.

In addition, in the organic light emitting diode 100, the intermediate layer 130 disposed between the first electrode 110 and the second electrode 120 can have a structure including a hole injection layer (HIL) 140, a hole transport layer (HTL) 150, the emission material layer (EML) 160, an electron transport layer (ETL) 170, and an electron injection layer (EIL) 180 sequentially from the first electrode 110. The second electrode 120 can be formed on the electron injection layer 180, and a protective film can also be formed on the second electrode 120.

In addition, with reference to FIG. 1, one or more of a hole transport auxiliary layer and an electron blocking layer can be further added between the hole transport layer 150 and the emission material layer 160.

The hole transport auxiliary layer can contain a compound with good hole transport characteristics and adjust the hole injection characteristics by reducing a HOMO energy level difference between the hole transport layer 150 and the emission material layer 160, thereby reducing the accumulation of holes at an interface between the hole transport auxiliary layer and the emission material layer 160. Therefore, it is possible to reduce a quenching phenomenon that excitons are annihilated by polarons at the interface. Therefore, it is possible to reduce a degradation phenomenon of the element, thereby stabilizing the element and increasing efficiency and lifetime thereof.

The electron blocking layer can prevent the introduction of electrons into the hole transport layer by adjusting the movement of electrons and the recombination with holes, thereby increasing the efficiency and lifetime of the OLED. A material forming the electron blocking layer can be selected from TCTA, tris [4-(diethylamino) phenyl]amine, N-(biphenyl-4-yl)-9, 9-dimethyl-N-(4-(9-phenyl-9H-carbazol-3-yl) phenyl)-9H-fluoren-2-amine, TAPC, MTDATA, mCP, mCBP, CuPC, DNTPD, TDAPB, DCDPA, 2,8-bis(9-phenyl-9H-carbazol-3-yl)dibenzo[b,d]thiophene, and the like. In addition, the electron blocking layer can include an inorganic compound. The inorganic compound can be selected from halide compounds, such as LiF, NaF, KF, RbF, CsF, FrF, MgF₂, CaF₂, SrF₂, BaF₂, LiCl, NaCl, KCl, RbCl, CsCl, and FrCl, and oxides, such as Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K₂SiO₃, B₂O₅, Al₂O₃, and SiO₂, but is not necessarily limited thereto.

The first electrode 110 can be an anode and can be made of ITO, IZO, tin-oxide, or zinc-oxide, which is a conductive material with a relatively high work function value, but is not limited thereto.

The second electrode 120 can be a cathode and can include Al, Mg, Ca, Ag, or an alloy or combination thereof, which is a conductive material with a relatively low work function value, but is not limited thereto.

The hole injection layer 140 can be positioned between the first electrode 110 and the hole transport layer 150. The hole injection layer 140 can have a function of improving the interface characteristics between the first electrode 110 and the hole transport layer 150 and can be selected as a material with appropriate conductivity. The hole injection layer 140 can include a compound, such as MTDATA, CuPc, TCTA, HATCN, TDAPB, PEDOT/PSS, or N1,N1′-([1,1′-biphenyl]-4,4′-diyl)bis(N1,N4,N4-triphenylbenzene-1,4-diamine), preferably, N1, N1′-([1, 1′-biphenyl]-4, 4′-diyl)bis (N1,N4,N4-triphenylbenzene-1, 4-diamine), but is not limited thereto.

The hole transport layer 150 can be positioned adjacent the emission material layer between the first electrode 110 and the emission material layer 160. The hole transport layer 150 can include a compound, such as TPD, NPB, CBP, N-(biphenyl-4-yl)-9,9-dimethyl-N-(4-9-phenyl-9H-carbazol-3-yl)phenyl)-9H-fluoren-2-amine, or N-biphenyl-4-yl)-N-4-9-phenyl-9H-carbazol-3-yl)phenyl)biphenyl)-4-amine, preferably, NPB, but is not limited thereto.

According to one embodiment of the present disclosure, the emission material layer 160 can be formed by being doped with the organometallic compound represented by Chemical Formula 1 as the dopant 160′ to increase the luminous efficiency and the like of the hosts 160″ and 160″′ and the element, and the dopant 160′ can be used as a material that emits light of green or red and for example, used as a red phosphorescent material.

According to one embodiment of the present disclosure, a doping concentration of the dopant 160′ can be adjusted in the range of 1 to 30 wt % based on the total weight of the two types of hosts 160″ and 160″′ and is not limited thereto, but for example, the doping concentration can be 2 to 20 wt %, for example, 3 to 15 wt %, for example, 5 to 10 wt %, for example, 3 to 8 wt %, for example, 2 to 7 wt %, for example, 5 to 7 wt %, and for example, 5 to 6 wt %.

According to one embodiment of the present disclosure, a mixing ratio of the two types of hosts 160″ and 160″′ is not particularly limited, and the host 160″, which is the compound represented by Chemical Formula 4, can have the hole transport characteristics and the host 160″′, which is the compound represented by Chemical Formula 5, can have the electron transport characteristics. Therefore, when the two types of hosts are mixed, it is possible to increase the lifetime characteristics, and the mixing ratio of the two types of hosts can be adjusted appropriately. Therefore, the mixing ratio of the two hosts in which the compound represented by Chemical Formula 4 and the compound represented by Chemical Formula 5 are mixed is not particularly limited, and the ratio (based on the weight) of the compound represented by Chemical Formula 4 and the compound represented by Chemical Formula 5 can be, for example, in the range of 1:9 to 9:1, for example, 2:8, for example, 3:7, for example, 4:6, for example, 5:5, for example, 6:4, for example 7:3, and for example, 8:2.

In addition, the electron transport layer 170 and the electron injection layer 180 can be sequentially stacked between the emission material layer 160 and the second electrode 120. A material of the electron transport layer requires high electron mobility, and electrons can be stably supplied to the emission material layer through smooth electron transport.

For example, the material of the electron transport layer 170 is used in the art and can include, for example, a compound, such as Alq₃ (tris (8-hydroxyquinolino) aluminum), Liq (8-hydroxyquinolinolatolithium), PBD (2-(4-biphenylyl)-5-(4-tert-butylphenyl)-1, 3, 4oxadiazole), TAZ (3-(4-biphenyl) 4-phenyl-5-tert-butylphenyl-1, 2, 4-triazole), spiro-PBD, BAlq (bis(2-methyl-8-quinolinolate)-4-(phenylphenolato) aluminium), SAlq, TPBi (2,2′, 2-(1,3,5-benzinetriyl)-tris(1-phenyl-1-H-benzimidazole), oxadiazole, triazole, phenanthroline, benzoxazole, benzthiazole, or 2-(4-(9, 10-di(naphthalen-2-yl)anthracen-2-yl)phenyl)-1-phenyl-1H-benzo [d]imidazole, preferably, 2-(4-(9, 10-di (naphthalen)-2-yl)anthracen-2-yl)phenyl)-1-phenyl-1H-benzo[d]imidazole, but is not limited thereto.

The electron injection layer 180 serves to allow electrons to be smoothly injected, and a material of the electron injection layer is used in the art and can include, for example, Alq₃ (tris(8-hydroxyquinolino) aluminum), PBD, TAZ, spiro-PBD, BAlq, SAlq, or the like, but is not limited thereto. Alternatively, the electron injection layer 180 can be made of a metal compound, and the metal compound can include, for example, Liq, LiF, NaF, KF, RbF, CsF, FrF, BeF₂, MgF₂, CaF₂, SrF₂, BaF₂, RaF₂, or the like, but is not limited thereto.

The OLED according to the present disclosure can be a white OLED with a tandem structure. In the tandem OLED according to one embodiment of the present disclosure, a single light emitting stack (or a light emitting part) can be formed in a structure in which two or more light emitting stacks (or light emitting parts) are connected by the charge generation layer CGL. The OLED can include two or more light emitting stacks (light emitting parts), which include the first and second electrodes that face each other on the substrate and the emission material layer stacked between the first and second electrodes to emit light in a specific wavelength band. The plurality of light emitting stacks (light emitting parts) can be applied to emit the same color or different colors. In addition, one light emitting stack (light emitting part) can include one or more emission material layers, and the plurality of light emitting layers can be light emitting layers of the same color or different colors.

In this case, one or more of the emission material layers included in the plurality of light emitting parts can include the organometallic compound represented by Chemical Formula 1 according to the present disclosure as a dopant material. The plurality of light emitting parts in the tandem structure can be connected to the charge generation layer CGL formed of an N-type charge generation layer and a P-type charge generation layer.

According to one embodiment of the present disclosure, there is provided an organic light emitting diode including:
a first electrode;
a second electrode facing the first electrode; and
one or more light emitting parts positioned between the first electrode and the second electrode,
wherein at least one of the light emitting parts includes a red phosphorescent layer,
the red phosphorescent layer includes a dopant material and a host material,
the dopant material includes the organometallic compound represented by Chemical Formula 1, and
the host material includes a mixture of the compound represented by Chemical Formula 4 and the compound represented by Chemical Formula 5.

Detailed descriptions of the first electrode, the second electrode, the organometallic compound represented by Chemical Formula 1, the compound represented by Chemical Formula 4, and the compound represented by Chemical Formula 5 are as described above.

The OLED can have a structure in which a plurality of light emitting parts are present between the first electrode and the second electrode and the light emitting parts are connected by charge generation layers disposed between the plurality of light emitting parts.

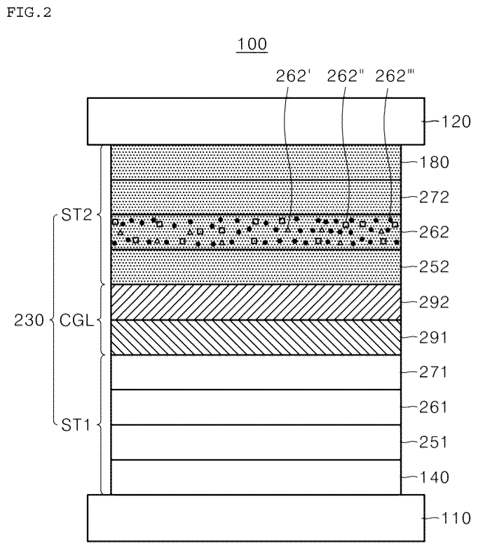

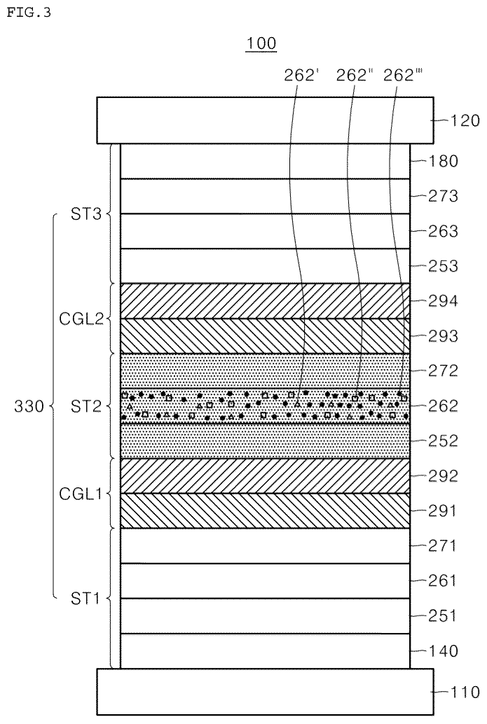

FIGS. 2 and 3, which show one or more embodiments of the present disclosure, are cross-sectional views schematically showing OLEDs in tandem structures having two light emitting parts and three light emitting parts, respectively.

As shown in FIG. 2, the organic light emitting diode 100 of the present disclosure includes the first electrode 110 and the second electrode 120 that face each other, and an intermediate layer 230 positioned between the first electrode 110 and the second electrode 120. The intermediate layer 230 includes a first light emitting part ST1 positioned between the first electrode 110 and the second electrode 120 and including a first emission material layer 261, a second light emitting part ST2 positioned between the first light emitting part ST1 and the second electrode 120 and including a second emission material layer 262, and the charge generation layer CGL positioned between the first and second light emitting parts ST1 and ST2. The charge generation layer CGL can include an N-type charge generation layer 291 and a P-type charge generation layer 292. One or more of the first emission material layer 261 and the second emission material layer 262 can include the organometallic compound represented by Chemical Formula 1 according to the present disclosure as a dopant 262′. For example, as shown in FIG. 2, the second emission material layer 262 of the second light emitting part ST2 can contain the compound 262′ represented by Chemical Formula 1 as the dopant, a compound 262″ represented by Chemical Formula 4 as the hole transport type host, and a compound 262″′ represented by Chemical Formula 5 as an electron transport type host. With reference to FIG. 2, each of the first and second light emitting parts ST1 and ST2 can further include an additional emission material layer in addition to the first emission material layer 261 and the second emission material layer 262. The contents described above in relation to the hole transport layer 150 of FIG. 1 can be applied to the first hole transport layer 251 and the second hole transport layer 252 of FIG. 2 in the same or similar manner. In addition, the contents described above in relation to the electron transport layer 170 of FIG. 1 can be applied to the first electron transport layer 271 and the second electron transport layer 272 of FIG. 2 in the same or similar manner.

As shown in FIG. 3, the organic light emitting diode 100 of the present disclosure includes the first electrode 110 and the second electrode 120 that face each other, and an intermediate layer 330 positioned between the first electrode 110 and the second electrode 120. The intermediate layer 330 includes the first light emitting part ST1 positioned between the first electrode 110 and the second electrode 120 and including the first emission material layer 261, the second light emitting part ST2 including the second emission material layer 262, a third light emitting part ST3 including a third emission material layer 263, a first charge generation layer CGL1 positioned between the first and second light emitting parts ST1 and ST2, and a second charge generation layer CGL2 positioned between the second and third light emitting parts ST2 and ST3. The first and second charge generation layers CGL1 and CGL2 can include the N-type charge generation layers 291 and 293 and the P-type charge generation layers 292 and 294, respectively. One or more of the first emission material layer 261, the second emission material layer 262, and the third emission material layer 263 can include the organometallic compound represented by Chemical Formula 1 according to the present disclosure as the dopant. For example, as shown in FIG. 3, the second emission material layer 262 of the second light emitting part ST2 can contain the compound 262′ represented by Chemical Formula 1 as the dopant, the compound 262″ represented by Chemical Formula 4 as the hole transport type host, and the compound 262″′ represented by Chemical Formula 5 as the electron transport type host. With reference to FIG. 3, in addition to the first emission material layer 261, the second emission material layer 262, and the third emission material layer 263, each of the first, second, and third light emitting parts ST1, ST2, and ST3 can be formed as a plurality of emission material layers by including an additional emission material layer. The contents described above in relation to the hole transport layer 150 of FIG. 1 can be applied to the first hole transport layer 251, the second hole transport layer 252, and the third hole transport layer 253 of FIG. 3 in the same or similar manner. In addition, the contents described above in relation to the electron transport layer 170 of FIG. 1 can be applied to the first electron transport layer 271, the second electron transport layer 272, and the third electrode transport layer 273 of FIG. 3 in the same or similar manner.

Furthermore, the OLED according to one embodiment of the present disclosure can include a tandem structure in which four or more light emitting parts and three or more charge generation layers are disposed between the first electrode and the second electrode.

The OLED according to the present disclosure can be used in OLED display devices and lighting devices using OLEDs.

According to one embodiment of the present disclosure, there is provided an organic light emitting diode display device including:
a substrate;
a driving element positioned on the substrate; and
the organic light emitting diode positioned on the substrate and connected to the driving element.

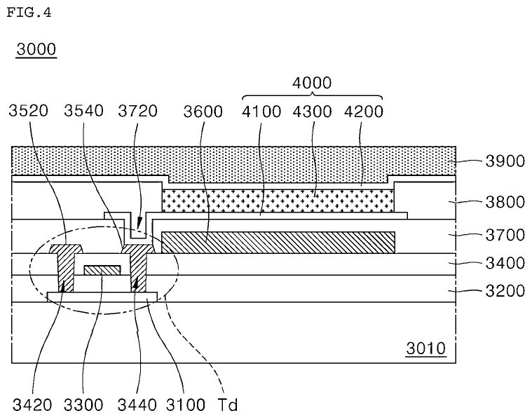

In one embodiment, FIG. 4 is a cross-sectional view schematically showing an OLED display device to which the OLED according to an embodiment of the present disclosure is applied.

As shown in FIG. 4, an OLED display device 3000 can include a substrate 3010, an OLED 4000, and an encapsulation film 3900 covering the OLED 4000. On the substrate 3010, a driving thin film transistor Td, which is a driving element, and the OLED 4000 connected to the driving thin film transistor Td are positioned. The OLED display device 3000 includes a plurality of the configuration shown in FIG. 4, in that the plurality of OLEDs 4000 and associated driving thin film transistors Td's. Other components to display images by the OLED display device 3000 are provided therein.

Although not explicitly shown in FIG. 4, on the substrate 3010, a gate line and a data line that intersect each other to define a pixel area, a power line spaced apart from any one of the gate line and the data line and extending in parallel, a switching thin film transistor connected to the gate line and the data line, and a storage capacitor connected to the power line and one electrode of the switching thin film transistor are further formed.

The driving thin film transistor Td is connected to the switching thin film transistor and includes a semiconductor layer 3100, a gate electrode 3300, a source electrode 3520, and a drain electrode 3540.

The semiconductor layer 3100 can be formed on the substrate 3010 and can be made of an oxide semiconductor material or polycrystalline silicon. When the semiconductor layer 3100 is made of the oxide semiconductor material, a light blocking pattern can optionally be formed under the semiconductor layer 3100, and the light blocking pattern prevents light incident on the semiconductor layer 3100, thereby preventing the degradation of the semiconductor layer 3100 caused by the light. Alternatively, the semiconductor layer 3100 can be made of polycrystalline silicon, and in this case, both edges of the semiconductor layer 3100 can be doped with impurities.

A gate insulating film 3200 made of an insulating material is formed on the entire surface of the substrate 3010 as well as the semiconductor layer 3100. The gate insulating film 3200 can be made of an inorganic insulating material, such as silicon oxide or silicon nitride.

A gate electrode 3300 made of a conductive material, such as a metal, is formed above the gate insulating film 3200 to correspond to the center of the semiconductor layer 3100. The gate electrode 3300 is connected to the switching thin film transistor.

An interlayer insulating film 3400 made of an insulating material is formed on the entire surface of the substrate 3010 as well as the gate electrode 3300. The interlayer insulating film 3400 can be made of an inorganic insulating material, such as silicon oxide or silicon nitride, or made of an organic insulating material, such as benzocyclobutene or photo-acryl.

The interlayer insulating film 3400 has first and second semiconductor layer contact holes 3420 and 3440 that expose both sides of the semiconductor layer 3100. The first and second semiconductor layer contact holes 3420 and 3440 are positioned to be spaced apart from the gate electrode 3300 at both sides of the gate electrode 3300.

The source electrode 3520 and the drain electrode 3540 made of the conductive material, such as a metal, are formed on the interlayer insulating film 3400. The source electrode 3520 and the drain electrode 3540 are positioned to be spaced apart from each other with respect to the gate electrode 3300 and are in contact with both sides of the semiconductor layer 3100 through the first and second semiconductor layer contact holes 3420 and 3440, respectively. The source electrode 3520 is connected to the power line.

The semiconductor layer 3100, the gate electrode 3300, the source electrode 3520, and the drain electrode 3540 form the driving thin film transistor Td, and the driving thin film transistor Td has a coplanar structure in which the gate electrode 3300, the source electrode 3520, and the drain electrode 3540 are positioned above the semiconductor layer 3100.

Alternatively, the driving thin film transistor Td can have an inverted staggered structure in which the gate electrode is positioned under the semiconductor layer and the source electrode and the drain electrode are positioned above the semiconductor layer. In this case, the semiconductor layer can be made of amorphous silicon. Meanwhile, the switching thin film transistor can have substantially the same structure as the driving thin film transistor Td.

Meanwhile, the OLED display device 3000 can include a color filter 3600 that absorbs light generated by the OLED 4000. For example, the color filter 3600 can absorb light of red (R), green (G), blue (B), and white (W). In this case, red, green, and blue color filter patterns that absorb light can be formed separately in each pixel area, and each of the color filter patterns can be disposed to overlap each intermediate layer 4300 of the OLED 4000 that emits light in a wavelength band to be absorbed. By adopting the color filter 3600, the OLED display device 3000 can implement full-color.

For example, when the OLED display device 3000 is a bottom-emission type, the color filter 3600 that absorbs light can be positioned above the interlayer insulating film 3400 corresponding to the OLED 4000. In an embodiment, when the OLED display device 3000 is a top-emission type, the color filter can be positioned above the OLED 4000, for example, above a second electrode 4200. For example, the color filter 3600 can be formed to have a thickness of 2 to 5 μm.

Meanwhile, a planarization layer 3700 with a drain contact hole 3720 that exposes the drain electrode 3540 of the driving thin film transistor Td is formed to cover the driving thin film transistor Td.

On the planarization layer 3700, a first electrode 4100 connected to the drain electrode 3540 of the driving thin film transistor Td through the drain contact hole 3720 is formed separately in each pixel area.

The first electrode 4100 can be an anode and can be made of a conductive material with a relatively high work function value. For example, the first electrode 4100 can be made of a transparent conductive material, such as ITO, IZO, or ZnO.

Meanwhile, when the OLED display device 3000 is a top-emission type, a reflective electrode or a reflective layer can be further formed under the first electrode 4100. For example, the reflective electrode or the reflective layer can be made of any one of aluminum (Al), silver (Ag), nickel (Ni), or an aluminum-palladium-copper (APC) alloy.

A bank layer 3800 covering an edge of the first electrode 4100 is formed on the planarization layer 3700. The bank layer 3800 exposes the center of the first electrode 4100 corresponding to the pixel area.

The intermediate layer 4300 is formed on the first electrode 4100, and if necessary, the OLED 4000 can have a tandem structure, and regarding the tandem structure, reference is made to FIGS. 2 to 4 showing the embodiment of the present disclosure and the above description thereof.

The second electrode 4200 is formed above the substrate 3010 on which the intermediate layer 4300 is formed. The second electrode 4200 can be positioned on the entire surface of the display area and can be made of a conductive material with a relatively low work function value to be used as a cathode. For example, the second electrode 4200 can be made of any one of aluminum (Al), magnesium (Mg), and aluminum-magnesium alloy (Al—Mg).

The first electrode 4100, the intermediate layer 4300, and the second electrode 4200 form the OLED 4000.

On the second electrode 4200, the encapsulation film 3900 is formed to prevent the permeation of external moisture into the OLED 4000. Although not explicitly shown in FIG. 4, the encapsulation film 3900 can have a triple-layer structure in which a first inorganic layer, an intermediate layer, and an inorganic layer are sequentially stacked, but is not limited thereto.

Hereinafter, examples of the present disclosure will be described. However, the following examples are only examples of the present disclosure, and the present disclosure is not limited thereto.

### EXAMPLES

The following examples are not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### Example 1

An ITO substrate was cleaned with UV ozone before use and then loaded into an evaporation system. Then, the substrate was transported into a vacuum deposition chamber for deposition of all other layers above the substrate. The following layers were deposited in the following order by evaporation from a heating boat under a vacuum of about 10-7 Torr.

HATCN (see a structure below) as a hole injection material was thermally deposited in vacuum on a provided ITO transparent electrode to form a hole injection layer in the thickness of 100 Å, and then HTL (see a structure below) as a hole transport material was thermally deposited in vacuum to form a hole transport layer in the thickness of 700 Å. Subsequently, an emission material layer was formed in the thickness of 300 Å using RD6 as a dopant and a mixture of RHH1 and REH1 (RHH1:REH1=1:1, based on a weight) as a host. A doping concentration of the dopant in the emission material layer was 10 wt %. Subsequently, an OLED having a structure of ITO/hole injection layer/hole transport layer/emission material layer/electron transport layer/electron injection layer/cathode was manufactured by thermally depositing Alq₃ (see a structure below) as the electron transport material and LiF as the electron injection material in vacuum sequentially to form an electron transport layer in the thickness of 300 Å and an electron injection layer in the thickness of 10 Å and then depositing aluminum in the thickness of 1000 Å to form a cathode. After the layers were deposited, the layers were transported from the deposition chamber into a dry box to form a film and subsequently encapsulated using a UV cured epoxy and a moisture getter.

### Examples 2 to 144 and Comparative Examples 1 to 4

OLEDs of Comparative Examples 1 to 4 and Examples 2 to 144 were manufactured in the same manner as Example 1, except that the dopant materials and host materials shown in Tables 1 to 8 below were used in Example 1. In Examples 2 to 144, a mixing ratio of the host materials was 1:1 (based on a weight). Comparative Examples 1 to 4 each used the type of “CBP” with a structure below as the host of the emission material layer.

The materials used in Example 1 to 144 and Comparative Example 1 to 4 are as follows.

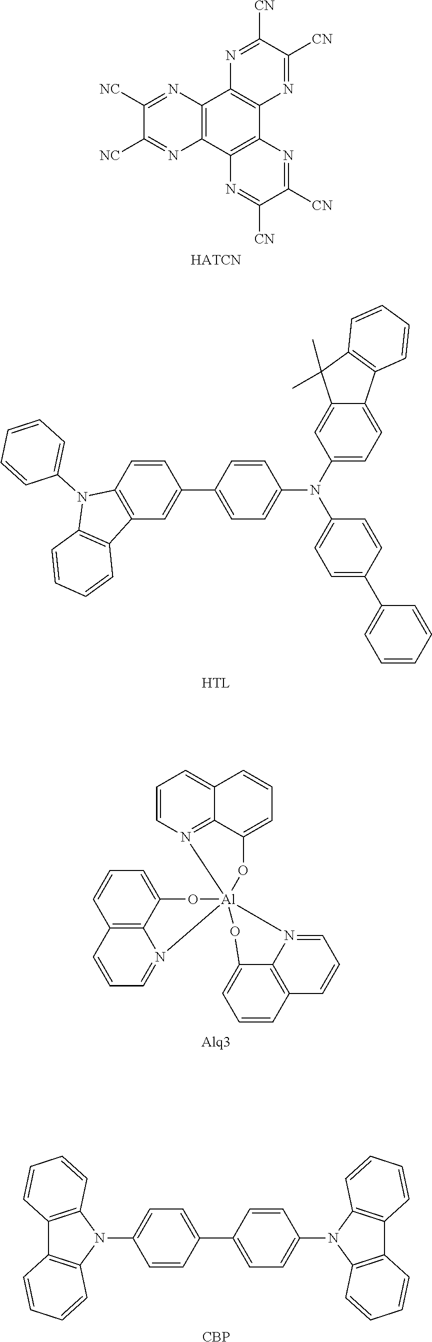

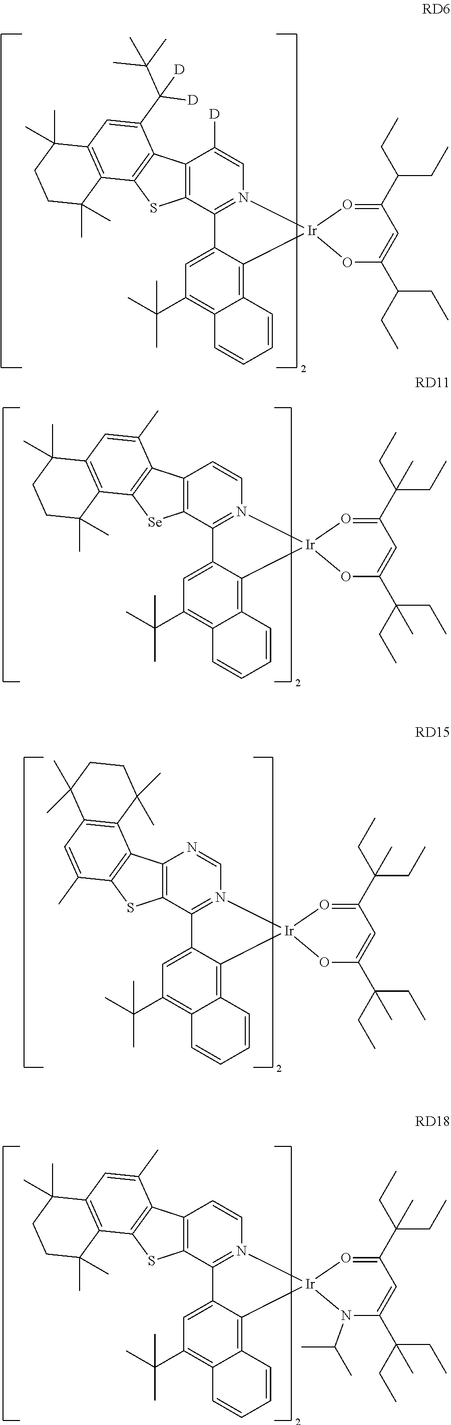

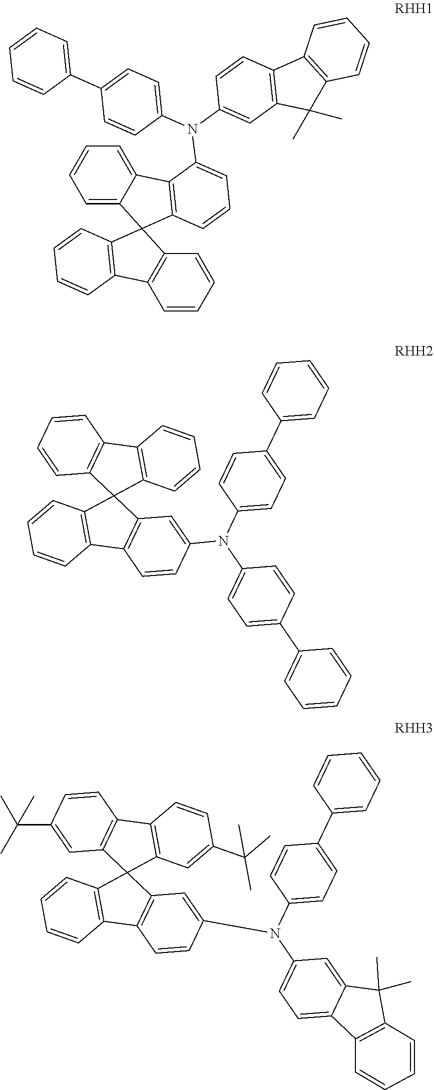 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc4c(c3)C3(c5ccccc5-c5ccccc53)c3ccccc3-4)cc2)cc1 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

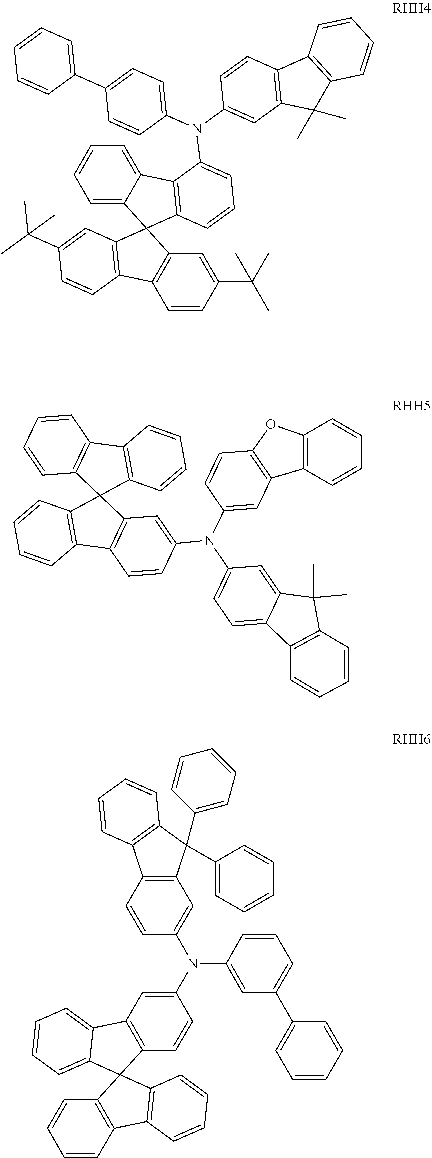 [SMILES: CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1]

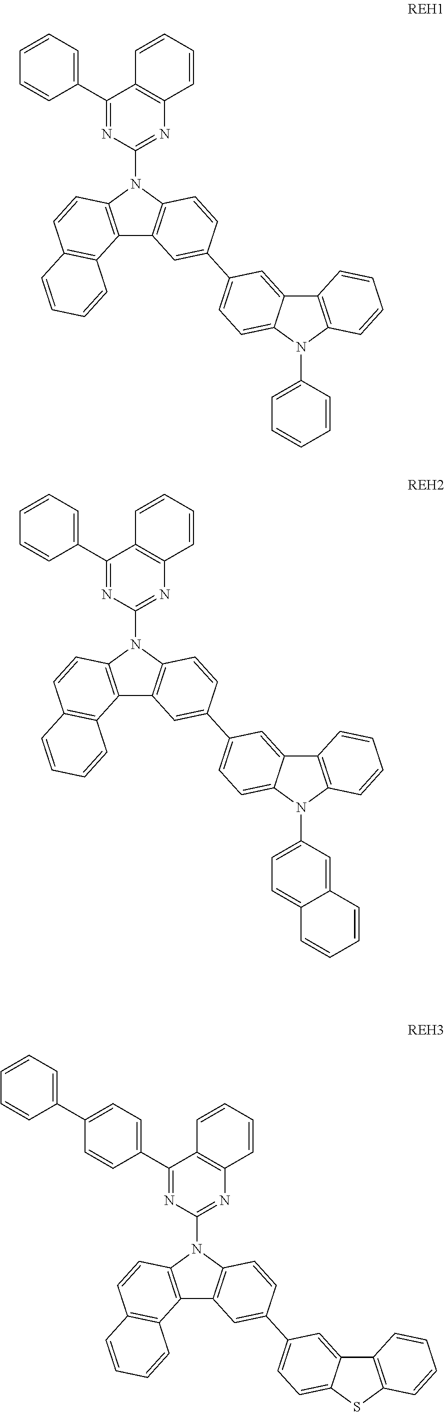 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

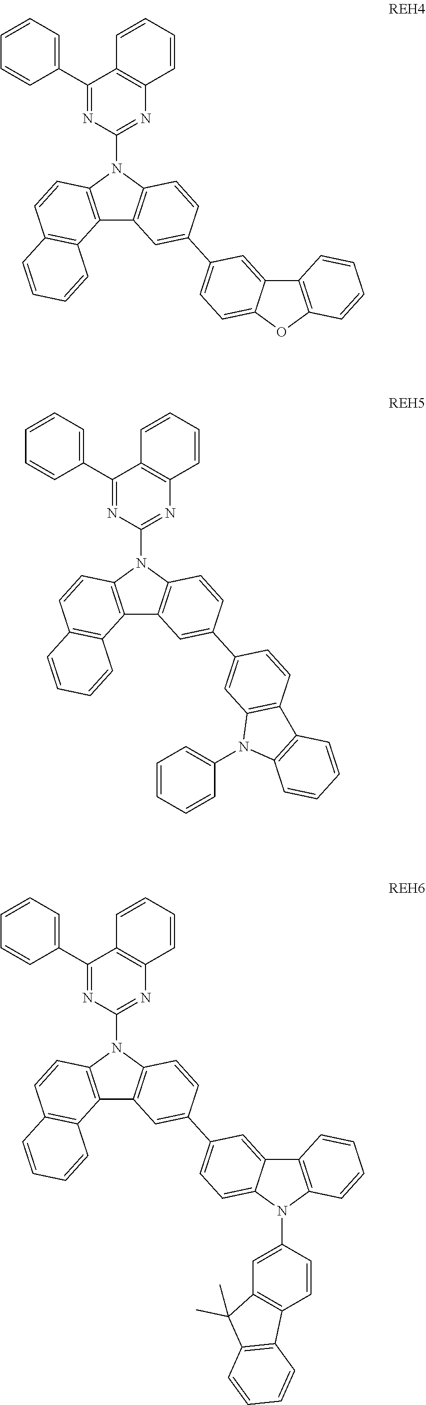 [SMILES: c1ccc(-c2nc(-n3c4ccc(-c5ccc6oc7ccccc7c6c5)cc4c4c5ccccc5ccc43)nc3ccccc23)cc1 ; c1ccc(-c2nc(-n3c4ccc(-c5ccc6c7ccccc7n(-c7ccccc7)c6c5)cc4c4c5ccccc5ccc43)nc3ccccc23)cc1 ; CC1(C)c2ccccc2-c2ccc(-n3c4ccccc4c4cc(-c5ccc6c(c5)c5c7ccccc7ccc5n6-c5nc(-c6ccccc6)c6ccccc6n5)ccc43)cc21]

### Experimental Example

Te OLDs manufactured in Examples 1 to 114 and Comparative Examples 1 to 4 had an emission area of 9 mm². Each OLED was connected to an external power source, and device characteristics were evaluated at room temperature using a current source (KEITHLEY) and a photometer (PR 650), and the results are shown in Tables 1 to 8 below. When a DC voltage was applied, light emission having the characteristics shown in Tables 1 to 8 below was confirmed.

Specifically, a driving voltage (V), external quantum efficiency (EQE), and lifetime (LT95) characteristics were measured with a current of 10 mA/cr², and measured values of Examples 1 to 144 were calculated as relative values (percentage, %) for any one of Comparative Examples 1 to 4, and the results are shown in Tables 1 to 8 below.

The LT95 lifetime indicates the time it takes for an OLED to lose 5% of its initial brightness at 40° C. and 40 mA/cm² (lifetime decreasing from 100% to 95%). LT95 is the most difficult element characteristic specification to meet, and whether an image burn-in phenomenon occurs in an OLED is determined using LT95

TABLE 1

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD6 | CBP | | 4.30 | 100 | 100 |
| Example 1 | | | | | | |
| Example 1 | RD6 | RHH1 | REH1 | 4.15 | 125 | 145 |
| Example 2 | RD6 | RHH1 | REH2 | 4.14 | 127 | 143 |
| Example 3 | RD6 | RHH1 | REH3 | 4.10 | 120 | 130 |
| Example 4 | RD6 | RHH1 | REH4 | 4.09 | 119 | 130 |
| Example 5 | RD6 | RHH1 | REH5 | 4.11 | 119 | 130 |
| Example 6 | RD6 | RHH1 | REH6 | 4.10 | 120 | 133 |
| Example 7 | RD6 | RHH2 | REH1 | 4.13 | 123 | 143 |
| Example 8 | RD6 | RHH2 | REH2 | 4.12 | 125 | 140 |
| Example 9 | RD6 | RHH2 | REH3 | 4.09 | 118 | 130 |
| Example 10 | RD6 | RHH2 | REH4 | 4.10 | 117 | 131 |
| Example 11 | RD6 | RHH2 | REH5 | 4.10 | 116 | 132 |
| Example 12 | RD6 | RHH2 | REH6 | 4.11 | 119 | 130 |
| Example 13 | RD6 | RHH3 | REH1 | 4.15 | 125 | 140 |
| Example 14 | RD6 | RHH3 | REH2 | 4.13 | 125 | 135 |
| Example 15 | RD6 | RHH3 | REH3 | 4.10 | 120 | 130 |
| Example 16 | RD6 | RHH3 | REH4 | 4.11 | 117 | 130 |
| Example 17 | RD6 | RHH3 | REH5 | 4.10 | 115 | 132 |
| Example 18 | RD6 | RHH3 | REH6 | 4.10 | 120 | 130 |

TABLE 2

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD6 | CBP | | 4.30 | 100 | 100 |
| Example 1 | | | | | | |
| Example 19 | RD6 | RHH4 | REH1 | 4.20 | 125 | 150 |
| Example 20 | RD6 | RHH4 | REH2 | 4.18 | 125 | 135 |
| Example 21 | RD6 | RHH4 | REH3 | 4.15 | 123 | 135 |
| Example 22 | RD6 | RHH4 | REH4 | 4.15 | 120 | 130 |
| Example 23 | RD6 | RHH4 | REH5 | 4.10 | 120 | 135 |
| Example 24 | RD6 | RHH4 | REH6 | 4.12 | 120 | 133 |
| Example 25 | RD6 | RHH5 | REH1 | 4.14 | 123 | 130 |
| Example 26 | RD6 | RHH5 | REH2 | 4.15 | 120 | 125 |
| Example 27 | RD6 | RHH5 | REH3 | 4.13 | 119 | 120 |
| Example 28 | RD6 | RHH5 | REH4 | 4.12 | 118 | 120 |
| Example 29 | RD6 | RHH5 | REH5 | 4.11 | 117 | 122 |
| Example 30 | RD6 | RHH5 | REH6 | 4.11 | 119 | 117 |
| Example 31 | RD6 | RHH6 | REH1 | 4.15 | 115 | 130 |
| Example 32 | RD6 | RHH6 | REH2 | 4.16 | 115 | 125 |
| Example 33 | RD6 | RHH6 | REH3 | 4.18 | 113 | 115 |
| Example 34 | RD6 | RHH6 | REH4 | 4.15 | 114 | 120 |
| Example 35 | RD6 | RHH6 | REH5 | 4.14 | 115 | 125 |
| Example 36 | RD6 | RHH6 | REH6 | 4.13 | 116 | 123 |

TABLE 3

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD11 | CBP | | 4.32 | 100 | 100 |
| Example 2 | | | | | | |
| Example 37 | RD11 | RHH1 | REH1 | 4.22 | 115 | 150 |
| Example 38 | RD11 | RHH1 | REH2 | 4.20 | 116 | 148 |
| Example 39 | RD11 | RHH1 | REH3 | 4.18 | 113 | 135 |
| Example 40 | RD11 | RHH1 | REH4 | 4.19 | 115 | 135 |
| Example 41 | RD11 | RHH1 | REH5 | 4.15 | 116 | 135 |
| Example 42 | RD11 | RHH1 | REH6 | 4.15 | 115 | 138 |
| Example 43 | RD11 | RHH2 | REH1 | 4.15 | 120 | 148 |
| Example 44 | RD11 | RHH2 | REH2 | 4.17 | 119 | 145 |
| Example 45 | RD11 | RHH2 | REH3 | 4.14 | 115 | 135 |
| Example 46 | RD11 | RHH2 | REH4 | 4.15 | 115 | 136 |
| Example 47 | RD11 | RHH2 | REH5 | 4.15 | 113 | 137 |
| Example 48 | RD11 | RHH2 | REH6 | 4.14 | 115 | 135 |
| Example 49 | RD11 | RHH3 | REH1 | 4.15 | 115 | 145 |
| Example 50 | RD11 | RHH3 | REH2 | 4.17 | 117 | 140 |
| Example 51 | RD11 | RHH3 | REH3 | 4.20 | 118 | 135 |
| Example 52 | RD11 | RHH3 | REH4 | 4.15 | 116 | 135 |
| Example 53 | RD11 | RHH3 | REH5 | 4.18 | 115 | 137 |
| Example 54 | RD11 | RHH3 | REH6 | 4.18 | 115 | 135 |

TABLE 4

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD11 | CBP | | 4.32 | 100 | 100 |
| Example 2 | | | | | | |
| Example 55 | RD11 | RHH4 | REH1 | 4.22 | 120 | 158 |
| Example 56 | RD11 | RHH4 | REH2 | 4.20 | 118 | 143 |
| Example 57 | RD11 | RHH4 | REH3 | 4.18 | 117 | 143 |
| Example 58 | RD11 | RHH4 | REH4 | 4.19 | 119 | 138 |
| Example 59 | RD11 | RHH4 | REH5 | 4.15 | 119 | 143 |
| Example 60 | RD11 | RHH4 | REH6 | 4.18 | 122 | 141 |
| Example 61 | RD11 | RHH5 | REH1 | 4.15 | 120 | 138 |
| Example 62 | RD11 | RHH5 | REH2 | 4.16 | 117 | 133 |
| Example 63 | RD11 | RHH5 | REH3 | 4.15 | 116 | 128 |
| Example 64 | RD11 | RHH5 | REH4 | 4.14 | 115 | 128 |
| Example 65 | RD11 | RHH5 | REH5 | 4.14 | 114 | 130 |
| Example 66 | RD11 | RHH5 | REH6 | 4.14 | 116 | 125 |
| Example 67 | RD11 | RHH6 | REH1 | 4.18 | 111 | 138 |
| Example 68 | RD11 | RHH6 | REH2 | 4.19 | 111 | 133 |
| Example 69 | RD11 | RHH6 | REH3 | 4.20 | 115 | 123 |
| Example 70 | RD11 | RHH6 | REH4 | 4.17 | 113 | 128 |
| Example 71 | RD11 | RHH6 | REH5 | 4.18 | 112 | 133 |
| Example 72 | RD11 | RHH6 | REH6 | 4.16 | 111 | 131 |

TABLE 5

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD15 | CBP | | 4.29 | 100 | 100 |
| Example 3 | | | | | | |
| Example 73 | RD15 | RHH1 | REH1 | 4.25 | 112 | 120 |
| Example 74 | RD15 | RHH1 | REH2 | 4.24 | 114 | 118 |
| Example 75 | RD15 | RHH1 | REH3 | 4.20 | 107 | 110 |
| Example 76 | RD15 | RHH1 | REH4 | 4.19 | 108 | 110 |
| Example 77 | RD15 | RHH1 | REH5 | 4.21 | 110 | 115 |
| Example 78 | RD15 | RHH1 | REH6 | 4.20 | 112 | 118 |
| Example 79 | RD15 | RHH2 | REH1 | 4.22 | 110 | 118 |
| Example 80 | RD15 | RHH2 | REH2 | 4.20 | 112 | 115 |
| Example 81 | RD15 | RHH2 | REH3 | 4.19 | 107 | 115 |
| Example 82 | RD15 | RHH2 | REH4 | 4.20 | 110 | 116 |
| Example 83 | RD15 | RHH2 | REH5 | 4.21 | 108 | 117 |
| Example 84 | RD15 | RHH2 | REH6 | 4.22 | 110 | 115 |
| Example 85 | RD15 | RHH3 | REH1 | 4.25 | 112 | 115 |
| Example 86 | RD15 | RHH3 | REH2 | 4.23 | 112 | 110 |
| Example 87 | RD15 | RHH3 | REH3 | 4.20 | 107 | 120 |
| Example 88 | RD15 | RHH3 | REH4 | 4.21 | 108 | 120 |
| Example 89 | RD15 | RHH3 | REH5 | 4.20 | 110 | 117 |
| Example 90 | RD15 | RHH3 | REH6 | 4.20 | 112 | 115 |

TABLE 6

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD15 | CBP | | 4.29 | 100 | 100 |
| Example 3 | | | | | | |
| Example 91 | RD15 | RHH4 | REH1 | 4.24 | 112 | 125 |
| Example 92 | RD15 | RHH4 | REH2 | 4.19 | 117 | 115 |
| Example 93 | RD15 | RHH4 | REH3 | 4.23 | 122 | 120 |
| Example 94 | RD15 | RHH4 | REH4 | 4.21 | 112 | 115 |
| Example 95 | RD15 | RHH4 | REH5 | 4.20 | 112 | 110 |
| Example 96 | RD15 | RHH4 | REH6 | 4.22 | 118 | 118 |
| Example 97 | RD15 | RHH5 | REH1 | 4.23 | 113 | 120 |
| Example 98 | RD15 | RHH5 | REH2 | 4.22 | 114 | 118 |
| Example 99 | RD15 | RHH5 | REH3 | 4.22 | 112 | 116 |
| Example 100 | RD15 | RHH5 | REH4 | 4.20 | 117 | 118 |
| Example 101 | RD15 | RHH5 | REH5 | 4.19 | 112 | 115 |
| Example 102 | RD15 | RHH5 | REH6 | 4.21 | 114 | 118 |
| Example 103 | RD15 | RHH6 | REH1 | 4.23 | 117 | 120 |
| Example 104 | RD15 | RHH6 | REH2 | 4.22 | 116 | 118 |
| Example 105 | RD15 | RHH6 | REH3 | 4.23 | 114 | 112 |
| Example 106 | RD15 | RHH6 | REH4 | 4.22 | 113 | 114 |
| Example 107 | RD15 | RHH6 | REH5 | 4.21 | 115 | 115 |
| Example 108 | RD15 | RHH6 | REH6 | 4.20 | 112 | 116 |

TABLE 7

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD18 | CBP | | 4.28 | 100 | 100 |
| Example 4 | | | | | | |
| Example 109 | RD18 | RHH1 | REH1 | 4.18 | 130 | 119 |
| Example 110 | RD18 | RHH1 | REH2 | 4.15 | 132 | 117 |
| Example 111 | RD18 | RHH1 | REH3 | 4.18 | 125 | 111 |
| Example 112 | RD18 | RHH1 | REH4 | 4.15 | 124 | 111 |
| Example 113 | RD18 | RHH1 | REH5 | 4.15 | 124 | 114 |
| Example 114 | RD18 | RHH1 | REH6 | 4.18 | 125 | 117 |
| Example 115 | RD18 | RHH2 | REH1 | 4.20 | 128 | 116 |
| Example 116 | RD18 | RHH2 | REH2 | 4.18 | 130 | 113 |
| Example 117 | RD18 | RHH2 | REH3 | 4.17 | 123 | 114 |
| Example 118 | RD18 | RHH2 | REH4 | 4.18 | 122 | 115 |
| Example 119 | RD18 | RHH2 | REH5 | 4.19 | 121 | 115 |
| Example 120 | RD18 | RHH2 | REH6 | 4.20 | 124 | 113 |
| Example 121 | RD18 | RHH3 | REH1 | 4.19 | 130 | 114 |
| Example 122 | RD18 | RHH3 | REH2 | 4.17 | 130 | 111 |
| Example 123 | RD18 | RHH3 | REH3 | 4.14 | 125 | 118 |
| Example 124 | RD18 | RHH3 | REH4 | 4.15 | 122 | 115 |
| Example 125 | RD18 | RHH3 | REH5 | 4.16 | 120 | 118 |
| Example 126 | RD18 | RHH3 | REH6 | 4.15 | 125 | 116 |

TABLE 8

| | | | | | EQE | LT95 |
|---|---|---|---|---|---|---|
| | | | | driving | (%, | (%, |
| | emission material layer | | | voltage | relative | relative |
| | dopant | host | | (V) | value) | value) |
| Comparative | RD18 | CBP | | 4.28 | 100 | 100 |
| Example 4 | | | | | | |
| Example 127 | RD18 | RHH4 | REH1 | 4.18 | 128 | 115 |
| Example 128 | RD18 | RHH4 | REH2 | 4.16 | 128 | 114 |
| Example 129 | RD18 | RHH4 | REH3 | 4.17 | 126 | 113 |
| Example 130 | RD18 | RHH4 | REH4 | 4.15 | 123 | 112 |
| Example 131 | RD18 | RHH4 | REH5 | 4.16 | 123 | 113 |
| Example 132 | RD18 | RHH4 | REH6 | 4.16 | 123 | 114 |
| Example 133 | RD18 | RHH5 | REH1 | 4.19 | 126 | 115 |
| Example 134 | RD18 | RHH5 | REH2 | 4.18 | 123 | 114 |
| Example 135 | RD18 | RHH5 | REH3 | 4.18 | 122 | 116 |
| Example 136 | RD18 | RHH5 | REH4 | 4.16 | 121 | 115 |
| Example 137 | RD18 | RHH5 | REH5 | 4.15 | 120 | 113 |
| Example 138 | RD18 | RHH5 | REH6 | 4.17 | 122 | 116 |
| Example 139 | RD18 | RHH6 | REH1 | 4.19 | 118 | 116 |
| Example 140 | RD18 | RHH6 | REH2 | 4.18 | 118 | 113 |
| Example 141 | RD18 | RHH6 | REH3 | 4.17 | 116 | 112 |
| Example 142 | RD18 | RHH6 | REH4 | 4.18 | 119 | 113 |
| Example 143 | RD18 | RHH6 | REH5 | 4.17 | 118 | 111 |
| Example 144 | RD18 | RHH6 | REH6 | 4.16 | 119 | 114 |

As can be seen from the results of Tables 1 to 8, it could be seen that Examples 1 to 144 provide the OLEDs that adopted the organometallic compound satisfying the structure represented by Chemical Formula 1 as the dopant of the emission material layer and adopted the mixture of the compound represented by Chemical Formula 4 and the compound represented by Chemical Formula 5 as the hosts, which had low driving voltages and increased external quantum efficiency (EQE) and lifetime (LT95) compared to the OLEDs of Comparative Examples 1 to 4 that used the single material as the host.

In the organic light emitting diode (OLED) according to the present disclosure, by adopting the organometallic compound represented by Chemical Formula 1 as the phosphorous dopant and adopting a mixture of a compound represented by Chemical Formula 4 and a compound represented by Chemical Formula 5 as the phosphorous host, it is possible to improve the efficiency and lifetime characteristics of the OLED and secure the low-power characteristics by decreasing the driving voltage.

The effects obtainable from the present disclosure are not limited to the above-described effects, and other effects that are not mentioned will be able to be clearly understood by those skilled in the art to which the present disclosure pertains from the following description.

Although the embodiments of the present specification have been described in more detail with reference to the accompanying drawings, the present specification is not necessarily limited to these embodiments, and various modifications can be carried out without departing from the technical spirit of the present specification. Therefore, the embodiments disclosed in the present specification are not intended to limit the technical spirit of the present specification, but is intended to describe the same, and the scope of the technical spirit of the present specification is not limited by these embodiments. Therefore, it should be understood that the above-described embodiments are illustrative and not restrictive in all aspects. The scope of the present specification should be construed according to the appended claims, and all technical spirits within the equivalent range should be construed as being included in the scope of the present specification.

### DESCRIPTION OF REFERENCE NUMERALS

100, 4000: organic light emitting diode (OLED)
110, 4100: first electrode
120, 4200: second electrode
130, 230, 330, 4300: an intermediate layer
140: hole injection layer
150: hole transport layer, 251: first hole transport layer, 252: second hole transport layer, 253: third hole transport layer
160: emission material layer, 261: first emission material layer, 262: second emission material layer, 263: third emission material layer
160′, 262′: dopant
160″, 262″: hole transport type host
160″′, 262″′: electron transport type host
170: electron transport layer, 271: first electron transport layer, 272: second electron transport layer, 273: third electron transport layer
180: electron injection layer
3000: OLED display device
3010: substrate
3100: semiconductor layer
3200: gate insulating film
3300: gate electrode
3400: interlayer insulating film
3420, 3440: first and second semiconductor contact holes
3520: source electrode
3540: drain electrode
3600: color filter
3700: planarization layer
3720: drain contact hole
3800: bank layer
3900: encapsulation film

What is claimed is:

1. An organic light emitting diode comprising:
a first electrode;
a second electrode facing the first electrode; and
an intermediate layer disposed between the first electrode and the second electrode,
wherein the intermediate layer comprises an emission material layer, and the emission material layer includes a dopant material and a host material,
the dopant material comprises an organometallic compound represented by Chemical Formula 1 below, and
the host material comprises a mixture of a compound represented by Chemical Formula 4 below and a compound represented by Chemical Formula 5 below:
M(L_{A})ₘ(L_{B})ₙ <Chemical Formula 1>
in Chemical Formula 1,
M is a central coordination metal and is one selected from the group consisting of molybdenum (Mo); tungsten (W); rhenium (Re); ruthenium (Ru); osmium (Os); rhodium (Rh); iridium (Ir); palladium (Pd); platinum (Pt); and gold (Au),
L_{A} is a ligand represented by Chemical Formula 2,
L_{B} is a bidentate ligand,
m is 1, 2 or 3, n is 0, 1 or 2, and (m+n) is the oxidation number of the central coordination metal M, 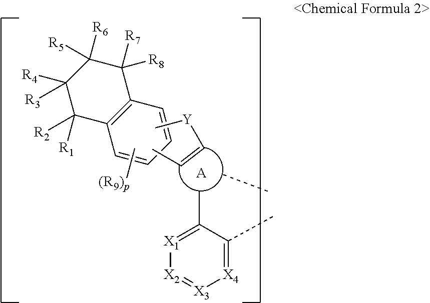
in Chemical Formula 2,
A has a ring structure selected from substituted or unsubstituted pyridine and substituted or unsubstituted pyrimidine,
R₁ to R₈ are, each independently, at least one selected from the group consisting of hydrogen; deuterium; a substituted or unsubstituted C1-C20 linear alkyl group; a substituted or unsubstituted C3-C20 branched alkyl group; and a substituted or unsubstituted C4-C20 bicycloalkyl group, and optionally, R₁ to R₈ are partially or entirely deuterated,
R₉ is, each independently, at least one selected from the group consisting of hydrogen; deuterium; a substituted or unsubstituted C1-C20 linear alkyl group; a substituted or unsubstituted C3-C20 branched alkyl group; a C3-C20 cycloalkyl group; halogen; a nitrile group; a substituted or unsubstituted C1-C20 alkoxy group; and combinations thereof, and optionally, R₉ is partially or entirely deuterated,
when any one of R₁ to R₉ is substituted, a substituent of R₁ to R₉ is, each independently, be at least one selected from the group consisting of deuterium; halogen; a C3-C10 cycloalkyl group; and combinations thereof, and when a plurality of substituents of R₁ to R₉ are present, each substituent is the same as or different from each other,
Y is at least one selected from the group consisting of BR₁₀; CR₁₀R₁₁; C═O; CNR₁₀; SiR₁₀R₁₁; NR₁₀; PR₁₀; AsR₁₀; SbR₁₀; P(O)R₁₀; P(S)R₁₀; P(Se)R₁₀; As(O)R₁₀; As(S)R₁₀; As(Se)R₁₀; Sb(O)R₁₀; Sb(S)R₁₀; Sb(Se)R₁₀; O; S; Se; Te; SO; SO2; SeO; SeO₂; TeO; and TeO₂,
X₁ to X₄ are, each independently, at least one selected from CR₁₂ and nitrogen (N),
when any two of X₁ to X₄ that are adjacent to each other are CR₁₂, two R₁₂ are not bonded, or are bonded to form a 5-membered or 6-membered, substituted or unsubstituted aromatic ring or heteroaromatic ring structure, when one of any two of X₁ to X₄ that are adjacent is CR₁₂ and the other is nitrogen (N), R₁₂ is not bonded, or is bonded to the nitrogen to form a 5-membered or 6-membered heteroaromatic ring structure, and the aromatic ring or the heteroaromatic ring structure formed where R₁₂ is bonded is not substituted or substituted with at least one deuterium,
R₁₀ to R₁₂ are, each independently, at least one selected from the group consisting of hydrogen; deuterium; halogen; a hydroxyl group; a nitro group; an amidino group; a hydrazine group; a hydrazone group; a substituted or unsubstituted C1-C20 linear alkyl group; a substituted or unsubstituted C3-C20 branched alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
when any one of R₁₀ to R₁₂ is substituted, a substituent of R₁₀ to R₁₂ is, each independently, at least one selected from the group consisting of deuterium; halogen; and combinations thereof, and when a plurality of the substituents of R₁₀ to R₁₂ are present, each substituent is the same as or different from each other, and
p is 2, and
dotted line represents a connection position to the central coordination metal M, 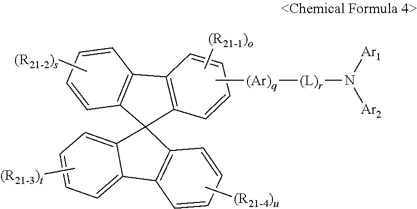
in Chemical Formula 4,
Ar is, each independently, a divalent group of an aromatic ring or a heteroaromatic ring selected from the group consisting of benzene; naphthalene; phenanthrene; fluorene; spirobifluorene; dibenzofuran; and dibenzothiophene,
Ar₁ and Ar₂ are, each independently, a substituted or unsubstituted C6-C60 aryl group or a substituted or unsubstituted C2-C60 heteroaryl group,
R₂₁₋₁ to R₂₁₋₄ are, each independently, at least one selected from the group consisting of deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
is an integer from 0 to 3, when o is an integer of 2 or 3, R₂₁₋₁ is the same or different, and optionally, R₂₁₋₁ is deuterated partially or entirely,
s is an integer from 0 to 4, when s is an integer from 2 to 4, R₂₁₋₂ is the same or different, and optionally, R₂₁₋₂ is deuterated partially or entirely,
t is an integer from 0 to 4, when t is an integer from 2 to 4,
R₂₁₋₃ is the same or different, and optionally, R₂₁₋₃ is deuterated partially or entirely,
u is an integer from 0 to 4, when u is an integer from 2 to 4, R₂₁₋₄ is the same or different, and optionally, R₂₁₋₄ is deuterated partially or entirely,
q is an integer from 0 to 2, and
r is an integer of 0 or 1, and
a linker L is at least one selected from the group consisting of a substituted or unsubstituted C6-C30 arylene group; a substituted or unsubstituted C2-C30 heteroarylene group; and a substituted or unsubstituted C7-C20 arylalkylene group, 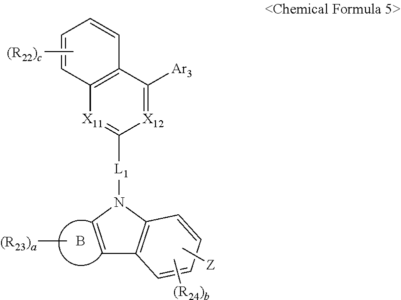
in Chemical Formula 5,
a B ring is a substituted or unsubstituted C6-C30 monocyclic or polycyclic aromatic fused ring,
X₁₁ and X₁₂ are, each independently, N or CR′,
L₁ is one selected from the group consisting of a single bond; a substituted or unsubstituted C6-C30 arylene group; a substituted or unsubstituted C2-C30 heteroarylene group; and a substituted or unsubstituted C3-C30 cycloalkylene group,
Ar₃ is one selected from the group consisting of hydrogen; deuterium; halogen; a substituted or unsubstituted C1-C30 alkyl group; a substituted or unsubstituted C6-C30 aryl group; a substituted or unsubstituted C2-C30 heteroaryl group; and -L₂₄-SiRₖRₗRₘ, in which L₂₄ is a single bond, a substituted or unsubstituted C6-C30 arylene group, or a substituted or unsubstituted C2-C30 heteroarylene group, and Rₖ, Rₗ, and Rₘ are, each independently, hydrogen, a substituted or unsubstituted C1-C30 alkyl group or a substituted or unsubstituted C6-C30 aryl group,
one or more of hydrogen of an alkyl group, an aryl group, a heteroaryl group, or a -L₂₄-SiRₖRₗRₘ group, which is Ar₃, are unsubstituted or substituted with one or more of deuterium and halogen atom,
Z is one selected from the group consisting of the following structures, 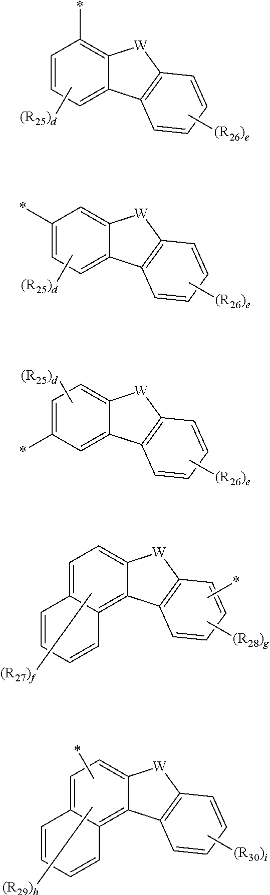
W is one selected from the group consisting of O; S; NR₃₁; CR₃₁R₃₂; and SiR₃₁R₃₂,
R₂₂ to R₃₂ and R′ are, each independently, one selected from the group consisting of hydrogen; deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group, and
a, c, e and i are, each independently, an integer of 1, 2, 3 or 4; b, d, g are, each independently, an integer of 1, 2 or 3; f is an integer of 1, 2, 3, 4, 5, or 6; and h is an integer of 1, 2, 3, 4, or 5.

2. The organic light emitting diode of claim 1, wherein L_{B} in Chemical Formula 1 is represented by a structure of at least one selected from the group consisting of Chemical Formula 3-1, and Chemical Formula 3-2 below: 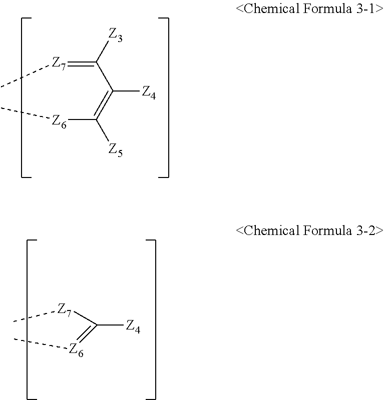
in Chemical Formula 3-1, and Chemical Formula 3-2,
Z₃ to Z₅ are, each independently, one selected from the group consisting of hydrogen; deuterium; halogen; a hydroxyl group; a nitro group; an amidino group; a hydrazine group; a hydrazone group; a substituted or unsubstituted C1-C20 linear alkyl group; a substituted or unsubstituted C3-C20 branched alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; an acyl group; a carboxyl group; a nitrile group; an isonitrile group; a sulfanyl group; and a phosphino group,
Z₆ and Z₇ are, each independently, one selected from the group consisting of oxygen (O) and NR_{z}, and R_{z} is, each independently, one selected from the group consisting of hydrogen; a C1-C20 linear alkyl group; and a substituted or unsubstituted C3-C20 branched alkyl groups, and
dotted line represents a connection position to the central coordination metal M.

3. The organic light emitting diode of claim 1, wherein the compound represented by Chemical Formula 1 is a compound represented by a structure of one selected from the group consisting of Chemical Formula 1-1-(1), Chemical Formula 1-1-(2), Chemical Formula 1-1-(3), Chemical Formula 1-1-(4), Chemical Formula 1-1-(5), and Chemical Formula 1-1-(6), the compound represented by Chemical Formula 1-2 is represented by a structure of one selected from the group consisting of Chemical Formula 1-2-(1), Chemical Formula 1-2-(2), Chemical Formula 1-2-(3), Chemical Formula 1-2-(4), Chemical Formula 1-2-(5), and Chemical Formula 1-2-(6), and the compound represented by Chemical Formula 1-3 is represented by a structure of one selected from the group consisting of Chemical Formula 1-3-(1), Chemical Formula 1-3-(2), Chemical Formula 1-3-(3), Chemical Formula 1-3-(4), Chemical Formula 1-3-(5), and Chemical Formula 1-3-(6): 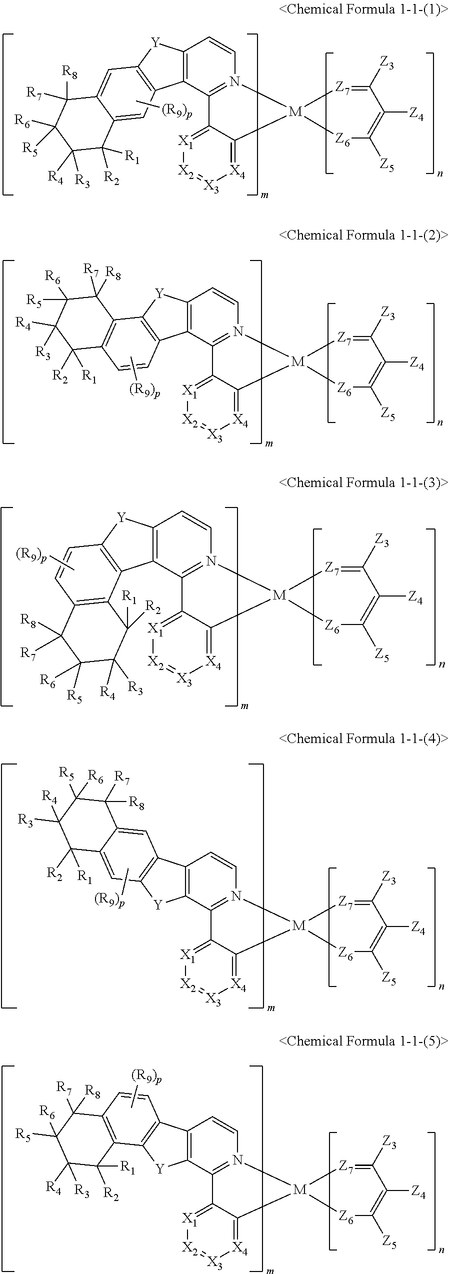 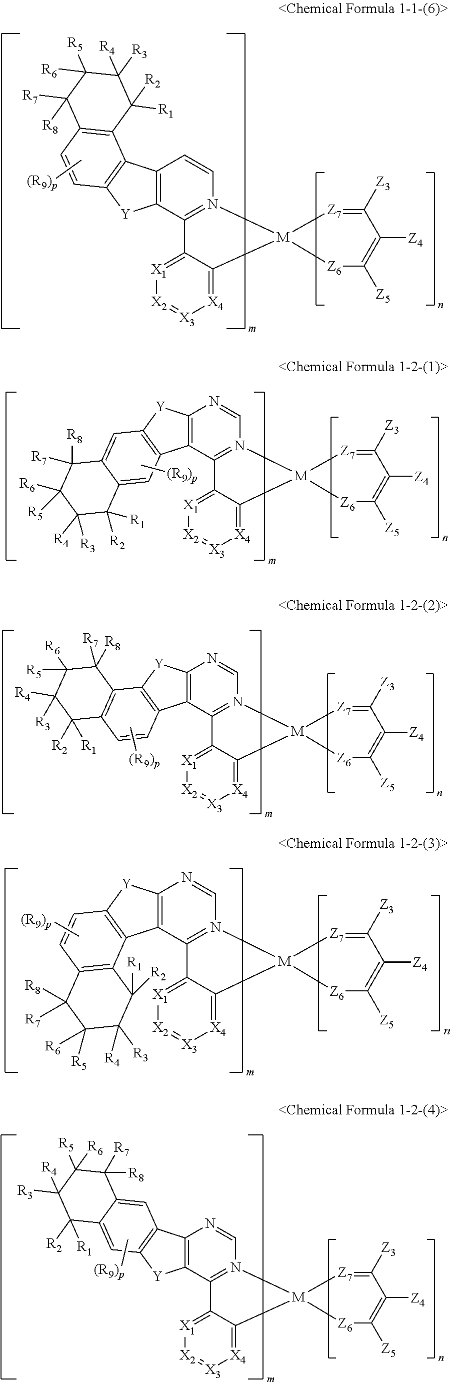 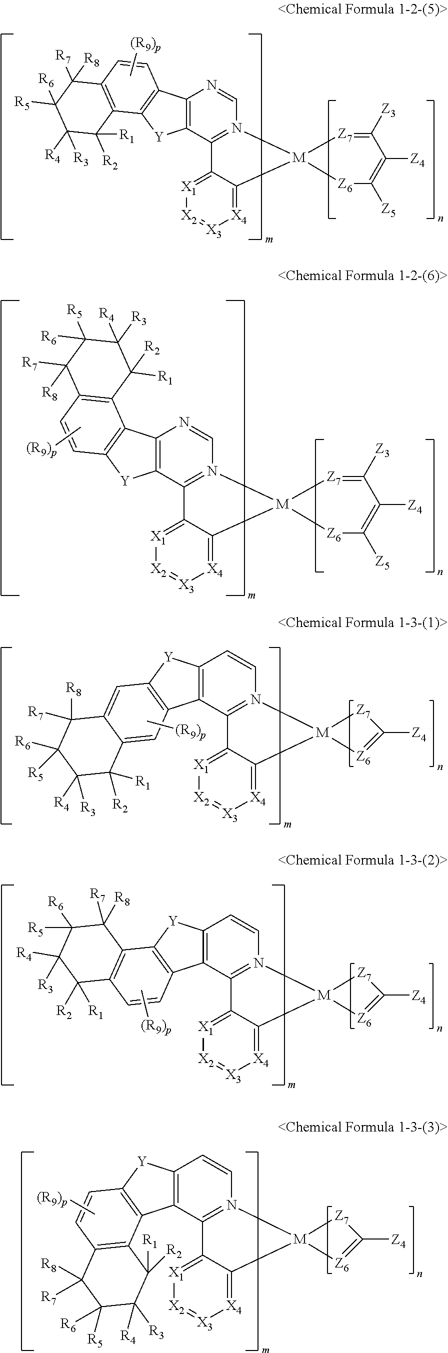 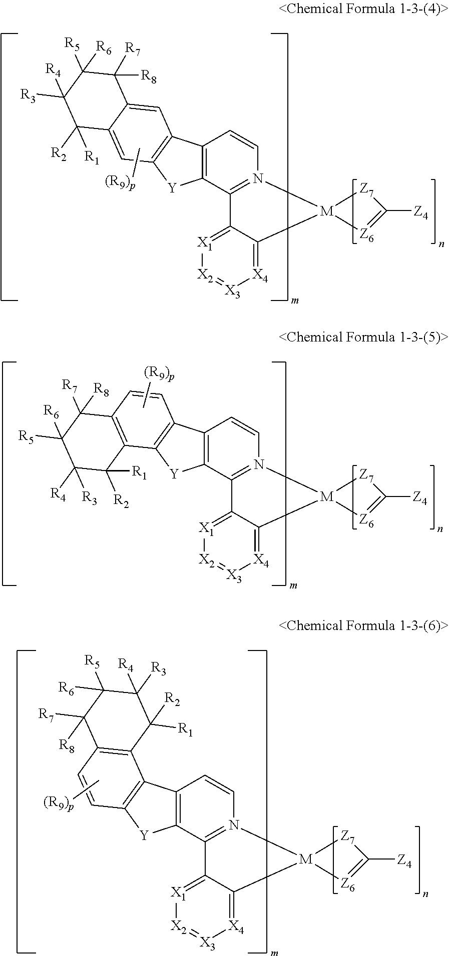
in Chemical Formula 1-1-(1), Chemical Formula 1-1-(2), Chemical Formula 1-1-(3), Chemical Formula 1-1-(4), Chemical Formula 1-1-(5), Chemical Formula 1-1-(6), Chemical Formula 1-2-(1), Chemical Formula 1-2-(2), Chemical Formula 1-2-(3), Chemical Formula 1-2-(4), Chemical Formula 1-2-(5), Chemical Formula 1-2-(6), Chemical Formula 1-3-(1), Chemical Formula 1-3-(2), Chemical Formula 1-3-(3), Chemical Formula 1-3-(4), Chemical Formula 1-3-(5), and Chemical Formula 1-3-(6), and
M, X₁ to X₄, Y, R₁ to R₉, p, m, and n are same as defined in Chemical Formula 1, and
Z₃ to Z₇ are same as defined in Chemical Formula 3-1 and Chemical Formula 3-2.

4. The organic light emitting diode of claim 1, wherein A in Chemical Formula 2 has a ring structure of pyridine.

5. The organic light emitting diode of claim 1, wherein M in Chemical Formula 1 is iridium (Ir).

6. The organic light emitting diode of claim 1, wherein Y in Chemical Formula 2 is any one of oxygen (O), sulfur (S), and selenium (Se).

7. The organic light emitting diode of claim 1, wherein at least one of R₉ in Chemical Formula 2 excludes hydrogen.

8. The organic light emitting diode of claim 1, wherein R₁₀ to R₁₂ in Chemical Formula 2 are, each independently, at least one selected from the group consisting of hydrogen; deuterium; halogen; a nitrile group; a nitro group; a substituted or unsubstituted C1-C20 alkoxy group; an amino group; a substituted or unsubstituted C1-C10 linear alkyl group; a substituted or unsubstituted C3-C10 branched alkyl group; and a substituted or unsubstituted C3-C10 cycloalkyl group.

9. The organic light emitting diode of claim 1, wherein the organometallic compound represented by Chemical Formula 1 is one selected from the group consisting of Compounds RD-1 to RD-20 below:

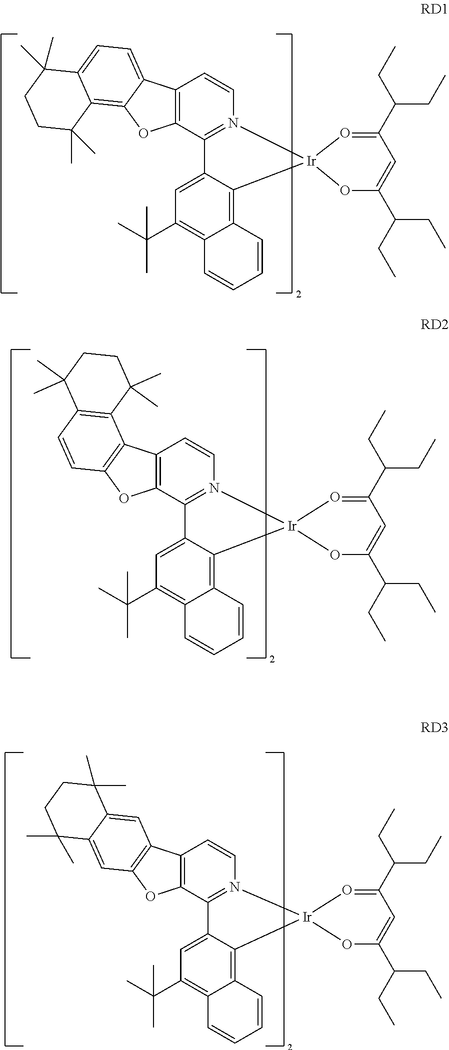

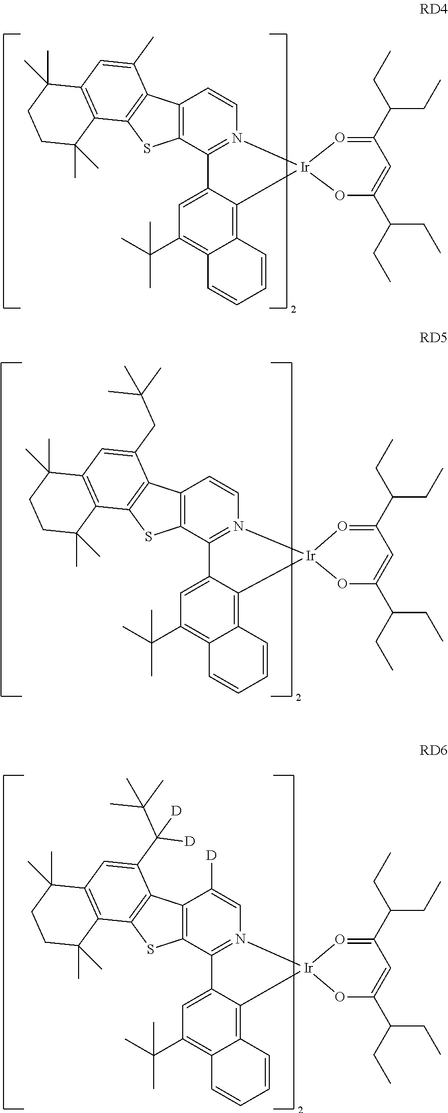

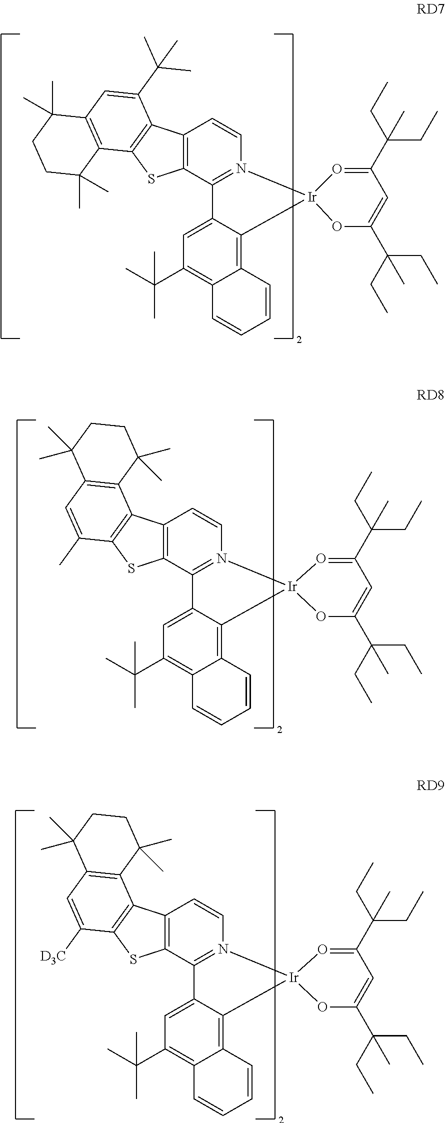

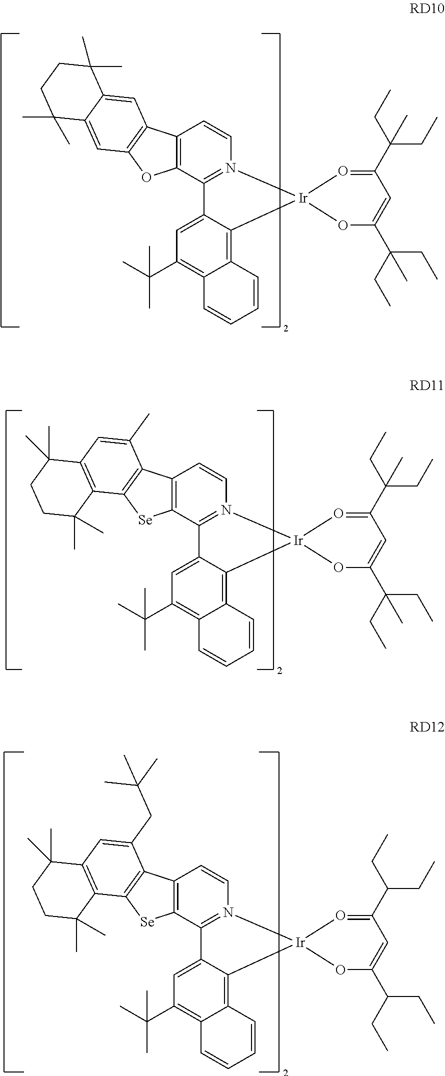

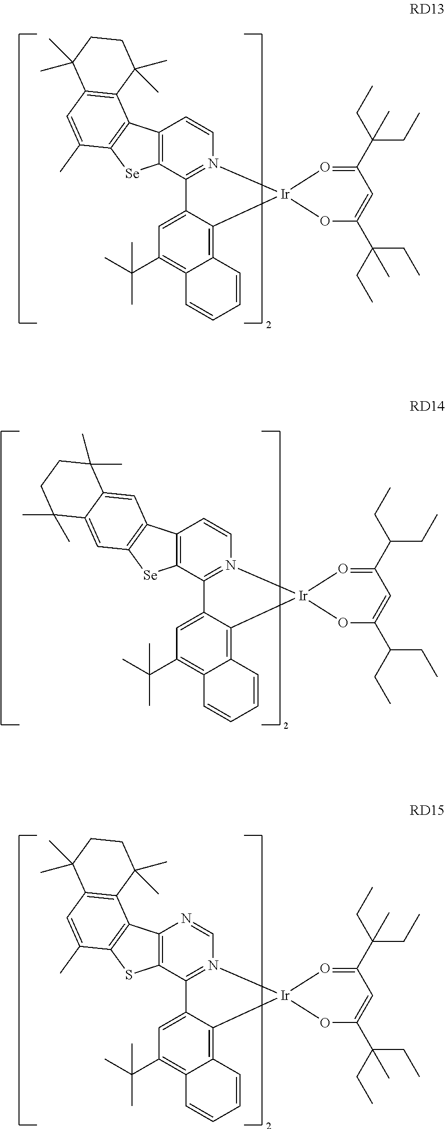

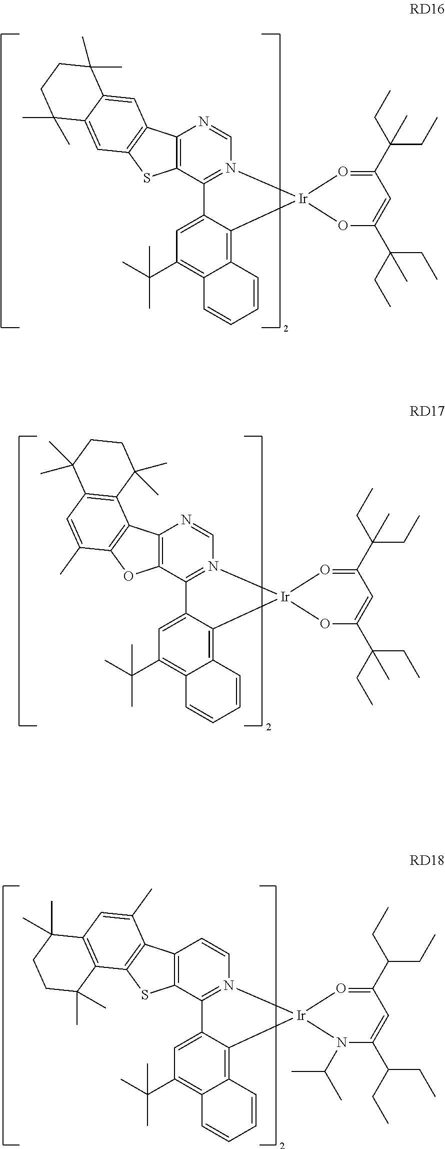

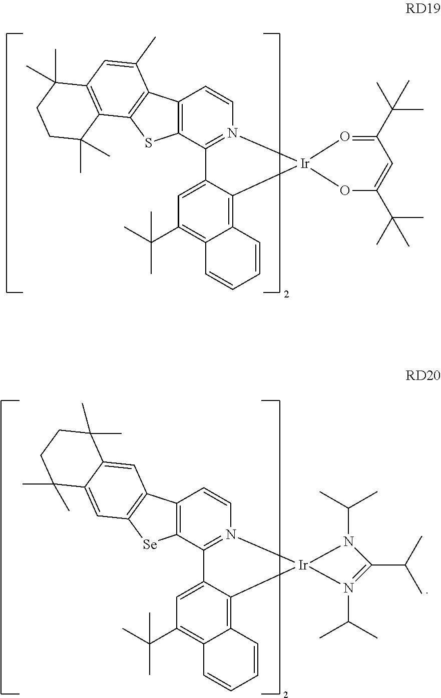

10. The organic light emitting diode of claim 1, wherein Ar¹ and Ar₂ in Chemical Formula 4 are, each independently, one monovalent group selected from the group consisting of substituted or unsubstituted benzene; substituted or unsubstituted biphenyl; substituted or unsubstituted naphthalene; substituted or unsubstituted phenanthrene; substituted or unsubstituted fluorene; substituted or unsubstituted dibenzofuran; substituted or unsubstituted dibenzothiophene; and substituted or unsubstituted spirobifluorene, and at least one hydrogen in any one of Ar₁ and Ar₂ is unsubstituted or substituted with at least one selected from the group consisting of deuterium; halogen atom; a C1-C10 alkyl group; a C6-C20 aryl group; a C2-C20 heteroaryl group; a nitrile group; a silyl group; and combinations thereof.

11. The organic light emitting diode of claim 1, wherein the compound represented by Chemical Formula 4 is one selected from the group consisting of Compounds RHH-1 to RHH-20 below:

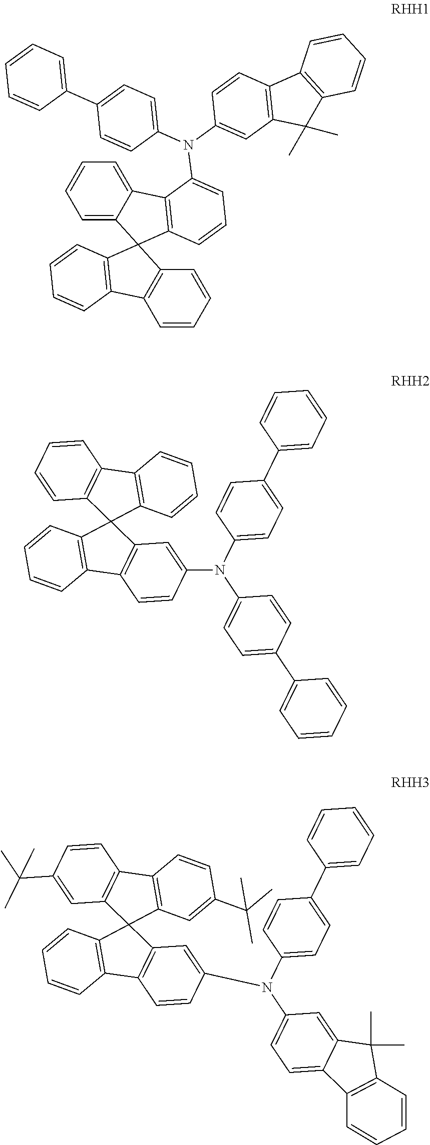 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc4c(c3)C3(c5ccccc5-c5ccccc53)c3ccccc3-4)cc2)cc1 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

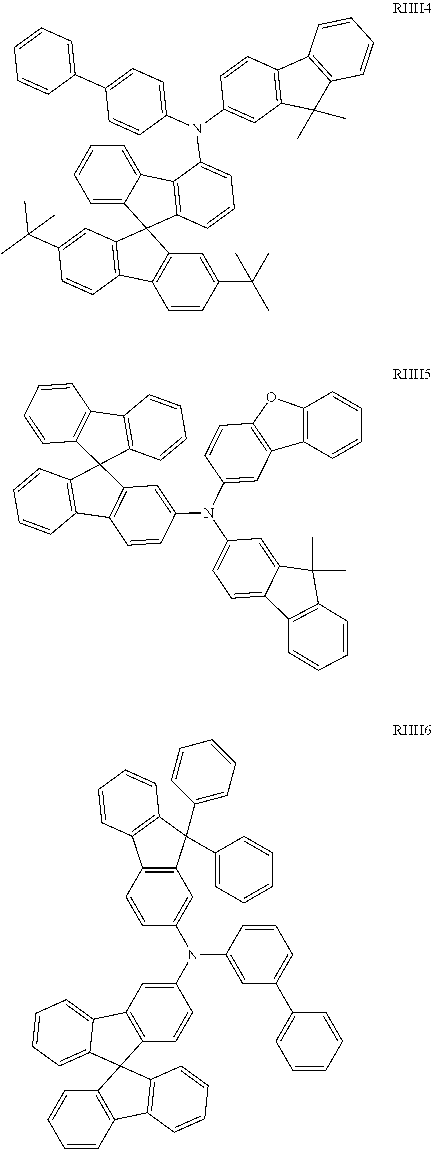 [SMILES: CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1]

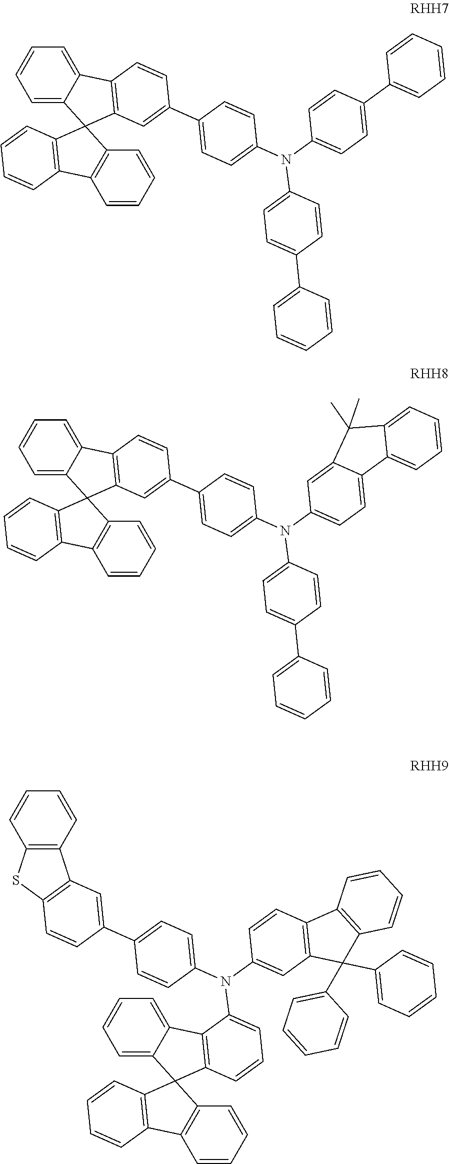 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1]

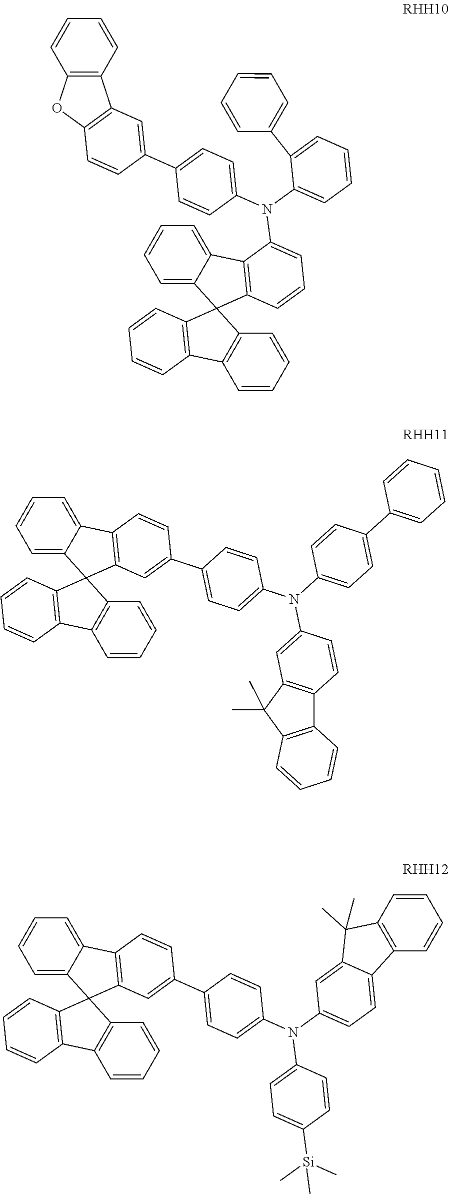 [SMILES: c1ccc(-c2ccccc2N(c2ccc(-c3ccc4oc5ccccc5c4c3)cc2)c2cccc3c2-c2ccccc2C32c3ccccc3-c3ccccc32)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; CC1(C)c2ccccc2-c2ccc(N(c3ccc(-c4ccc5c(c4)C4(c6ccccc6-c6ccccc64)c4ccccc4-5)cc3)c3ccc([Si](C)(C)C)cc3)cc21]

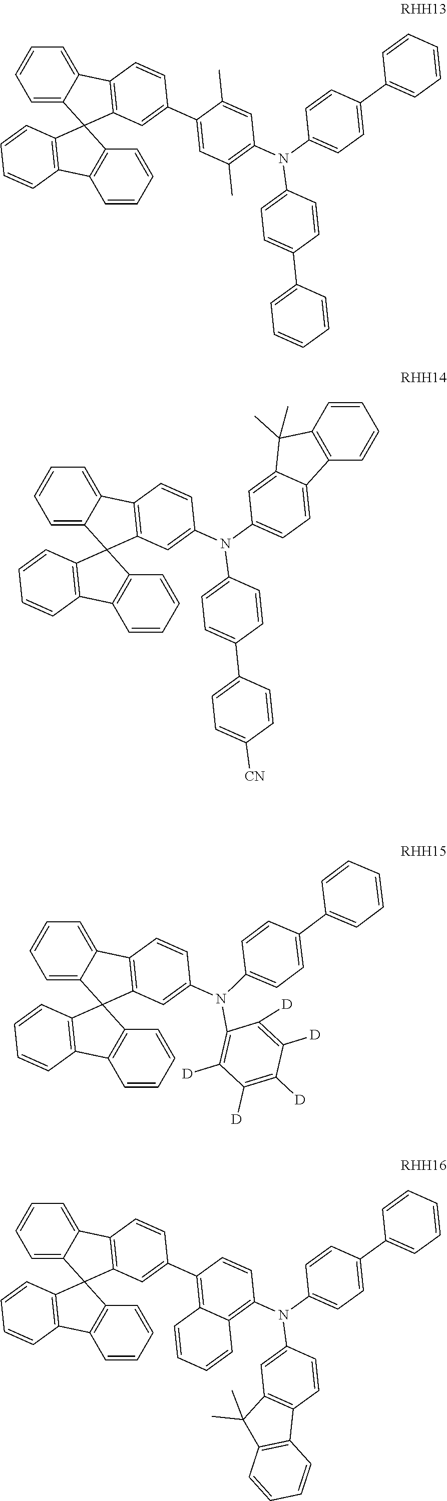 [SMILES: Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21 ; [2H]c1c([2H])c([2H])c(N(c2ccc(-c3ccccc3)cc2)c2ccc3c(c2)C2(c4ccccc4-c4ccccc42)c2ccccc2-3)c([2H])c1[2H] ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21]

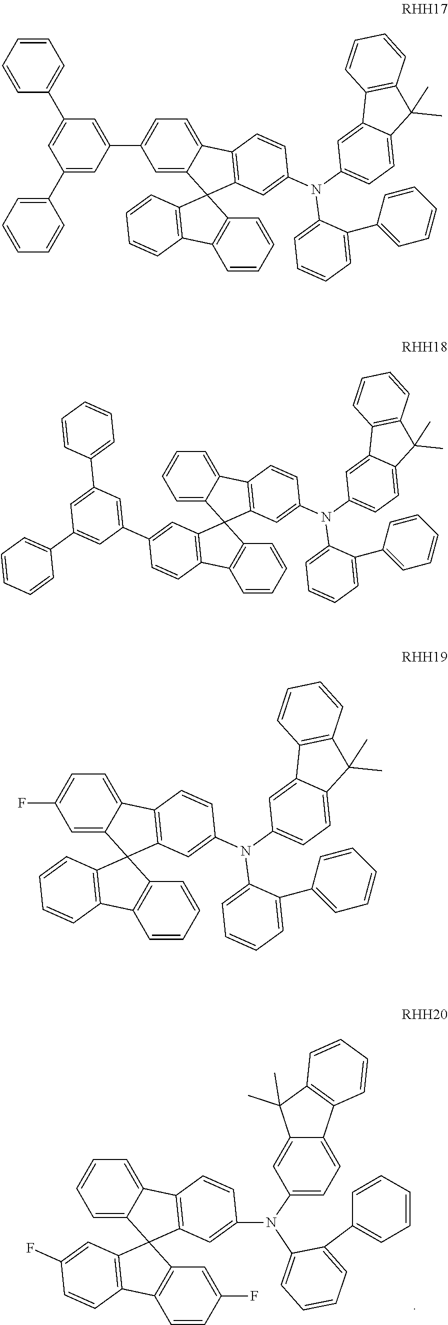 [SMILES: CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21 ; CC1(C)c2ccccc2-c2cc(N(c3ccc4c(c3)C3(c5ccccc5-c5ccccc53)c3cc(F)ccc3-4)c3ccccc3-c3ccccc3)ccc21 ; CC1(C)c2ccccc2-c2ccc(N(c3ccc4c(c3)C3(c5ccccc5-4)c4cc(F)ccc4-c4ccc(F)cc43)c3ccccc3-c3ccccc3)cc21]

12. The organic light emitting diode of claim 1, wherein X₁₁ and X₁₂ in Chemical Formula 5 are N.

13. The organic light emitting diode of claim 1, wherein the compound represented by Chemical Formula 5 is one selected from the group consisting of Compounds REH-1 to REH-20 below:

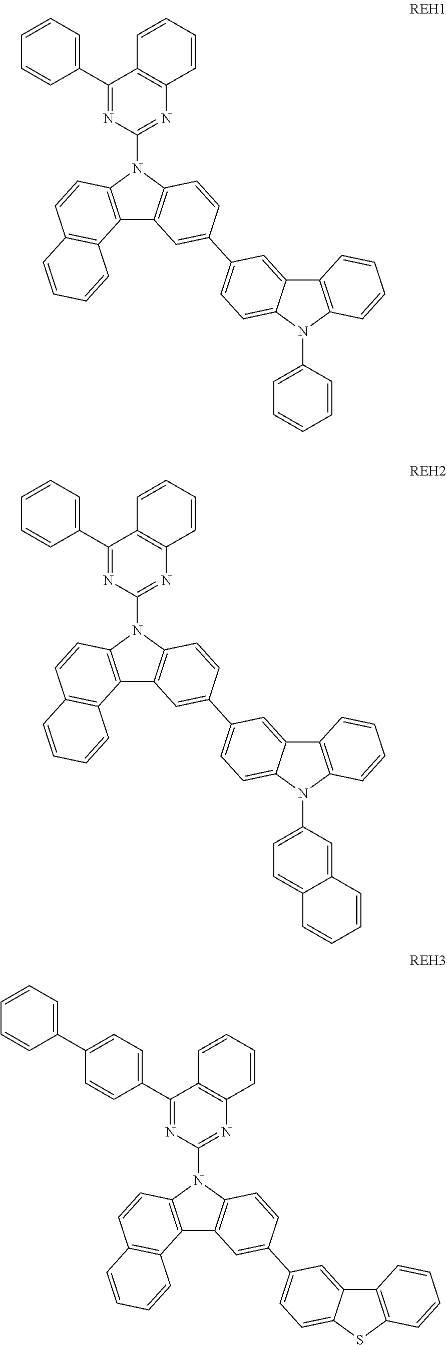 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

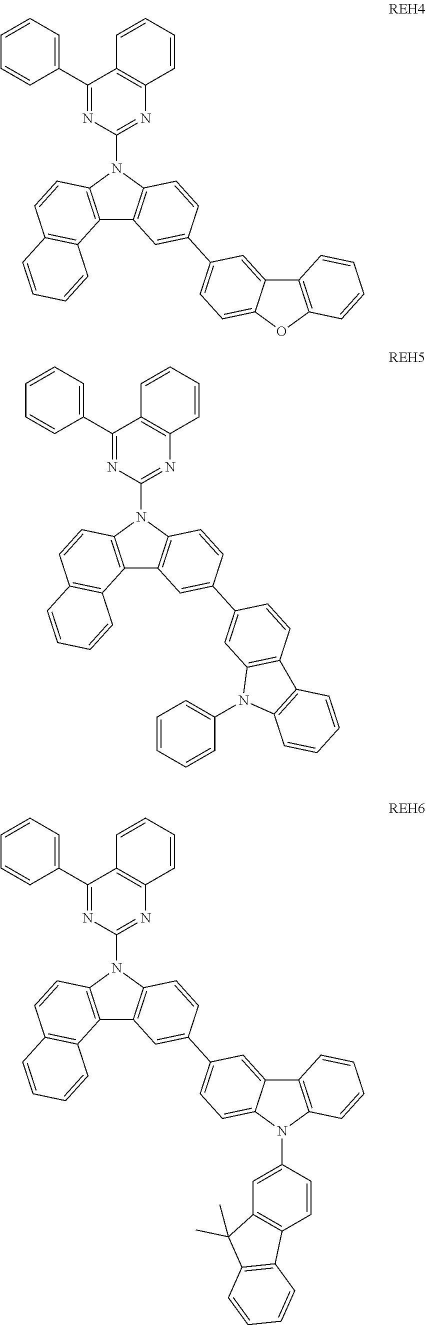 [SMILES: c1ccc(-c2nc(-n3c4ccc(-c5ccc6oc7ccccc7c6c5)cc4c4c5ccccc5ccc43)nc3ccccc23)cc1 ; c1ccc(-c2nc(-n3c4ccc(-c5ccc6c7ccccc7n(-c7ccccc7)c6c5)cc4c4c5ccccc5ccc43)nc3ccccc23)cc1 ; CC1(C)c2ccccc2-c2ccc(-n3c4ccccc4c4cc(-c5ccc6c(c5)c5c7ccccc7ccc5n6-c5nc(-c6ccccc6)c6ccccc6n5)ccc43)cc21]

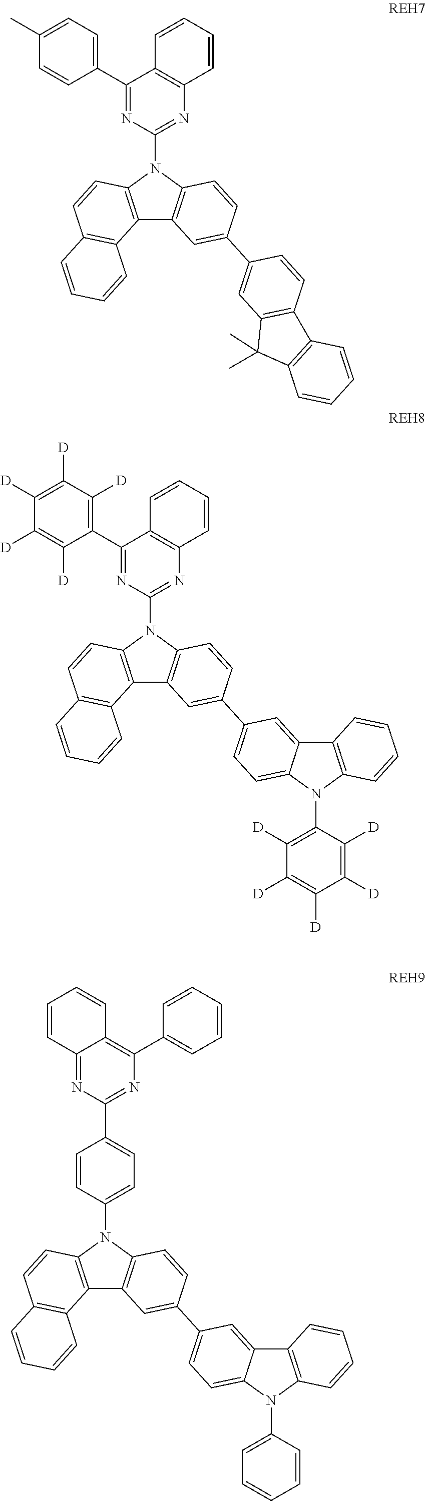 [SMILES: Cc1ccc(-c2nc(-n3c4ccc(-c5ccc6c(c5)C(C)(C)c5ccccc5-6)cc4c4c5ccccc5ccc43)nc3ccccc23)cc1 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H] ; c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1]

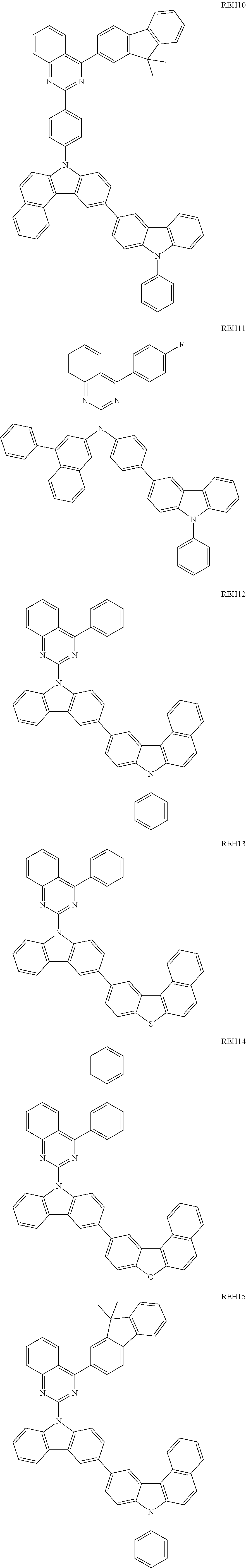

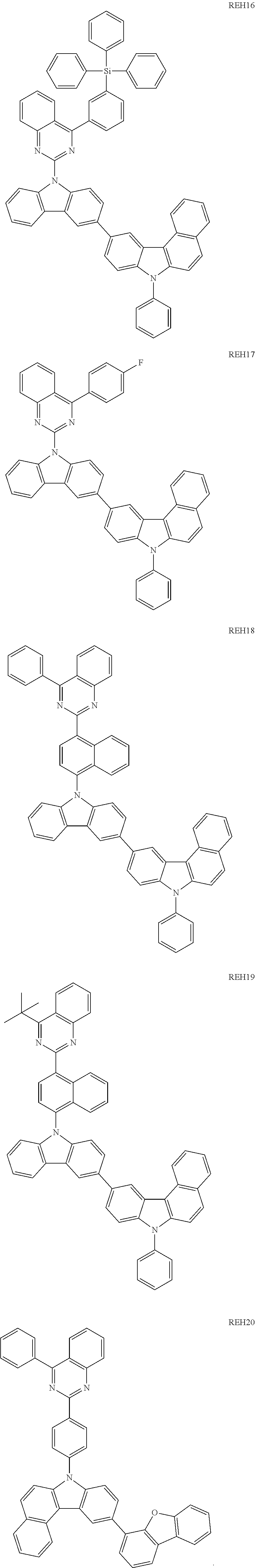

14. The organic light emitting diode of claim 1, wherein the intermediate layer further comprises any one or more among a hole injection layer, a hole transport layer, a hole transport auxiliary layer, an electron blocking layer, an electron transport layer, and an electron injection layer.

15. An organic light emitting diode comprising:
a first electrode;
a second electrode facing the first electrode; and
one or more light emitting parts positioned between the first electrode and the second electrode,
wherein at least one of the light emitting parts comprises a red phosphorescent layer,
the red phosphorescent layer comprises a dopant material and a host material,
the dopant material comprises an organometallic compound represented by Chemical Formula 1 below, and
the host material comprises a compound represented by Chemical Formula 4 below and a compound represented by Chemical Formula 5 below:
M(L_{A})ₘ(L_{B})ₙ <Chemical Formula 1>
in Chemical Formula 1,
M is a central coordination metal and is one selected from the group consisting of molybdenum (Mo); tungsten (W); rhenium (Re); ruthenium (Ru); osmium (Os); rhodium (Rh); iridium (Ir); palladium (Pd); platinum (Pt); and gold (Au),
L_{A} is a ligand represented by Chemical Formula 2,
L_{B} is a bidentate ligand,
m is 1, 2 or 3, n is 0, 1 or 2, and (m+n) is the oxidation number of the central coordination metal M, 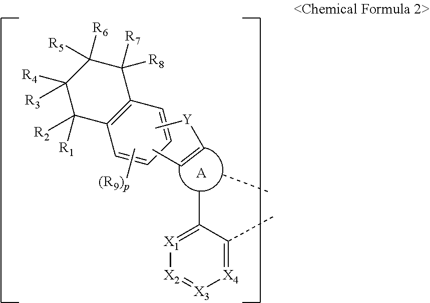
in Chemical Formula 2,
A has a ring structure selected from substituted or unsubstituted pyridine and substituted or unsubstituted pyrimidine,
R₁ to R₈ are, each independently, at least one selected from the group consisting of hydrogen; deuterium; a substituted or unsubstituted C1-C20 linear alkyl group; a substituted or unsubstituted C3-C20 branched alkyl group; and a substituted or unsubstituted C4-C20 bicycloalkyl group, and optionally, R₁ to R₈ are partially or entirely deuterated,
R₉ is, each independently, at least one selected from the group consisting of hydrogen; deuterium; a substituted or unsubstituted C1-C20 linear alkyl group; a substituted or unsubstituted C3-C20 branched alkyl group; a C3-C20 cycloalkyl group; halogen; a nitrile group; a substituted or unsubstituted C1-C20 alkoxy group; and combinations thereof, and optionally, R₉ is partially or entirely deuterated,
when any one of R₁ to R₉ is substituted, a substituent of R₁ to R₉ is, each independently, be at least one selected from the group consisting of deuterium; halogen; a C3-C10 cycloalkyl group; and combinations thereof, and when a plurality of substituents of R₁ to R₉ are present, each substituent is the same as or different from each other,
Y is at least one selected from the group consisting of BR₁₀; CR₁₀R₁₁; C═O; CNR₁₀; SiR₁₀R₁₁; NR₁₀; PR₁₀; AsR₁₀; SbR₁₀; P(O) R₁₀; P(S)R₁₀; P(Se)R₁₀; As(O) R₁₀; As(S)R₁₀; As(Se)R₁₀; Sb(O) R₁₀; Sb(S)R₁₀; Sb(Se)R₁₀; O; S; Se; Te; SO; SO2; SeO; SeO₂; TeO; and TeO₂,
X₁ to X₄ are, each independently, at least one selected from CR₁₂ and nitrogen (N),
when any two of X₁ to X₄ that are adjacent to each other are CR₁₂, two R₁₂ are not bonded, or are bonded to form a 5-membered or 6-membered, substituted or unsubstituted aromatic ring or heteroaromatic ring structure, when one of any two of X₁ to X₄ that are adjacent is CR₁₂ and the other is nitrogen (N), R₁₂ is not bonded, or is bonded to the nitrogen to form a 5-membered or 6-membered heteroaromatic ring structure, and the aromatic ring or the heteroaromatic ring structure formed where R₁₂ is bonded is not substituted or substituted with at least one deuterium,
R₁₀ to R₁₂ are, each independently, at least one selected from the group consisting of hydrogen; deuterium; halogen; a hydroxyl group; a nitro group; an amidino group; a hydrazine group; a hydrazone group; a substituted or unsubstituted C1-C20 linear alkyl group; a substituted or unsubstituted C3-C20 branched alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
when any one of R₁₀ to R₁₂ is substituted, a substituent of R₁₀ to R₁₂ is, each independently, at least one selected from the group consisting of deuterium; halogen; and combinations thereof, and when a plurality of the substituents of R₁₀ to R₁₂ are present, each substituent is the same as or different from each other, and
p is 2, and
dotted line represents a connection position to the central coordination metal M, 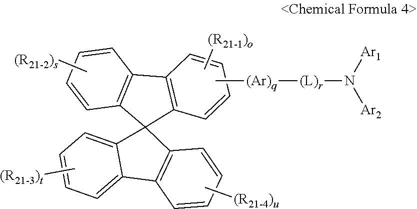
in Chemical Formula 4,
Ar is, each independently, a divalent group of an aromatic ring or a heteroaromatic ring selected from the group consisting of benzene; naphthalene; phenanthrene; fluorene; spirobifluorene; dibenzofuran; and dibenzothiophene,
Ar₁ and Ar₂ are, each independently, a substituted or unsubstituted C6-C60 aryl group or a substituted or unsubstituted C2-C60 heteroaryl group,
R₂₁₋₁ to R₂₁₋₄ are, each independently, at least one selected from the group consisting of deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group,
o is an integer from 0 to 3, when o is an integer of 2 or 3, R₂₁₋₁ is the same or different, and optionally, R₂₁₋₁ is deuterated partially or entirely,
s is an integer from 0 to 4, when s is an integer from 2 to 4, R₂₁₋₂ is the same or different, and optionally, R₂₁₋₂ is deuterated partially or entirely,
t is an integer from 0 to 4, when t is an integer from 2 to 4, R₂₁₋₃ is the same or different, and optionally, R₂₁₋₃ is deuterated partially or entirely,
u is an integer from 0 to 4, when u is an integer from 2 to 4, R₂₁₋₄ is the same or different, and optionally, R₂₁₋₄ is deuterated partially or entirely,
q is an integer from 0 to 2, and
r is an integer of 0 or 1, and
a linker L is at least one selected from the group consisting of a substituted or unsubstituted C6-C30 arylene group; a substituted or unsubstituted C2-C30 heteroarylene group; and a substituted or unsubstituted C7-C20 arylalkylene group, 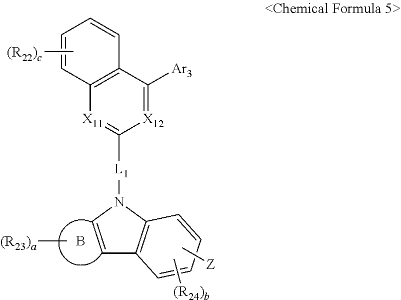
in Chemical Formula 5,
a B ring is a substituted or unsubstituted C6-C30 monocyclic or polycyclic aromatic fused ring,
X₁₁ and X₁₂ are, each independently, N or CR′,
L₁ is one selected from the group consisting of a single bond; a substituted or unsubstituted C6-C30 arylene group; a substituted or unsubstituted C2-C30 heteroarylene group; and a substituted or unsubstituted C3-C30 cycloalkylene group,
Ar₃ is one selected from the group consisting of hydrogen; deuterium; halogen; a substituted or unsubstituted C1-C30 alkyl group; a substituted or unsubstituted C6-C30 aryl group; a substituted or unsubstituted C2-C30 heteroaryl group; and -L₂₄-SiRₖRₗRₘ, in which L₂₄ is a single bond, a substituted or unsubstituted C6-C30 arylene group, or a substituted or unsubstituted C2-C30 heteroarylene group, and Rₖ, Rₗ, and Rₘ are, each independently, hydrogen, a substituted or unsubstituted C1-C30 alkyl group or a substituted or unsubstituted C6-C30 aryl group,
one or more of hydrogen of an alkyl group, an aryl group, a heteroaryl group, or a -L₂₄-SiRₖRₗRₘ group, which is Ar₃, are unsubstituted or substituted with one or more of deuterium and halogen atom,
Z is one selected from the group consisting of the following structures, 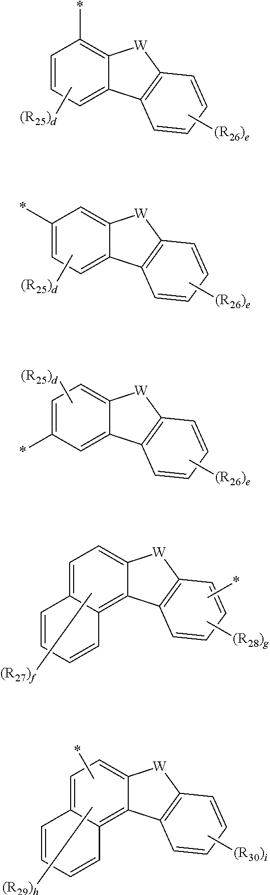
W is one selected from the group consisting of O; S; NR₃₁; CR₃₁R₃₂; and SiR₃₁R₃₂,
R₂₂ to R₃₂ and R′ are, each independently, one selected from the group consisting of hydrogen; deuterium; halogen; a hydroxyl group; a nitro group; an amidino group; a hydrazine group; a hydrazone group; a substituted or unsubstituted C1-C20 alkyl group; a substituted or unsubstituted C3-C20 cycloalkyl group; a substituted or unsubstituted C1-C20 heteroalkyl group; a substituted or unsubstituted C7-C20 arylalkyl group; a substituted or unsubstituted C2-C20 alkenyl group; a substituted or unsubstituted C3-C20 cycloalkenyl group; a substituted or unsubstituted C2-C20 heteroalkenyl group; a substituted or unsubstituted C2-C20 alkynyl group; a substituted or unsubstituted C6-C30 aryl group; a substituted or unsubstituted C2-C30 heteroaryl group; a substituted or unsubstituted C1-C20 alkoxy group; an amino group; a silyl group; a C2-C30 acyl group; a carboxyl group; a nitrile group; an isonitrile group; a sulfanyl group; and a phosphino group, and
a, c, e and i are, each independently, an integer of 1, 2, 3 or 4; b, d, g are, each independently, an integer of 1, 2 or 3; f is an integer of 1, 2, 3, 4, 5, or 6; and h is an integer of 1, 2, 3, 4, or 5.

16. The organic light emitting diode of claim 15, wherein the organometallic compound represented by Chemical Formula 1 is one selected from the group consisting of Compounds RD-1 to RD-20 below:

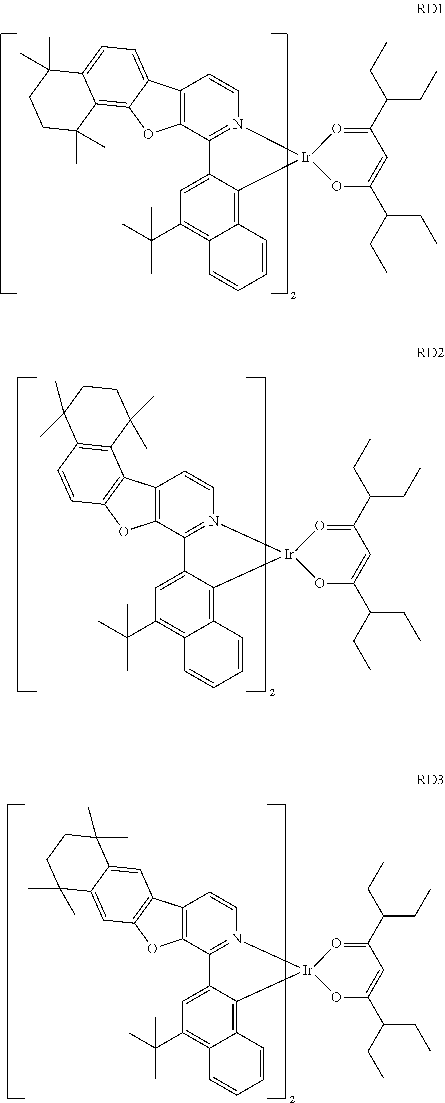

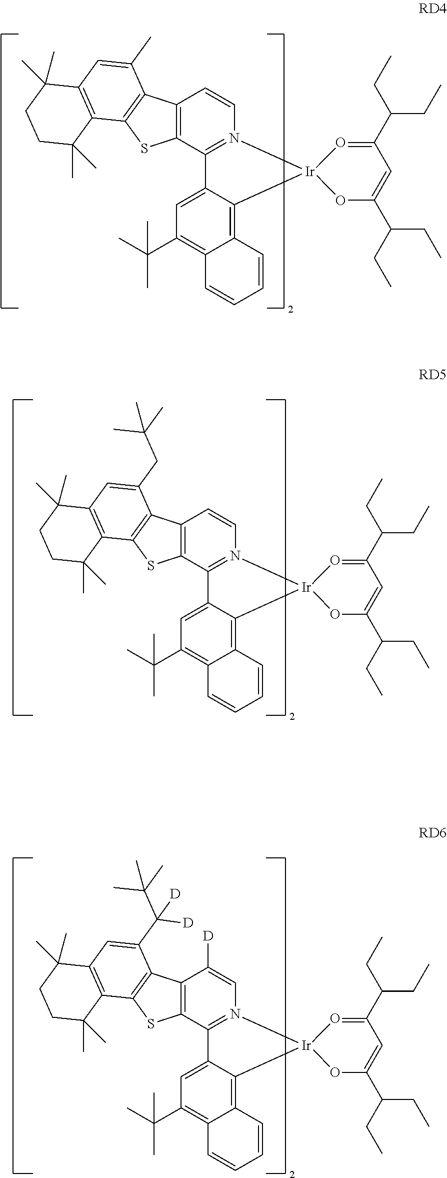

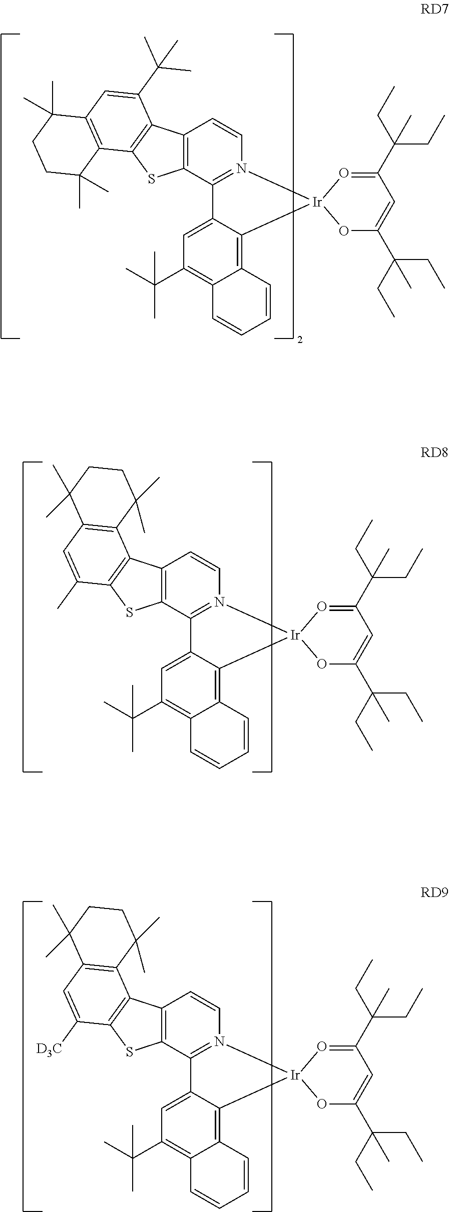

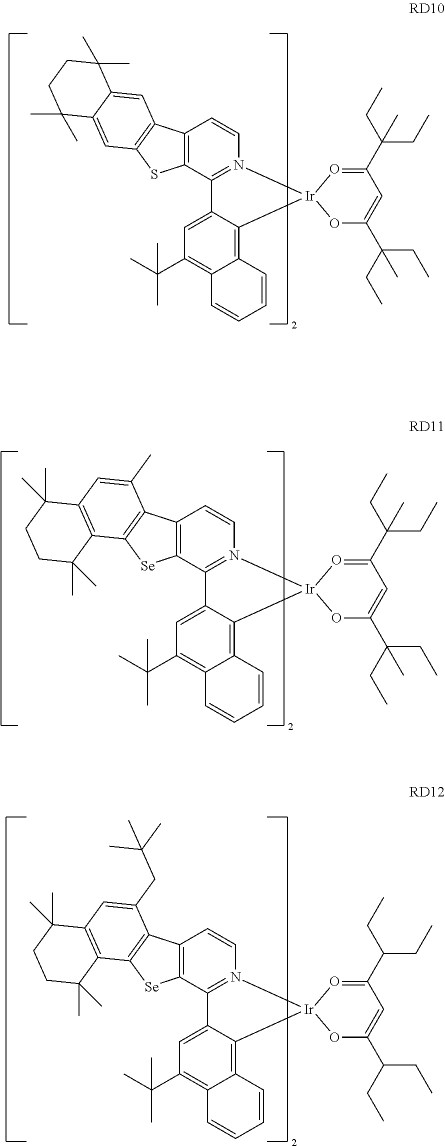

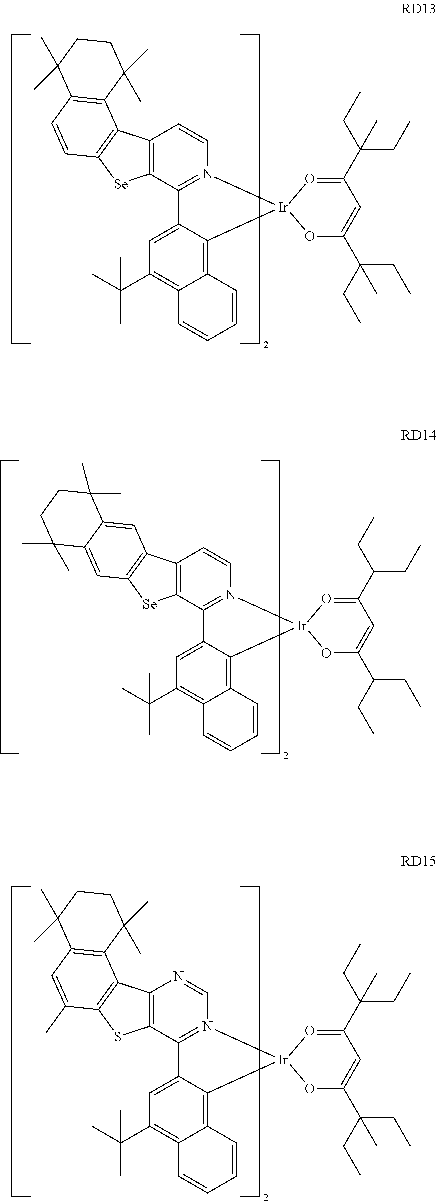

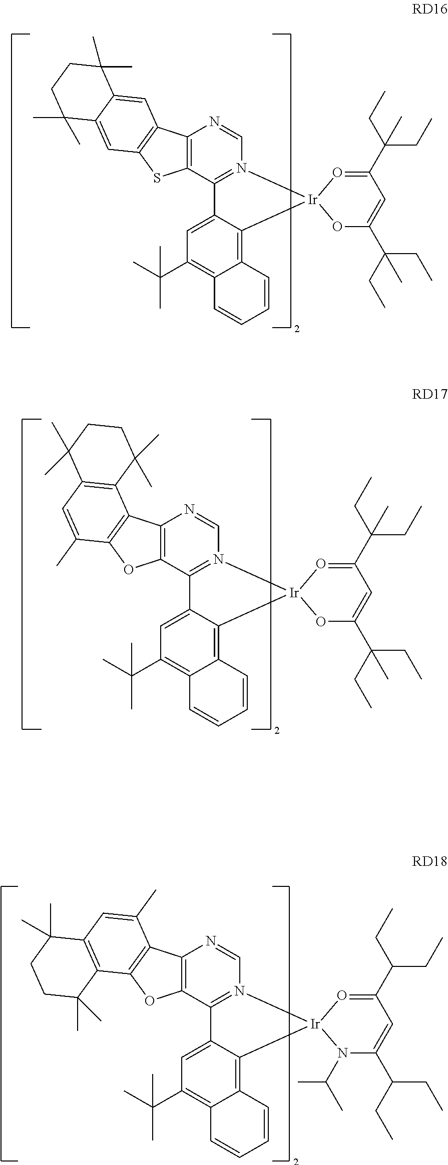

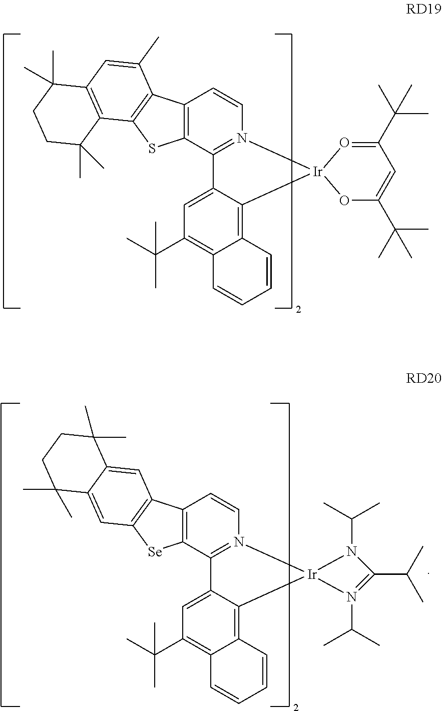

17. The organic light emitting diode of claim 15, wherein the compound represented by Chemical Formula 4 is one selected from the group consisting of Compounds RHH-1 to RHH-20 below:

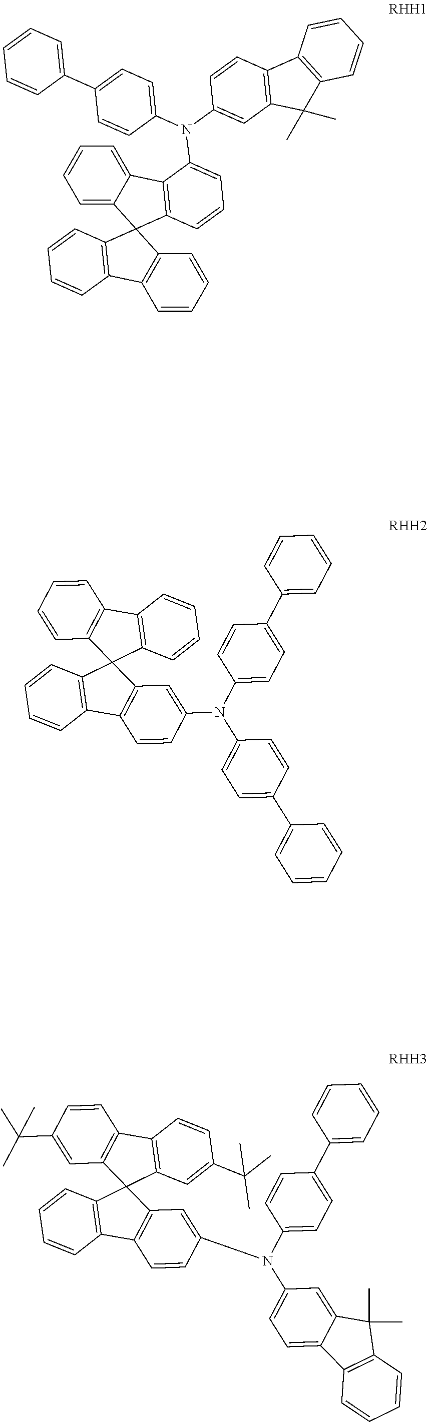 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc4c(c3)C3(c5ccccc5-c5ccccc53)c3ccccc3-4)cc2)cc1 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

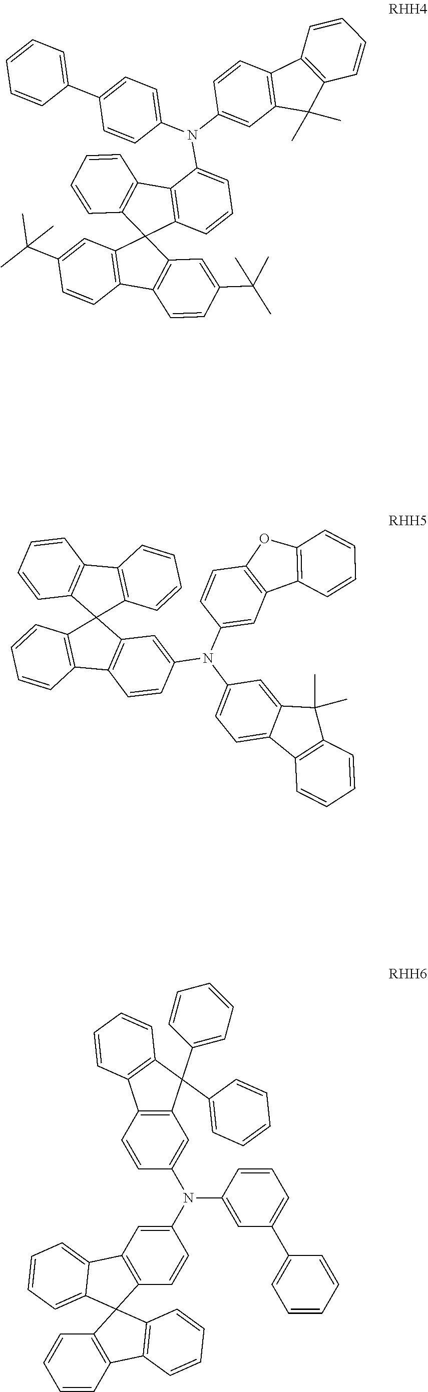 [SMILES: CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1]

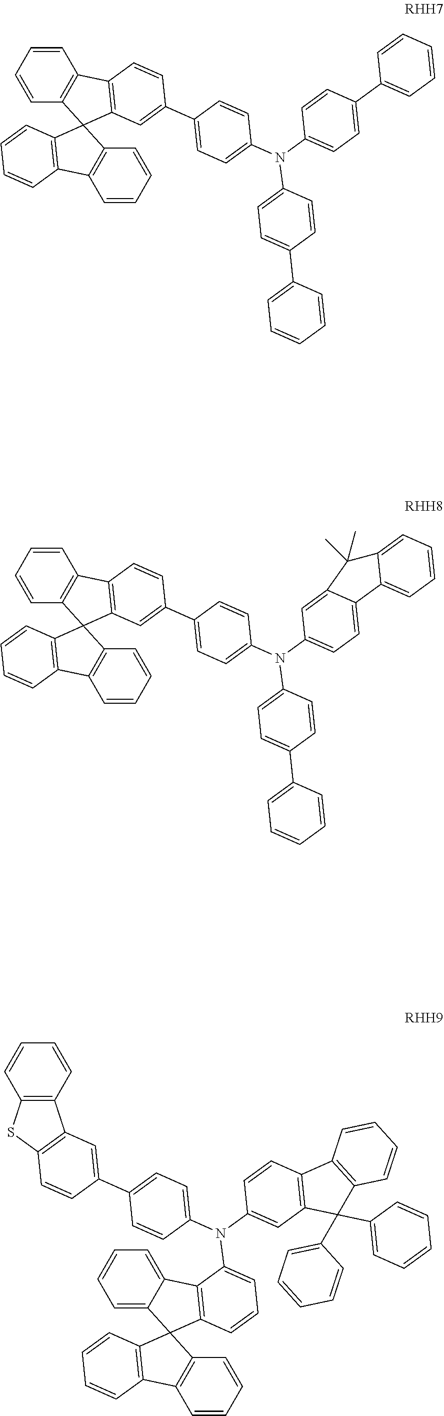 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1]

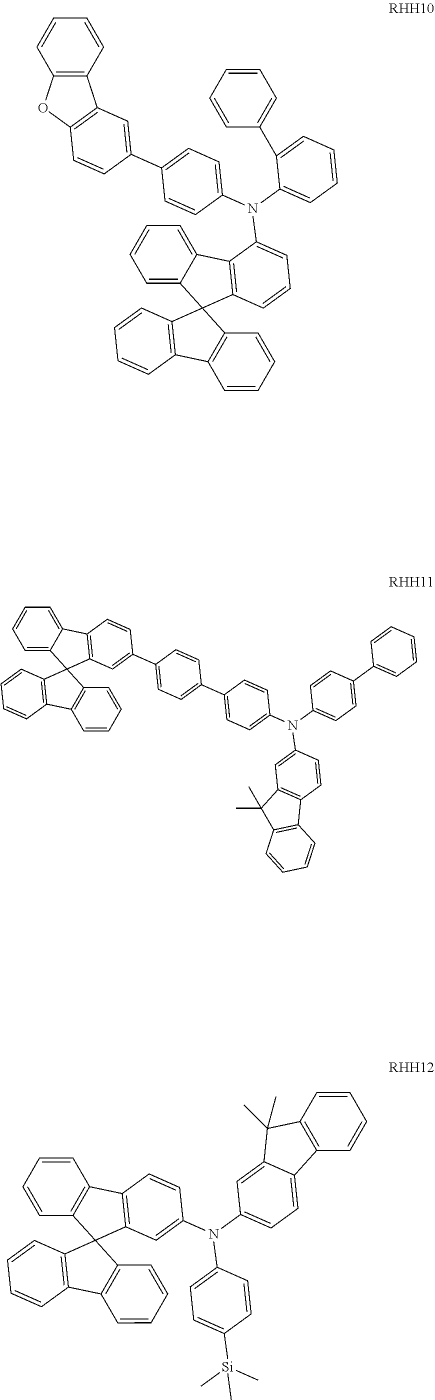 [SMILES: c1ccc(-c2ccccc2N(c2ccc(-c3ccc4oc5ccccc5c4c3)cc2)c2cccc3c2-c2ccccc2C32c3ccccc3-c3ccccc32)cc1 ; CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21 ; CC1(C)c2ccccc2-c2ccc(N(c3ccc([Si](C)(C)C)cc3)c3ccc4c(c3)C3(c5ccccc5-c5ccccc53)c3ccccc3-4)cc21]

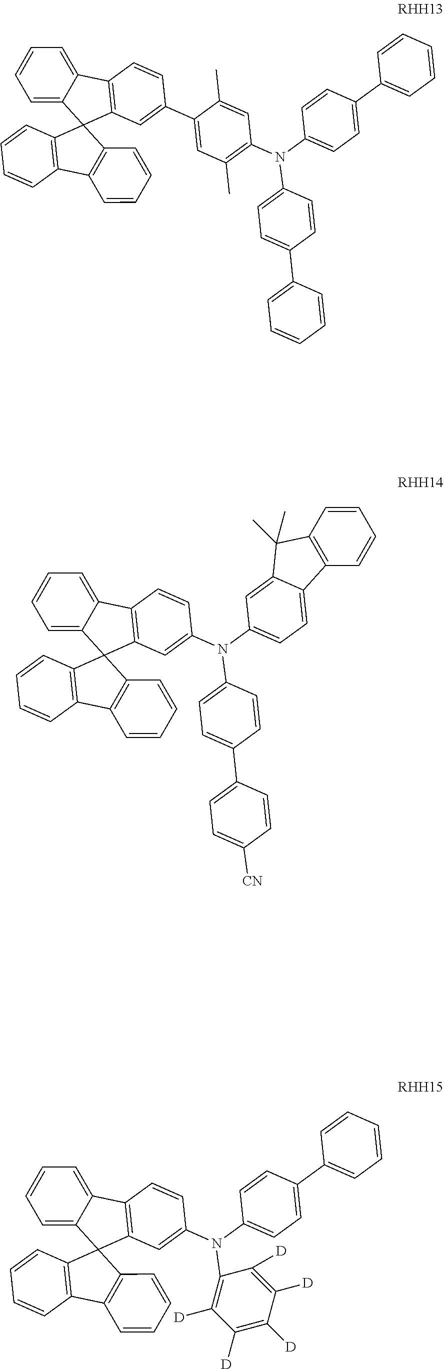 [SMILES: Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21 ; [2H]c1c([2H])c([2H])c(N(c2ccc(-c3ccccc3)cc2)c2ccc3c(c2)C2(c4ccccc4-c4ccccc42)c2ccccc2-3)c([2H])c1[2H]]

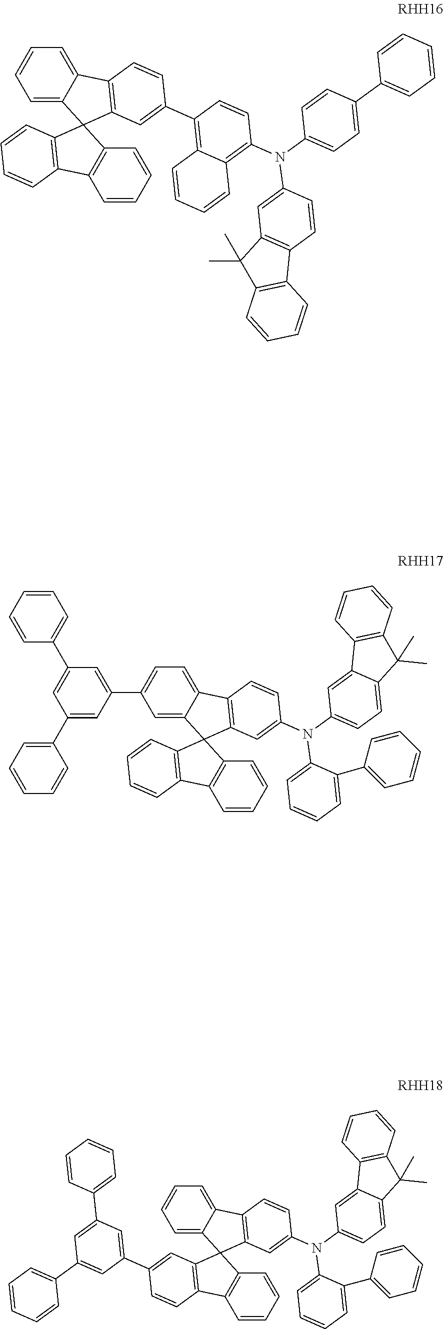 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21 ; CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21]

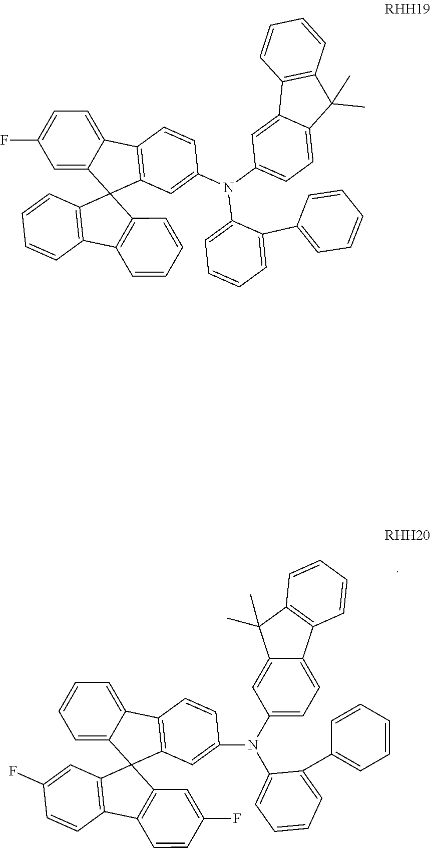

18. The organic light emitting diode of claim 15, wherein the compound represented by Chemical Formula 5 is one selected from the group consisting of Compounds REH-1 to REH-20 below:

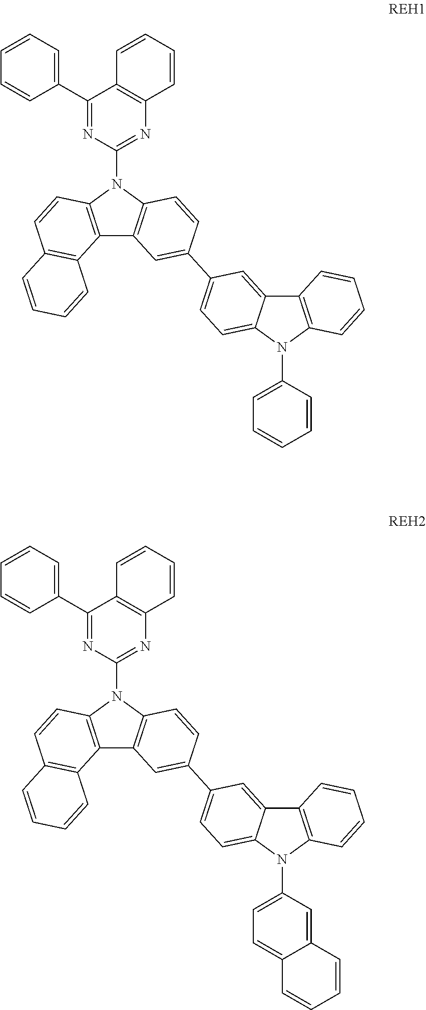 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1]

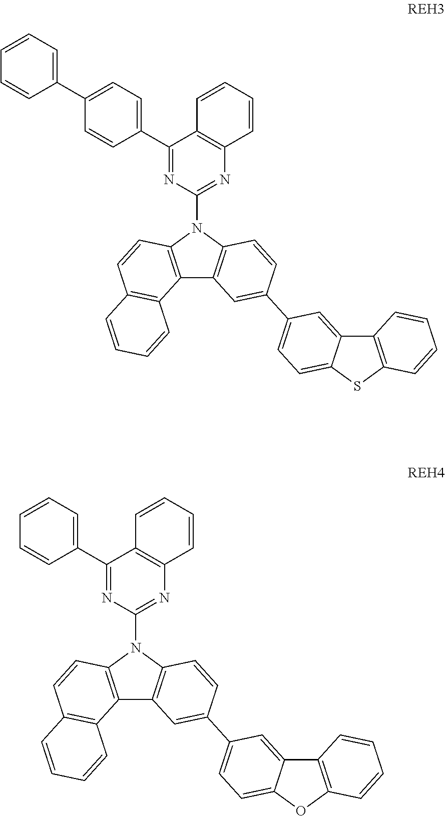 [SMILES: c1ccc(-c2ccc(-c3nc(-n4c5ccc(-c6ccc7sc8ccccc8c7c6)cc5c5c6ccccc6ccc54)nc4ccccc34)cc2)cc1 ; c1ccc(-c2nc(-n3c4ccc(-c5ccc6oc7ccccc7c6c5)cc4c4c5ccccc5ccc43)nc3ccccc23)cc1]

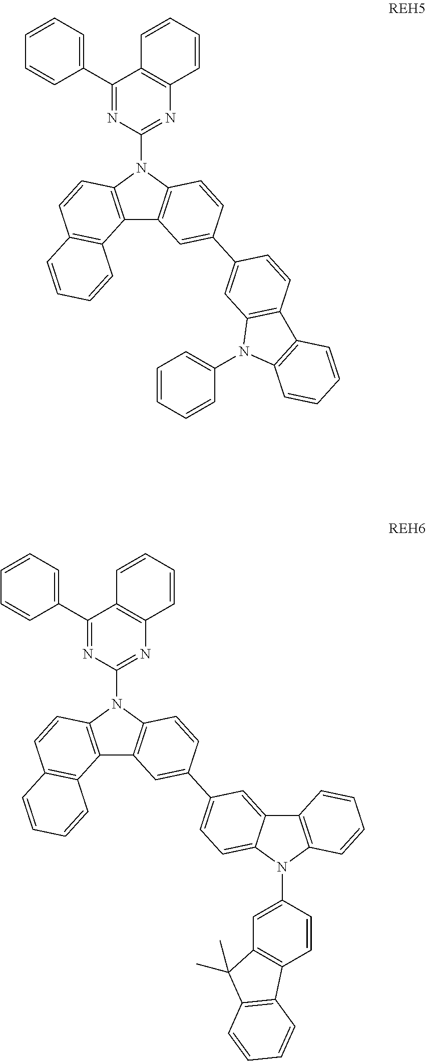 [SMILES: c1ccc(-c2nc(-n3c4ccc(-c5ccc6c7ccccc7n(-c7ccccc7)c6c5)cc4c4c5ccccc5ccc43)nc3ccccc23)cc1 ; CC1(C)c2ccccc2-c2ccc(-n3c4ccccc4c4cc(-c5ccc6c(c5)c5c7ccccc7ccc5n6-c5nc(-c6ccccc6)c6ccccc6n5)ccc43)cc21]

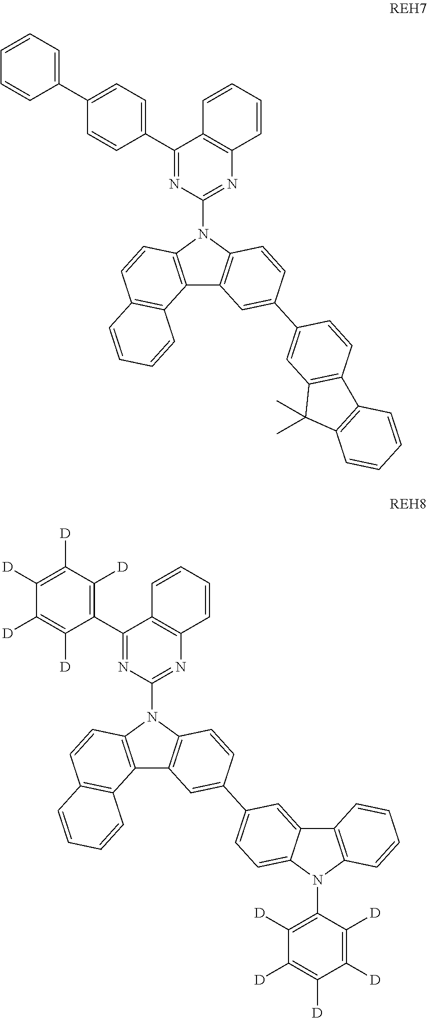 [SMILES: CC1(C)c2ccccc2-c2ccc(-c3ccc4c(c3)c3c5ccccc5ccc3n4-c3nc(-c4ccc(-c5ccccc5)cc4)c4ccccc4n3)cc21 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H]]

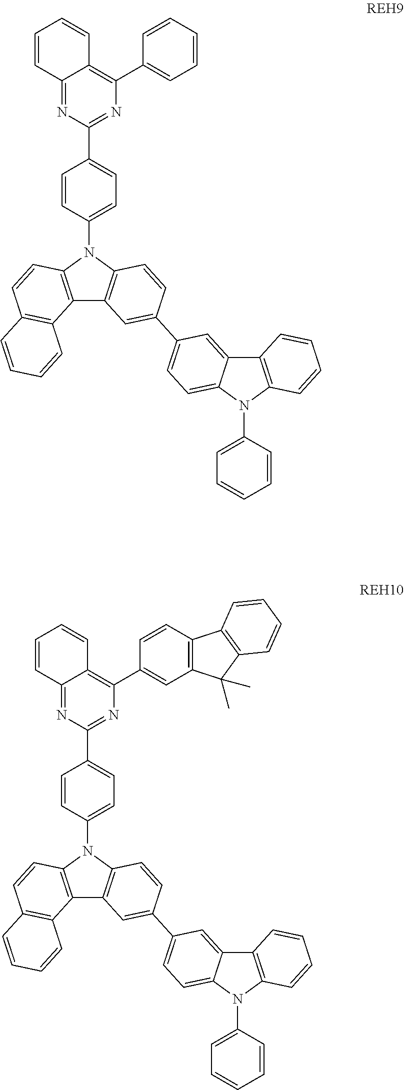 [SMILES: c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1 ; CC1(C)c2ccccc2-c2ccc(-c3nc(-c4ccc(-n5c6ccc(-c7ccc8c(c7)c7ccccc7n8-c7ccccc7)cc6c6c7ccccc7ccc65)cc4)nc4ccccc34)cc21]

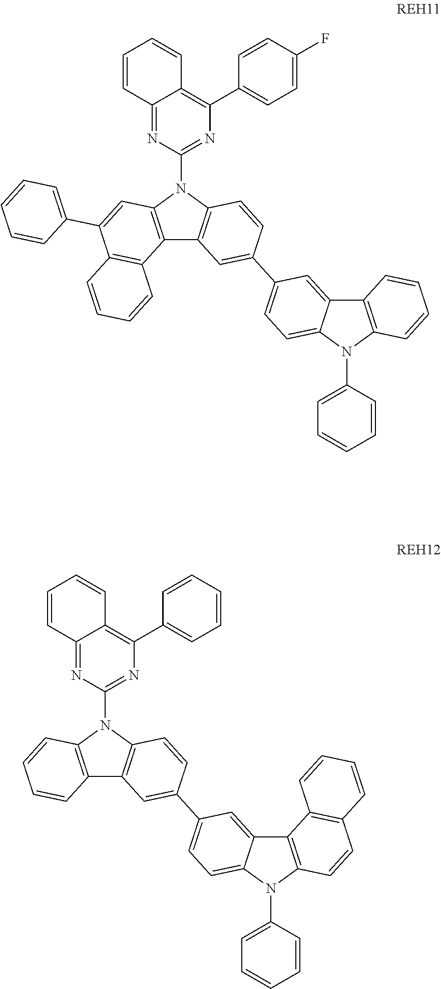 [SMILES: Fc1ccc(-c2nc(-n3c4ccc(-c5ccc6c(c5)c5ccccc5n6-c5ccccc5)cc4c4c5ccccc5c(-c5ccccc5)cc43)nc3ccccc23)cc1 ; c1ccc(-c2nc(-n3c4ccccc4c4cc(-c5ccc6c(c5)c5c7ccccc7ccc5n6-c5ccccc5)ccc43)nc3ccccc23)cc1]

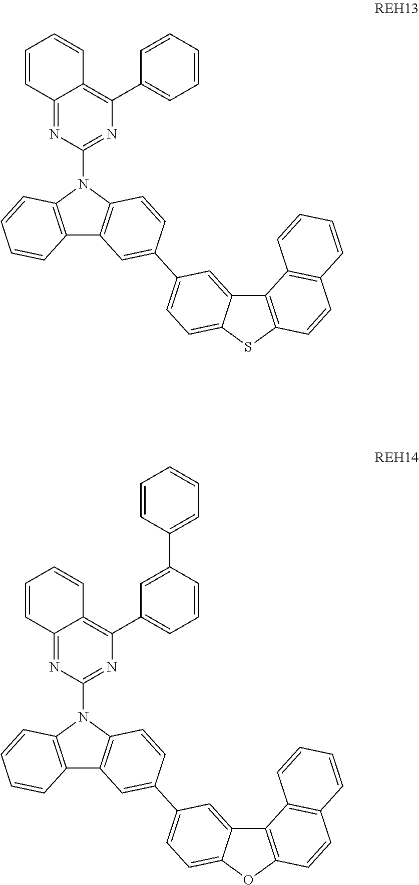 [SMILES: c1ccc(-c2nc(-n3c4ccccc4c4cc(-c5ccc6sc7ccc8ccccc8c7c6c5)ccc43)nc3ccccc23)cc1 ; c1ccc(-c2cccc(-c3nc(-n4c5ccccc5c5cc(-c6ccc7oc8ccc9ccccc9c8c7c6)ccc54)nc4ccccc34)c2)cc1]

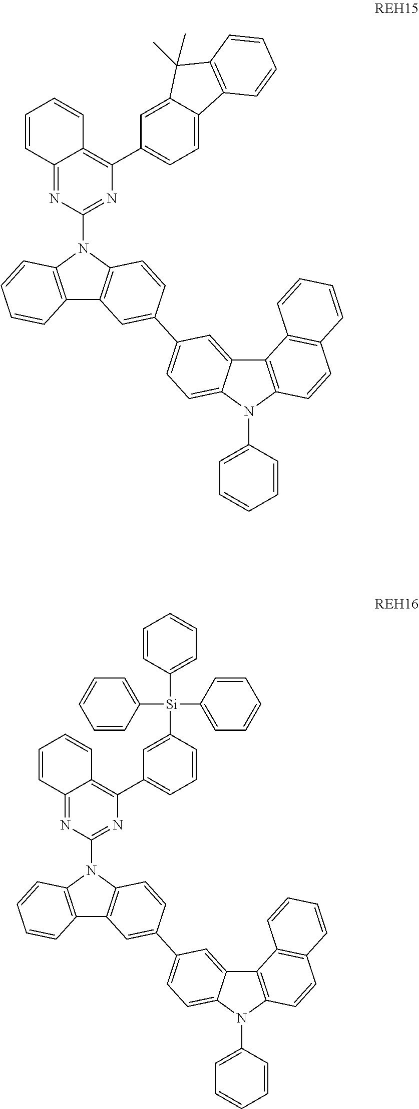 [SMILES: CC1(C)c2ccccc2-c2ccc(-c3nc(-n4c5ccccc5c5cc(-c6ccc7c(c6)c6c8ccccc8ccc6n7-c6ccccc6)ccc54)nc4ccccc34)cc21 ; c1ccc(-n2c3ccc(-c4ccc5c(c4)c4ccccc4n5-c4nc(-c5cccc([Si](c6ccccc6)(c6ccccc6)c6ccccc6)c5)c5ccccc5n4)cc3c3c4ccccc4ccc32)cc1]

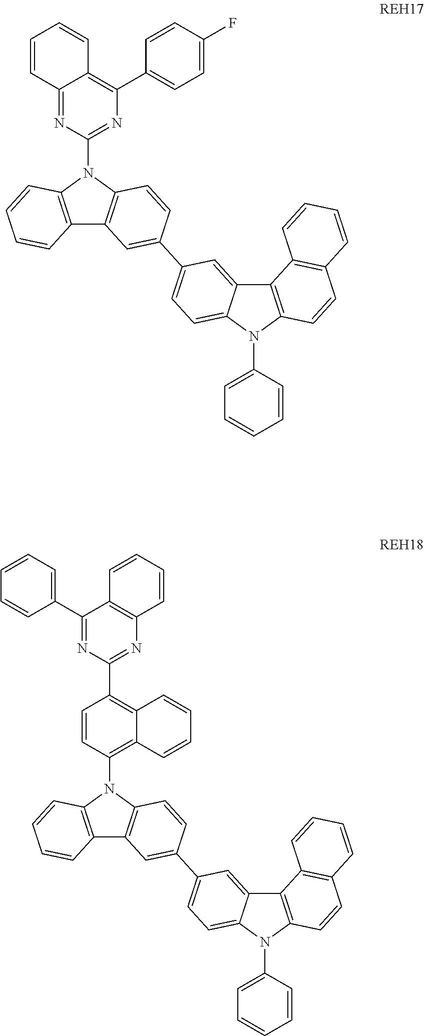 [SMILES: Fc1ccc(-c2nc(-n3c4ccccc4c4cc(-c5ccc6c(c5)c5c7ccccc7ccc5n6-c5ccccc5)ccc43)nc3ccccc23)cc1 ; c1ccc(-c2nc(-c3ccc(-n4c5ccccc5c5cc(-c6ccc7c(c6)c6c8ccccc8ccc6n7-c6ccccc6)ccc54)c4ccccc34)nc3ccccc23)cc1]

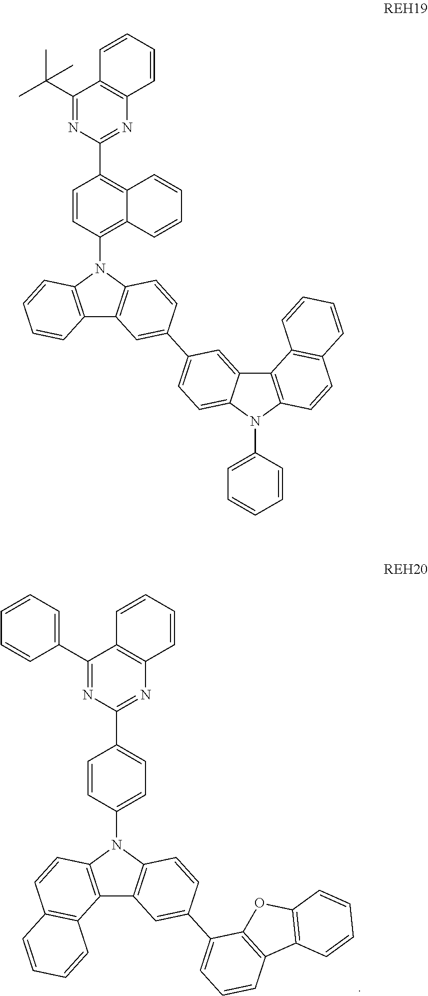 [SMILES: CC(C)(C)c1nc(-c2ccc(-n3c4ccccc4c4cc(-c5ccc6c(c5)c5c7ccccc7ccc5n6-c5ccccc5)ccc43)c3ccccc23)nc2ccccc12 ; c1ccc(-c2nc(-c3ccc(-n4c5ccc(-c6cccc7c6oc6ccccc67)cc5c5c6ccccc6ccc54)cc3)nc3ccccc23)cc1]

19. The organic light emitting diode of claim 15, wherein a plurality of light emitting parts are present between the first electrode and the second electrode, and
the plurality of light emitting parts have a structure connected by charge generation layers disposed between the plurality of light emitting parts.

20. An organic light emitting diode display device comprising:
a substrate;
a driving element positioned on the substrate; and
the organic light emitting diode according to claim 1, which is positioned on the substrate and connected to the driving element.
